(19) United States
(12) Patent Application Publication
(10) Pub. No.: US 2025/0253298 A1
(43) Pub. Date: Aug. 7, 2025

(54) PACKAGE STRUCTURE AND METHOD FOR FORMING THE SAME

(71) Applicant: Taiwan Semiconductor Manufacturing Company, Ltd., Hsinchu (TW)

(72) Inventors: Chen-Hua YU, Hsinchu City (TW); Hsing-Kuo HSIA, Jhubei City (TW); Ren-Fen TSUI, Taipei (TW); Yu-Hung LIN, Taichung City (TW); Jui-Lin CHAO, New Taipei City (TW)

(73) Assignee: Taiwan Semiconductor Manufacturing Company, Ltd., Hsinchu (TW)

(21) Appl. No.: 18/429,850

(22) Filed: Feb. 1, 2024

(51) Int. Cl. H01L 25/16; G02B 6/42; H01L 23/00; H01L 23/36; H01L 23/538; H01L 25/065; H10B 80/00

(52) U.S. Cl. CPC H01L 25/167; G02B 6/4214; G02B 6/4239; H01L 23/36; H01L 23/5385; H01L 24/08; H01L 24/80; H01L 25/0652; H01L 25/0657; H01L 2224/08145; H01L 2224/80895; H01L 2224/80896; H10B 80/00

(57) ABSTRACT

A package structure and method for forming the same are provided. The package structure includes a top interposer formed over a substrate, and a first die formed over the top interposer. The first die includes an optical package structure, and the optical package structure includes first optical components. The first die also includes an electronic die bonded to the optical package structure to form a hybrid bonding structure. The hybrid bonding structure includes a metal-to-metal bonding and dielectric-to-dielectric bonding. The package structure includes an optical die adjacent to the first die, and the top interposer is shared by the optical die and the first die.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

New packaging technologies, such as package on package (POP), have begun to be developed, in which a top package with a device die is bonded to a bottom package, with another device die. By adopting the new packaging technologies, various packages with different or similar functions may be integrated together.

Although existing package structures and methods of fabricating package structure have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A to 1L illustrate cross-sectional representations of various stages of manufacturing a package structure, in accordance with some embodiments.

FIG. 2 shows an enlarged cross-sectional representation of a region A of the package structure of FIG. 1K, in accordance with some embodiments.

FIG. 3 shows an enlarged cross-sectional representation of a region B of the package structure of FIG. 1K, in accordance with some embodiments.

FIG. 4 shows a cross-sectional representation of a package structure, in accordance with some embodiments of the disclosure.

FIG. 5 shows a cross-sectional representation of a package structure, in accordance with some embodiments of the disclosure.

FIG. 6 shows a cross-sectional representation of a package structure, in accordance with some embodiments of the disclosure.

FIG. 7 shows a cross-sectional representation of a package structure, in accordance with some embodiments of the disclosure.

FIG. 8 shows a cross-sectional representation of a package structure, in accordance with some embodiments of the disclosure.

FIG. 9 shows a cross-sectional representation of a package structure, in accordance with some embodiments of the disclosure.

FIG. 10 shows a cross-sectional representation of a package structure, in accordance with some embodiments of the disclosure.

FIG. 11 shows a cross-sectional representation of a package structure, in accordance with some embodiments of the disclosure.

FIG. 12 shows a cross-sectional representation of a package structure, in accordance with some embodiments of the disclosure.

FIG. 13 shows a cross-sectional representation of a package structure, in accordance with some embodiments of the disclosure.

FIG. 14 shows a cross-sectional representation of a package structure, in accordance with some embodiments of the disclosure.

FIG. 15 shows a cross-sectional representation of a package structure, in accordance with some embodiments of the disclosure.

FIG. 16 shows a cross-sectional representation of a package structure, in accordance with some embodiments of the disclosure.

FIG. 17 shows a cross-sectional representation of a package structure, in accordance with some embodiments of the disclosure.

FIG. 18 shows a cross-sectional representation of a package structure, in accordance with some embodiments of the disclosure.

FIG. 19 shows a cross-sectional representation of a package structure, in accordance with some embodiments of the disclosure.

FIG. 20 shows a cross-sectional representation of a package structure, in accordance with some embodiments of the disclosure.

FIG. 21 shows a cross-sectional representation of a package structure, in accordance with some embodiments of the disclosure.

FIG. 22 shows a cross-sectional representation of a package structure, in accordance with some embodiments of the disclosure.

FIG. 23 shows a cross-sectional representation of a package structure, in accordance with some embodiments of the disclosure.

FIG. 24 shows a cross-sectional representation of a package structure, in accordance with some embodiments of the disclosure.

FIG. 25 shows a cross-sectional representation of a package structure, in accordance with some embodiments of the disclosure.

FIG. 26 shows a cross-sectional representation of a package structure, in accordance with some embodiments of the disclosure.

FIG. 27 shows a cross-sectional representation of a package structure, in accordance with some embodiments of the disclosure.

FIG. 28 shows a cross-sectional representation of a package structure, in accordance with some embodiments of the disclosure.

FIG. 29 shows a cross-sectional representation of a package structure, in accordance with some embodiments of the disclosure.

FIG. 30 shows a cross-sectional representation of a package structure, in accordance with some embodiments of the disclosure.

FIG. 31 shows a cross-sectional representation of a package structure, in accordance with some embodiments of the disclosure.

FIG. 32 shows a cross-sectional representation of a package structure, in accordance with some embodiments of the disclosure.

FIG. 33 shows a cross-sectional representation of a package structure, in accordance with some embodiments of the disclosure.

FIG. 34 shows a cross-sectional representation of a package structure, in accordance with some embodiments of the disclosure.

FIG. 35 shows a cross-sectional representation of a package structure, in accordance with some embodiments of the disclosure.

FIG. 36 shows a cross-sectional representation of a package structure, in accordance with some embodiments of the disclosure.

FIG. 37 shows a cross-sectional representation of a package structure, in accordance with some embodiments of the disclosure.

FIG. 38 shows a cross-sectional representation of a package structure, in accordance with some embodiments of the disclosure.

FIG. 39 shows a cross-sectional representation of a package structure, in accordance with some embodiments of the disclosure.

FIG. 40 shows a cross-sectional representation of a package structure, in accordance with some embodiments of the disclosure.

FIG. 41 shows a cross-sectional representation of a package structure, in accordance with some embodiments of the disclosure.

FIG. 42 shows a cross-sectional representation of a package structure, in accordance with some embodiments of the disclosure.

FIG. 43 shows a cross-sectional representation of a package structure, in accordance with some embodiments of the disclosure.

FIG. 44 shows a cross-sectional representation of a package structure, in accordance with some embodiments of the disclosure.

FIGS. 45A to 45L illustrate cross-sectional representations of various stages of manufacturing a package structure, in accordance with some embodiments.

FIG. 46 shows a cross-sectional representation of a package structure, in accordance with some embodiments of the disclosure.

FIG. 47 shows a cross-sectional representation of a package structure, in accordance with some embodiments of the disclosure.

FIG. 48 shows a cross-sectional representation of a package structure, in accordance with some embodiments of the disclosure.

FIG. 49 shows a cross-sectional representation of a package structure, in accordance with some embodiments of the disclosure.

FIG. 50 shows a cross-sectional representation of a package structure, in accordance with some embodiments of the disclosure.

FIG. 51 shows a cross-sectional representation of a package structure, in accordance with some embodiments of the disclosure.

FIG. 52A illustrates a top-view representation of a package structure, in accordance with some embodiments.

FIG. 52B illustrate a cross-sectional representation of the package structure shown along line A-A′ in FIG. 52A, in accordance with some embodiments.

FIG. 52C illustrate a cross-sectional representation of the package structure shown along line B-B′ in FIG. 52A, in accordance with some embodiments.

FIG. 53A illustrates a top-view representation of a package structure, in accordance with some embodiments.

FIG. 53B illustrate a cross-sectional representation of the package structure shown along line A-A′ in FIG. 52A, in accordance with some embodiments.

FIG. 53C illustrate a cross-sectional representation of the package structure shown along line B-B′ in FIG. 52A, in accordance with some embodiments.

FIG. 54A illustrates a top-view representation of a package structure, in accordance with some embodiments.

FIG. 54B illustrate a cross-sectional representation of the package structure shown along line A-A′ in FIG. 52A, in accordance with some embodiments.

FIG. 54C illustrate a cross-sectional representation of the package structure shown along line B-B′ in FIG. 52A, in accordance with some embodiments.

FIG. 55A illustrates a top-view representation of a package structure, in accordance with some embodiments.

FIG. 55B illustrate a cross-sectional representation of the package structure shown along line A-A′ in FIG. 52A, in accordance with some embodiments.

FIG. 55C illustrate a cross-sectional representation of the package structure shown along line B-B′ in FIG. 52A, in accordance with some embodiments.

FIG. 56A illustrates a top-view representation of a package structure, in accordance with some embodiments.

FIG. 56B illustrate a cross-sectional representation of the package structure shown along line A-A′ in FIG. 52A, in accordance with some embodiments.

FIG. 56C illustrate a cross-sectional representation of the package structure shown along line B-B′ in FIG. 52A, in accordance with some embodiments.

FIG. 57A illustrates a top-view representation of a package structure, in accordance with some embodiments.

FIG. 57B illustrate a cross-sectional representation of the package structure shown along line A-A′ in FIG. 52A, in accordance with some embodiments.

FIG. 57C illustrate a cross-sectional representation of the package structure shown along line B-B′ in FIG. 52A, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments for a package structure and method for forming the same are provided. The package structure includes a composite die including an optical package structure (e.g. photonic integrated circuit (PIC)) and an electronic die (e.g. electronic integrated circuit (EIC)) and an optical die adjacent to the composite die. The composite die and the optical die are formed on the top interposer, and the top interposer is shared by the composite die and the optical die. Since the optical die is adjacent to the composite die, the alignment accuracy between the optical die and the composite die become easier. Furthermore, the optical die provides a build-in light source to improve the optical coupling efficiency.

In addition, the optical die is configured to provide the light to the composite die, rather than from the external environment, the light loss is reduced, and the light efficiency is greatly improved. Therefore, the performance and the reliability of the package structure are further improved.

The embodiments may be applied to, but are not limited to, embodiments, that include, a chip-on-a-wafer-on-substrate (CoWoS) package structure that includes the optical package structure and the electronic die.

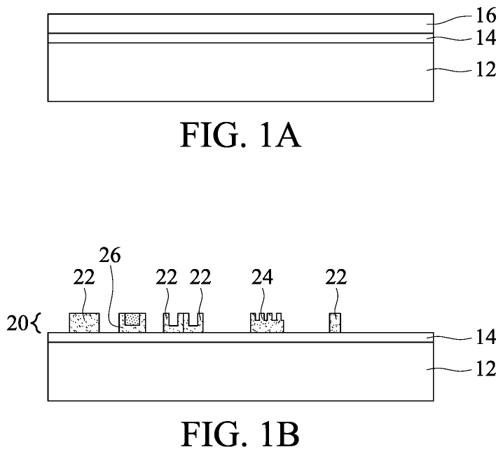

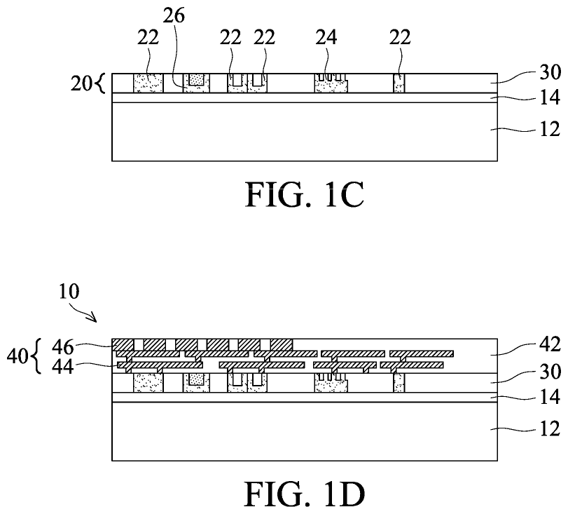

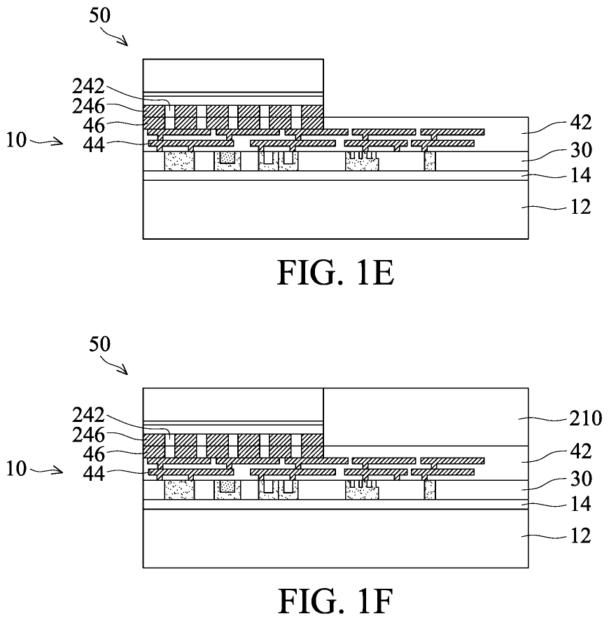

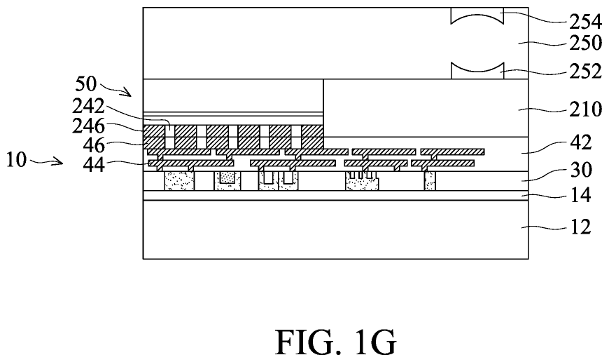

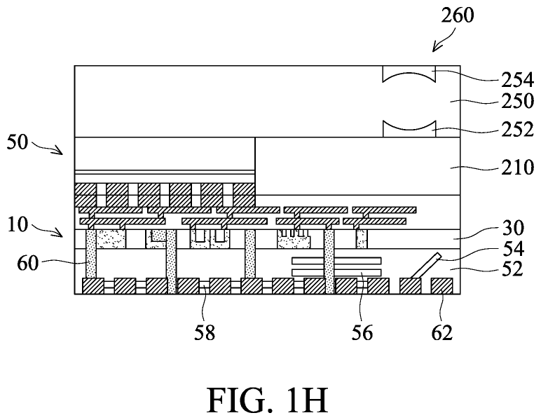

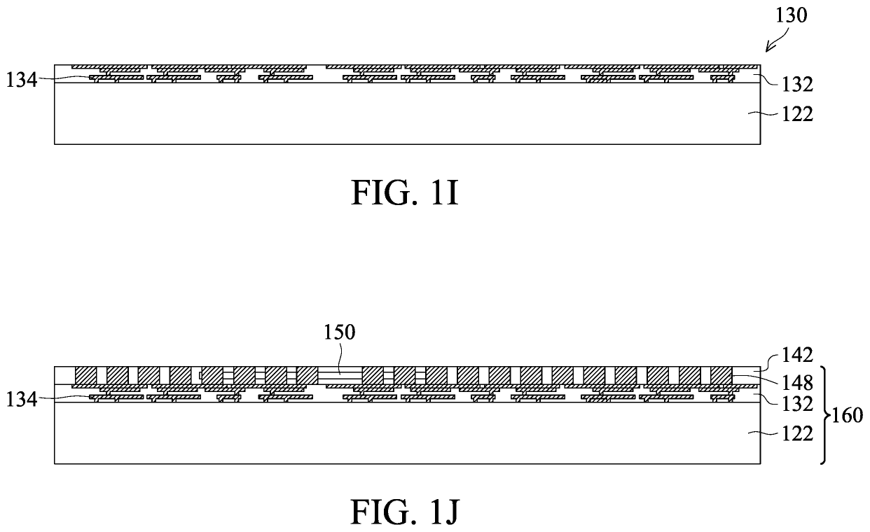

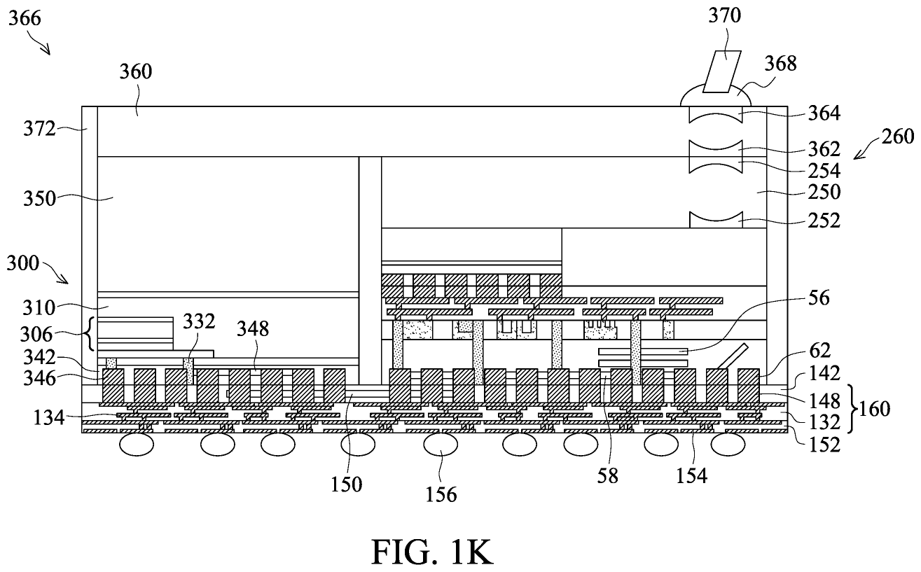

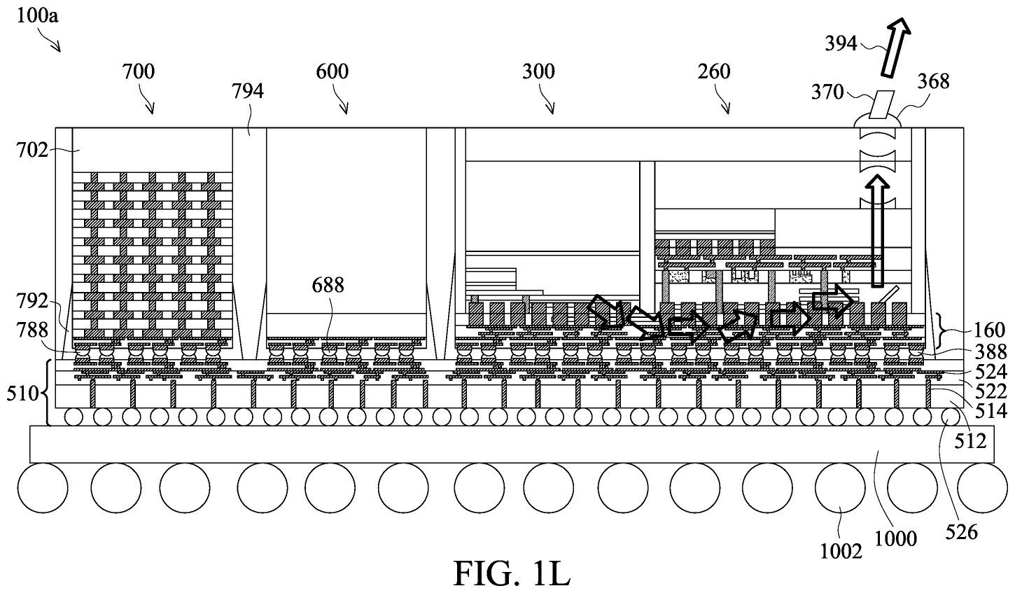

FIGS. 1A to 1L illustrate cross-sectional representations of various stages of manufacturing a package structure 100a, in accordance with some embodiments.

As shown in FIG. 1A, an optical package structure 10 (seen in FIG. 1D) is formed by step FIG. 1A to FIG. 1C and includes forming a substrate 12, an insulator layer 14 and a silicon layer 16, in accordance with some embodiments. In some embodiments, the optical package structure 10 is an optical interposer. In some embodiments, the optical package structure 10 is in a wafer form.

The insulator layer 14 is formed over the substrate 12, and the silicon layer 16 is formed over the insulator layer 14. In some embodiments, the substrate 12, the insulator layer 14, and the silicon layer 16 are collectively be part of a silicon-on-insulator (SOI) substrate.

The substrate 12 may be a semiconductor wafer such as a silicon wafer. Alternatively or additionally, the substrate 12 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GalnP, and/or GaInAsP.

The insulator layer 14 may be silicon oxide, silicon nitride, germanium oxide, germanium nitride, combinations of these, or another applicable material. In some embodiments, the insulator layer 14 is formed using thermal oxidation, chemical vapor deposition (CVD), atomic vapor deposition (ALD), physical vapor deposition (PVD), another suitable method, or a combination thereof.

Next, as shown in FIG. 1B, the silicon layer 16 is patterned to form optical components 20, in accordance with some embodiments. The various optical components 20 are used to form a photonic integrated circuit (PIC). The optical components 20 include optical waveguides (e.g., ridge waveguides, rib waveguides, buried channel waveguides, diffused waveguides, slab waveguides etc.), couplers (e.g., grating couplers, edge couplers, etc.), optical switches (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. The optical components 20 are formed by a patterning process. The patterning process includes a photolithography process and an etching process. The photolithography process includes photoresist coating (e.g., spin-on coating), soft baking, mask aligning, exposure, post-exposure baking, developing the photoresist, rinsing and drying (e.g., hard baking). The etching process may include a dry etching process or a wet etching process.

In some embodiments, the optical components 20 include waveguides 22, couplers 24, and modulators 26.

The waveguides 22 is used to guide electromagnetic waves with minimal loss of energy by restricting the transmission of energy to two dimensions. In some embodiments, the multiple waveguides is formed and they are connected as a single continuous structure.

The couplers 24 may be integrated with the waveguides 22, and may be formed with the waveguides 22. The couplers 24 are photonic structures that allow optical signals and/or optical power to be transferred between the waveguides 22. In some embodiments, the couplers 24 include grating couplers, which allow optical signals and/or optical power to be transferred between the waveguides 22.

Modulators 26 are optically coupled to the waveguides 22 to receive electrical signals and generate corresponding optical signals within the waveguides 22 by modulating optical power within the waveguides 22. The modulators 26 may include the germanium modulator over the modulators 26. In some embodiments, the germanium modulator is formed by partially etching a portion of the silicon layer 16 to form a recess and growing an epitaxial material in the recess on the remaining silicon layer 16. The silicon layer 16 may be etched using photolithography and etching techniques. The epitaxial material may include a semiconductor material, such as doped or undoped germanium (Ge).

Although the configurations or arrangements of the optical component 20 including the waveguides 22, the couplers 24 and the modulators 26 are shown in FIG. 1B, the configurations or arrangements of optical component 20 may be adjusted according to actual application.

Afterwards, as shown in FIG. 1C, a dielectric layer 30 is formed on the optical component 20, in accordance with some embodiments. More specifically, the dielectric layer 30 is formed on the waveguides 22, the couplers 24, the modulators 26. The dielectric layer 30 is used to separate the individual optical components 20.

In some embodiments, the dielectric layer 30 includes silicon oxide, silicon nitride, silicon oxynitride (SiON), or a combination thereof. In some embodiments, the dielectric layer 30 is formed using thermal oxidation, chemical vapor deposition (CVD), atomic vapor deposition (ALD), physical vapor deposition (PVD), another suitable method, or a combination thereof. In some embodiments, the refractive index of the dielectric layer 30 is in a range from 1.4 to about 2.2. When the refractive index of the waveguides 22, the couplers 24 and the modulators 26 is higher than the refractive index of the dielectric layer 30, the light can be confined in the waveguides 22, the couplers 24, the modulators 26. When the waveguides 22, the couplers 24, the modulators 26 are made of Si, and the refractive index of Si is about 3.4.

Next, as shown in FIG. 1D, an interconnect structure 40 is formed over the dielectric layer 30, in accordance with some embodiments. The interconnect structure 40 includes conductive layers 44 and conductive pads 46 embedded in a dielectric layer 42. The interconnect structure 40 may be used as a redistribution (RDL) structure for routing. Therefore, the optical package structure 10 is formed to have optical components 20 and interconnect structure 40 for connecting other dies or chips.

It should be noted that one or more optical components may be formed in the dielectric layer 42 of the interconnect structure 40. The optical components may include optical waveguides (e.g., ridge waveguides, rib waveguides, buried channel waveguides, diffused waveguides, slab waveguides etc.), couplers (e.g., grating couplers, edge couplers, etc.), optical switches (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like.

In some embodiments, the dielectric layer 42 include silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. In some embodiments, the dielectric layer 42 is formed using thermal oxidation, chemical vapor deposition (CVD), atomic vapor deposition (ALD), physical vapor deposition (PVD), another suitable method, or a combination thereof.

In some embodiments, the conductive layers 44 and the conductive pads 46 are made of conductive materials, such as copper (Cu), copper alloy, aluminum (Al), aluminum alloys, combinations thereof or another applicable material. In some embodiments, the conductive layers 44 and the conductive pads 46 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

Afterwards, as shown in FIG. 1E, an electronic die 50 is bonded to the optical package structure 10, in accordance with some embodiments. In some embodiments, the electronic die 50 is an electronic integrated circuit (EIC). The electronic die 50 includes conductive pads 246 embedded in dielectric layer 242, and the conductive pads 246 are for bonding to the interconnect structure 40.

The electronic die 50 may include integrated circuits for interfacing with the various photonic components formed in the dielectric layer 42 of the interconnect structure 40 or in the dielectric layer 30 of the optical package structure 10. The electronic die 50 is used to communicate with one or more of the photonic components 20 in the optical package structure 10 using electrical signals.

In some embodiments, the electronic die 50 includes suitable device, such as a xPU, a logic die, a 3DIC die, a CPU, a GPU, a SoC die, a MEMS die, or a combination thereof. Although one electronic die 50 is formed in FIG. 1E, but two or more electronic dies 50 may be bonded to the interconnect structure 40.

Before the electronic die 50 and the optical package structure 10 are bonded together, a surface treatment is performed to active the surfaces of the conductive pads 246 and the conductive pads 46. In some embodiments, the surface treatment includes a dry treatment, a wet treatment, a plasma treatment, exposure to an inert gas, exposure to H₂, exposure to N₂, exposure to O₂, the like, or combinations thereof. After the surface treatment, a cleaning process is performed on the electronic die 50 and the optical package structure 10. Afterwards, the electronic die 50 and the optical package structure 10 are aligned, such that the conductive pads 246 of electronic die 50 can be bonded to the conductive pads 46 of the optical package structure 10, and the dielectric layer 242 can be bonded to the dielectric layer 42 of the interconnect structure 40 of the optical package structure 10. In some embodiments, the alignment of the electronic die 50 and the optical package structure 10 may be achieved by using an optical sensing method.

After the alignment is performed, the electronic die 50 and the optical package structure 10 are bonded together by a hybrid bonding structure. The hybrid bonding structure involves at least two types of bonding structures, including metal-to-metal bonding structure and non-metal-to-non-metal bonding structure. The metal-to-metal bonding structure includes conductive pads 246 of electronic die 50 bonded to the conductive pads 46 of the optical package structure 10. The non-metal-to-non-metal bonding structure includes the dielectric layer 242 of electronic die 50 bonded to the dielectric layer 42 of the interconnect structure 40 of the optical package structure 10. The electronic die 50 and the optical package structure 10 are hybrid bonded together by the application of pressure and heat.

Next, as shown in FIG. 1F, a dielectric layer 210 formed on the optical package structure 10 and adjacent to the electronic die 50, in accordance with some embodiments. In some embodiments, the dielectric layer 210 is an oxide layer. The top surface of the electronic die 50 is substantially coplanar with the top surface of the dielectric layer 210.

Afterwards, as shown in FIG. 1G, a supporting substrate 250 is formed on the electronic die 50 and the dielectric layer 210, in accordance with some embodiments. The lens 252 and 254 are pre-formed in the supporting substrate 250 before the supporting substrate 250 is formed on the electronic die 50 and the dielectric layer 210.

The supporting substrate 250 is configured to provide mechanical and structural support during subsequent processing steps. The supporting substrate 250 includes glass, silicon oxide, aluminum oxide, metal, a combination thereof, and/or the like.

Next, as shown in FIG. 1H, after the supporting substrate 250 is formed, the substrate 12 and the insulator 14 are removed to expose the optical components 20, in accordance with some embodiments. Next, a dielectric layer 52 is formed on the exposed surface of the optical components 20, and the vias 60 are formed through the dielectric layer 30 and the dielectric layer 52. As a result, a composite die 260 including the optical package structure 10 and the electronic die 50 is formed.

The openings are formed through the dielectric layer 30 and the dielectric layer 52 by the patterning process. The patterning process includes a photolithography process and an etching process. The photolithography process includes photoresist coating (e.g., spin-on coating), soft baking, mask aligning, exposure, post-exposure baking, developing the photoresist, rinsing and drying (e.g., hard baking). The etching process may include a dry etching process or a wet etching process. Afterwards, the barrier layer and a conductive material are formed in the opening to form the vias 60.

The mirror 54 and the optical components 56, 58 and are formed in the dielectric layer 52. The optical components 56, 58 may include optical waveguides (e.g., ridge waveguides, rib waveguides, buried channel waveguides, diffused waveguides, slab waveguides etc.), couplers (e.g., grating couplers, edge couplers, etc.), optical switches (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. In some embodiments, the optical components 56, 58 include optical waveguides, and the optical waveguides are made of SiN.

The conductive pads 62 are formed in the dielectric layer 52. The conductive pads 62 is configured to bond to another conducive pad to form the hybrid bonding structure.

In some embodiments, the dielectric layer 52 include silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. In some embodiments, the dielectric layer 52 is formed using thermal oxidation, chemical vapor deposition (CVD), atomic vapor deposition (ALD), physical vapor deposition (PVD), another suitable method, or a combination thereof. In some embodiments, the refractive index of the dielectric layer 52 is in a range from 1.4 to about 2.2.

In some embodiments, the conductive pads 62 are made of conductive materials, such as copper (Cu), copper alloy, aluminum (Al), aluminum alloys, combinations thereof or another applicable material. In some embodiments, the conductive pads 62 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

Afterwards, as shown in FIG. 1I, an interconnect structure 130 is formed on a substrate 122, in accordance with some embodiments. The interconnect structure 130 includes conductive layers 134 embedded in a dielectric layer 132. The interconnect structure 130 may be used as a redistribution (RDL) structure for routing.

The substrate 122 may be a semiconductor wafer such as a silicon wafer. Alternatively or additionally, the substrate 122 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

The dielectric layer 132 include silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. In some embodiments, the dielectric layer 132 is formed using thermal oxidation, chemical vapor deposition (CVD), atomic vapor deposition (ALD), physical vapor deposition (PVD), another suitable method, or a combination thereof.

In some embodiments, the conductive layers 134 are made of conductive materials, such as copper (Cu), copper alloy, aluminum (Al), aluminum alloys, combinations thereof or another applicable material. In some embodiments, the conductive layers 134 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

Next, as shown in FIG. 1J, the dielectric layer 142 is formed on the dielectric layer 132, and conductive pads 148 and optical components 150 are formed in the dielectric layer 142 to form a top interposer 160, in accordance with some embodiments. The optical component 150 may include optical waveguides (e.g., ridge waveguides, rib waveguides, buried channel waveguides, diffused waveguides, slab waveguides etc.), couplers (e.g., grating couplers, edge couplers, etc.), optical switches (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. In some embodiments, the optical components 150 include optical waveguides, and the optical waveguides are made of SiN.

By forming the optical components 150, 56 and 58, the optical signal can be transmitted in the horizontal direction through the optical coupling between adjacent optical components 150, 56 and 58. The optical signals are routed within and between the optical die 300 (shown later), the top interposer 160 and the composite die 260. Since the distance between two adjacent optical components 150, 56 and 58 is reduced, the coupling efficiency is greatly improved.

Afterwards, as shown in FIG. 1K, an optical die 300 is provided, and a supporting substrate 350 is formed on the optical die 300. The composite die 260 and the optical die 300 are bonded to the top interposer 160 by a hybrid bonding structure to form a connection die 366, in accordance with some embodiments. Next, a supporting substrate 360 is formed on the supporting substrate 250 and the supporting substrate 350. The supporting substrate 360 includes lens 326 and 364. An optical gel 368 is formed on the supporting substrate 360, and an optical fiber 370 is formed on the optical gel 368. The optical die 300 is configured to provide the light to the composite die 260, rather than from the external environment, the light loss is reduced, and the light efficiency is greatly improved. In addition, the form factor of the package structure 100a is reduced.

Next, a package layer 372 is formed to surround the composite die 260 and the optical die 300. Afterwards, the conductive connectors 156 are formed below the top interposer 160.

The composite die 260 is bonded to the top interposer 160 by bonding the conductive pads 62 to the conductive pads 148, and bonding the dielectric layer 52 to the dielectric layer 142.

The optical die 300 includes main optical structure 306 formed in a dielectric layer 310, the vias 332 formed through a dielectric layer 342. In addition, conductive pads 346 and optical components 348 are formed in the dielectric layer 342. In some embodiments, the optical die 300 is a laser die. The optical die 300 is bonded to the top interposer 160 by bonding the conductive pads 346 to the conductive pads 148, and bonding the dielectric layer 342 to the dielectric layer 142.

The optical component 348 may include optical waveguides (e.g., ridge waveguides, rib waveguides, buried channel waveguides, diffused waveguides, slab waveguides etc.), couplers (e.g., grating couplers, edge couplers, etc.), optical switches (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. In some embodiments, the optical components 348 include optical waveguides, and the optical waveguides are made of SiN. By forming the optical components 348, 150, 56 and 58, the optical signal can be transmitted in the horizontal direction through the optical coupling between adjacent optical components 348, 150, 56 and 58. The optical signals are routed within and between the optical die 300, the top interposer 160 and the composite die 260.

The conductive connector 156 may be made of copper, a copper alloy, or another suitable material. In some embodiments, the conductive connectors 156 are formed by electroplating, electroless plating, printing, a chemical vapor deposition (CVD) process, a physical vapor process, or another applicable process.

Next, as shown in FIG. 1L, the top interposer 160 is bonded to a bottom interposer 510, and a semiconductor die 600 and a semiconductor die 700 are bonded to the bottom interposer 510, in accordance with some embodiments of the disclosure. In some embodiments, the semiconductor die 600 is an ASIC (application Specific Integrated Circuit) die, and the semiconductor die 700 is a memory die.

The bottom interposer 510 includes a substrate 512, through-substrate via (TSV) structures 514 formed in the substrate 512, a dielectric layer 522 and conductive layers 524. The dielectric layer 522 is formed on the substrate 512, and the conductive layers 524 are formed in the dielectric layer 522.

The top interposer 160 is bonded to the bottom interposer 510 by bonding conductive connectors 388. The semiconductor die 600 is bonded to the bottom interposer 510 by bonding conductive connectors 688.

The semiconductor die 700 is bonded to the bottom interposer 510 by bonding conductive connectors 788. The semiconductor die 700 may include memory dies in the form of a die stack, and a substrate 702 on the memory dies.

The bottom interposer 510 is bonded to a substrate 1000 by conductive connectors 526, and conductive connectors 1002 are formed below the substrate 1000.

The arrows 394 represent a general direction that the optical signals are routed within and between the optical fiber 370, the composite die 260 and the optical die 300, and do not necessarily represent the exact path that the optical signals travel through.

The composite die 260 includes the optical package structure 10 bonded to the electronic die 50. The composite die 260 and the optical die 300 are bonded to the top interposer 160 by the hybrid bonding structure. The top interposer 160 is shared by the composite die 260 and the optical die 300. The optical die 300 is configured to provide the light to the composite die 260, rather than from the external environment, the light loss is reduced, and the light efficiency is greatly improved. In addition, the form factor of the package structure 100a is reduced.

Furthermore, the optical components 348 are formed in the optical die 300, the optical components 150 are formed in the top interposer 160, and the optical components 56 and 58 are formed in the optical package structure 10. By forming the optical components 348, 150, 56 and 58, the optical signal can be transmitted in the horizontal direction through the optical coupling between adjacent optical components 348, 150, 56 and 58. The optical signals are routed within and between the optical die 300, the top interposer 160 and the composite die 260. Since the distance between two adjacent optical components 348, 150, 56 and 58 is reduced, the coupling efficiency is greatly improved. The optical signal transmission speed is improved by forming the optical die 300 adjacent to the composite die 260. Therefore, the performance, the reliability and yield of the package structure 100a is further improved.

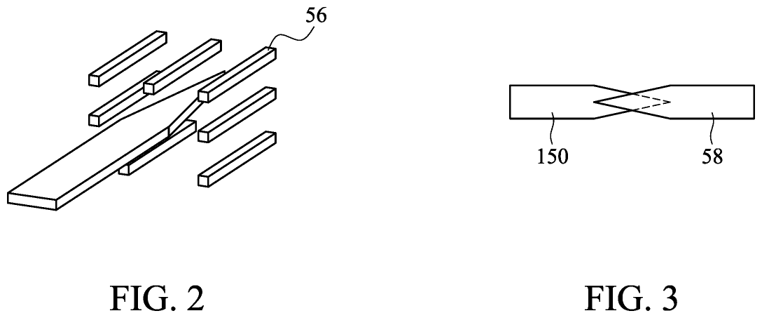

FIG. 2 shows an enlarged cross-sectional representation of a region A of the package structure of FIG. 1K, in accordance with some embodiments. As shown in FIG. 2, the optical components 56 are stacked vertically and separated from each other. By forming the numbers of the optical components 56, the optical signal can be transmitted in the horizontal direction through the optical coupling between adjacent optical components 56.

FIG. 3 shows an enlarged cross-sectional representation of a region B of the package structure of FIG. 1K, in accordance with some embodiments. As shown in FIG. 3, the optical components 58 and the optical components 150 are stacked vertically and separated from each other. By forming the optical components 58 and the optical components 150, the optical signal can be transmitted in the horizontal direction through the optical coupling between adjacent optical components 58 and 150.

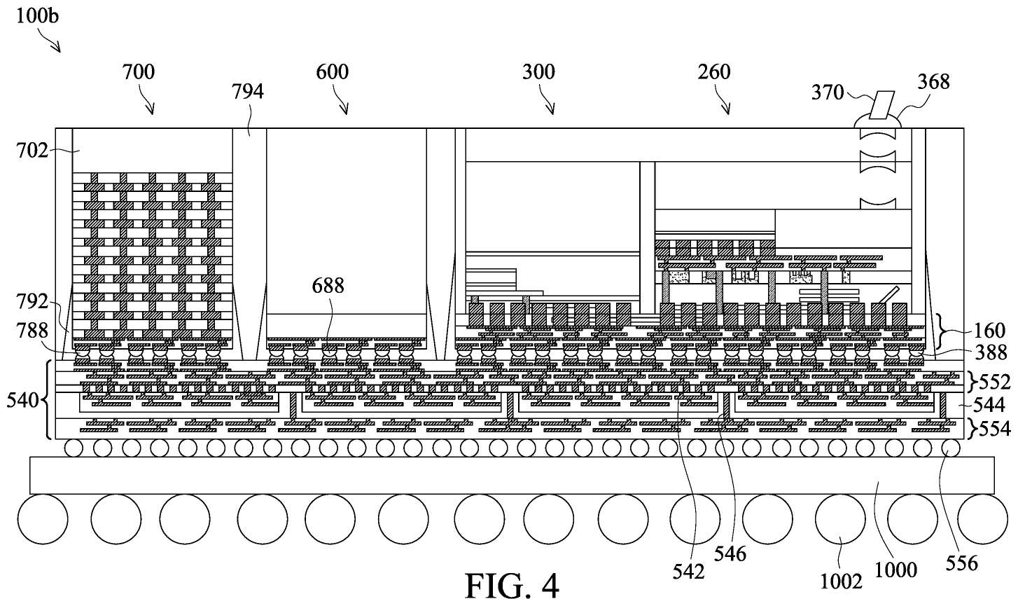

FIG. 4 shows a cross-sectional representation of a package structure 100b, in accordance with some embodiments of the disclosure. The package structure 100b is an alternate embodiment which may be similar to the package structure 100a of FIGS. 1A-1L, where like reference numerals indicate like elements formed using like processes, unless specified otherwise. Processes and materials used to form the package structure 100b may be similar to, or the same as, those used to form the package structure 100a and are not repeated herein.

The package structure 100s differs from the package structure 100a in that the package structure 100b includes a local silicon interconnect (LSI) interposer 540 instead of the bottom interposer 510. The LSI interposer 540 includes one or more LSI die 542 in a package layer 544. A front side interconnect structure 552 and a back side interconnect structure 554 are formed on front side and back side of the LSI die 542. Through vias 546 are formed through the package layer 544 and are electrically connected to the front side interconnect structure 552 and the back side interconnect structure 554. The composite die 260, the optical die 300, the semiconductor die 600 and the semiconductor die 700 are bonded to the LSI interposer 540. The composite die 260, the composite die 300, the semiconductor die 600 and the semiconductor die 700 are electrically connected to each other by the front side interconnect structure 552 and the back side interconnect structure 554 on and below the LSI die 542 in the LSI interposer 540.

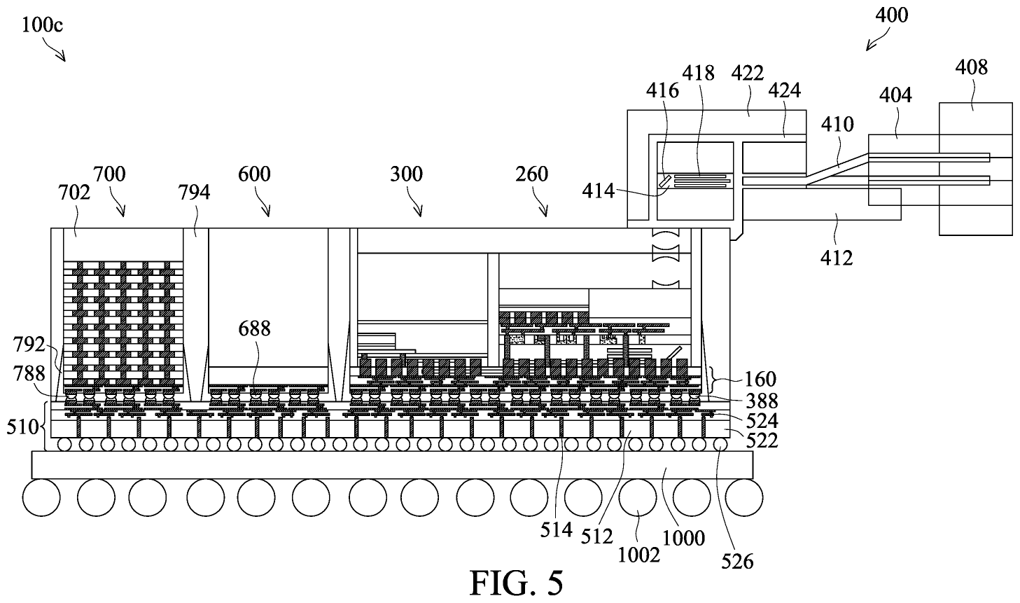

FIG. 5 shows a cross-sectional representation of a package structure 100c, in accordance with some embodiments of the disclosure. The package structure 100c is an alternate embodiment which may be similar to the package structure 100a of FIGS. 1A-1L, where like reference numerals indicate like elements formed using like processes, unless specified otherwise. Processes and materials used to form the package structure 100c may be similar to, or the same as, those used to form the package structure 100a and are not repeated herein.

The difference between FIG. 5 and FIG. 1L is that an optical array 400 is formed on the supporting substrate 360. The optical array 400 is used as an optical input/output port to the optical package structure 100c. In some embodiments, the optical array is an optical array unit (FAU).

The optical array 400 includes an optical fiber 410. The optical fiber 410 is enclosed by cladding layers 404, and the cladding layer 404 is enclosed by fiber stealth 408. In addition, a substrate 412 and a substrate 422 are formed on top surface and the bottom surface of the optical fiber to security the optical fiber 410. The optical gel 424 is filled into the gap between the optical fiber 410 and the substrates 412 and 422. The optical array 400 also includes dielectric layer 414, and mirror 416 and the optical components 418 are formed in the dielectric layer 414.

In some embodiments, the substrate 412 is a Si substrate, and the substrate 422 is a glass substrate. In some embodiments, the dielectric layer 414 is an oxide layer.

In some embodiments, the optical components 418 includes optical waveguides (e.g., ridge waveguides, rib waveguides, buried channel waveguides, diffused waveguides, slab waveguides etc.), couplers (e.g., grating couplers, edge couplers, etc.), optical switches (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like.

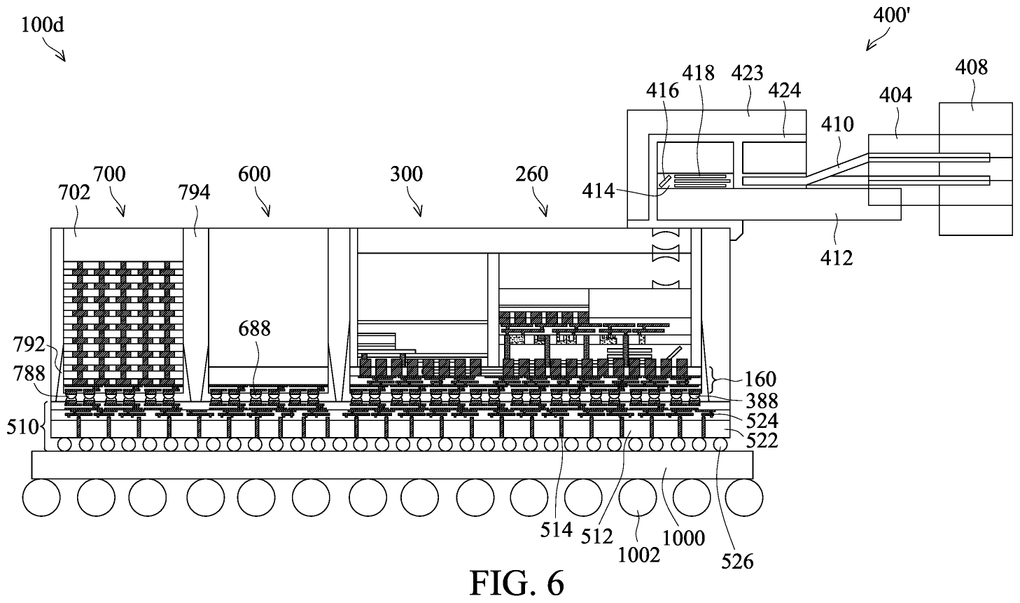

FIG. 6 shows a cross-sectional representation of a package structure 100d, in accordance with some embodiments of the disclosure. The package structure 100d is an alternate embodiment which may be similar to the package structure 100c of FIG. 5, where like reference numerals indicate like elements formed using like processes, unless specified otherwise. Processes and materials used to form the package structure 100d may be similar to, or the same as, those used to form the package structure 100c and are not repeated herein.

The difference between FIG. 6 and FIG. 5 is that an optical array 400′ is formed on the supporting substrate 360. The optical array 400′ is used as an optical input/output port to the optical package structure 100c. The substrate 412 and the substrate 423 are made of the same material. In some embodiments, the substrate 423 of the optical array 400′ is made of Si substrate.

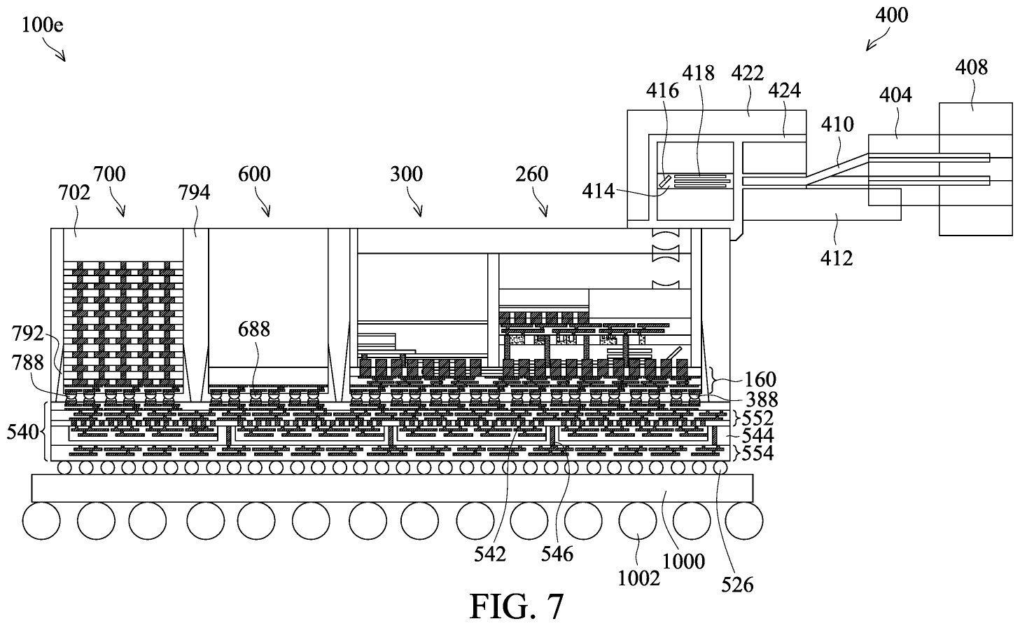

FIG. 7 shows a cross-sectional representation of a package structure 100e, in accordance with some embodiments of the disclosure. The package structure 100e is an alternate embodiment which may be similar to the package structure 100b of FIG. 4, where like reference numerals indicate like elements formed using like processes, unless specified otherwise. Processes and materials used to form the package structure 100e may be similar to, or the same as, those used to form the package structure 100b and are not repeated herein.

The difference between FIG. 7 and FIG. 4 is that the optical array 400 is formed on the supporting substrate 360. The optical array 400 is used as an optical input/output port to the optical package structure 100e.

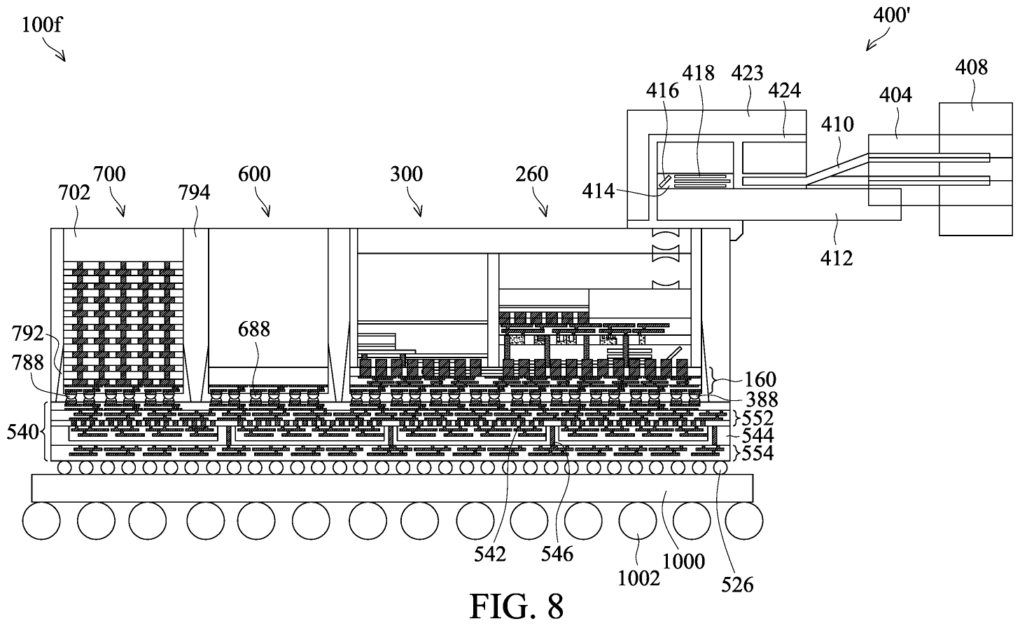

FIG. 8 shows a cross-sectional representation of a package structure 100f, in accordance with some embodiments of the disclosure. The package structure 100f is an alternate embodiment which may be similar to the package structure 100e of FIG. 7, where like reference numerals indicate like elements formed using like processes, unless specified otherwise. Processes and materials used to form the package structure 100f may be similar to, or the same as, those used to form the package structure 100e and are not repeated herein.

The difference between FIG. 8 and FIG. 7 is that an optical array 400′ is formed on the supporting substrate 360. The optical array 400′ is used as an optical input/output port to the optical package structure 100c. The substrate 412 and the substrate 423 are made of the same material. In some embodiments, the substrate 423 of the optical array 400′ is made of a Si substrate.

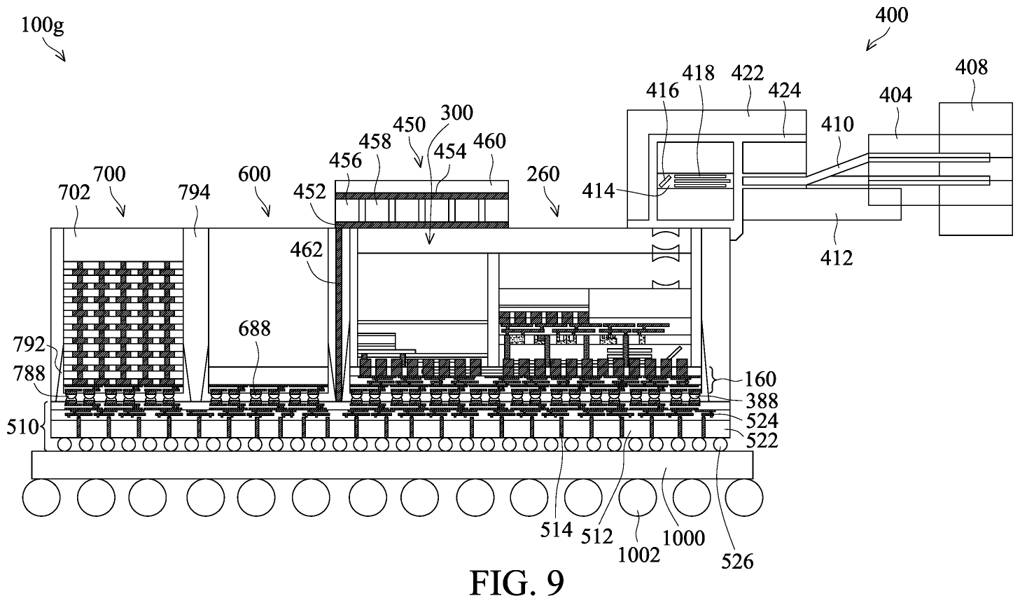

FIG. 9 shows a cross-sectional representation of a package structure 100g, in accordance with some embodiments of the disclosure. The package structure 100g is an alternate embodiment which may be similar to the package structure 100c of FIG. 5, where like reference numerals indicate like elements formed using like processes, unless specified otherwise. Processes and materials used to form the package structure 100g may be similar to, or the same as, those used to form the package structure 100c and are not repeated herein.

The difference between FIG. 9 and FIG. 5 is that a thermal electronic cooler (TEC) 450 is formed on the supporting substrate 360. The TEC 450 is directly formed on the optical die 300. The TEC 450 is configured to transfer heat generated by the optical die 300 or the composite die 260 to the external environment. In addition, a connection structure 462 is between the TEC 450 and the bottom interposer 510. The connection structure 462 is configured to electrically connect the TEC 450 and the bottom interposer 510.

The TEC 450 includes a number of first regions 456 and a number of second regions 458 are between a first plate 452 and a second plate 454. A top substrate 460 is formed on the second plate 454. The first plate 452 and the second plate 454 are heat conductors and electrical insulators.

In some embodiments, the first regions 456 are made of n-type semiconductor material. In some embodiments, the second regions 458 are made of p-type semiconductor material. In some embodiments, the first plate 452 and the second plate 454 are made of ceramic (for example, Be₂TE₃, which is an effective heat conductor and an electrical insulator. The alternating p and n-type semiconductor pillars are placed thermally in parallel to each other and electrically in series and then joined with a thermally conducting plate on each side. When a voltage is applied to the free ends of the two semiconductors there is a flow of DC current across the junction of the semiconductors, causing a temperature difference. The side with the cooling plate absorbs heat which is then transported by the semiconductor to the other side of the device.

In some embodiments, when a DC electric current flows through the TEC 450, it brings heat from one side to the other, so that one side gets cooler while the other gets hotter. In some embodiments, the first plate 452 absorbs heat which is then transported by the first regions 456 and the second regions 458 is transmitted to the second plate 454.

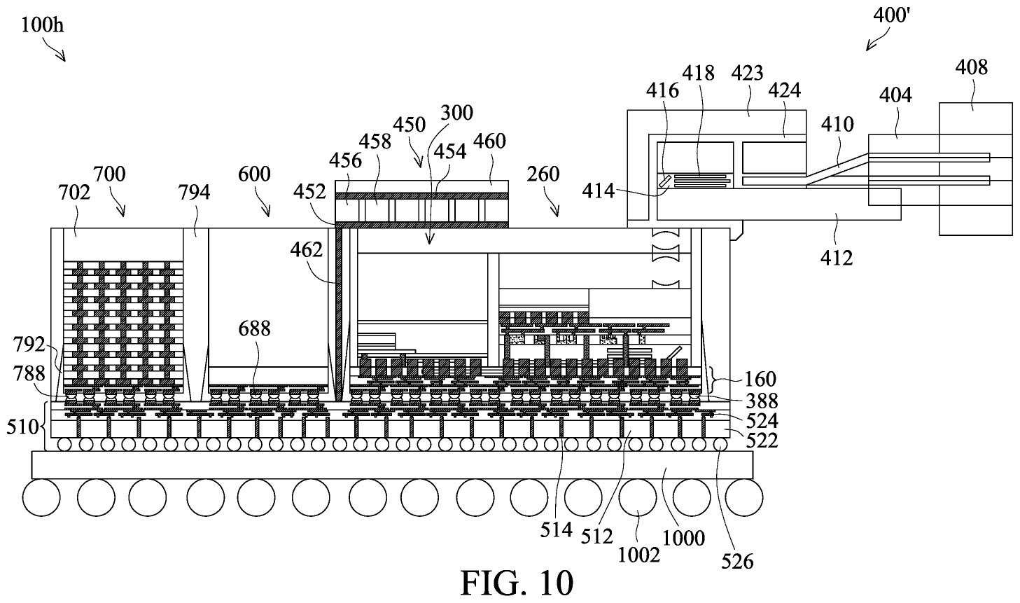

FIG. 10 shows a cross-sectional representation of a package structure 100h, in accordance with some embodiments of the disclosure. The package structure 100h is an alternate embodiment which may be similar to the package structure 100d of FIG. 6, where like reference numerals indicate like elements formed using like processes, unless specified otherwise. Processes and materials used to form the package structure 100h may be similar to, or the same as, those used to form the package structure 100d and are not repeated herein.

The difference between FIG. 10 and FIG. 6 is that the thermal electronic cooler (TEC) 450 is formed on the supporting substrate 360. The TEC 450 is directly formed on the optical die 300. The TEC 450 is configured to transfer heat generated by the optical die 300 or the composite die 260 to the external environment.

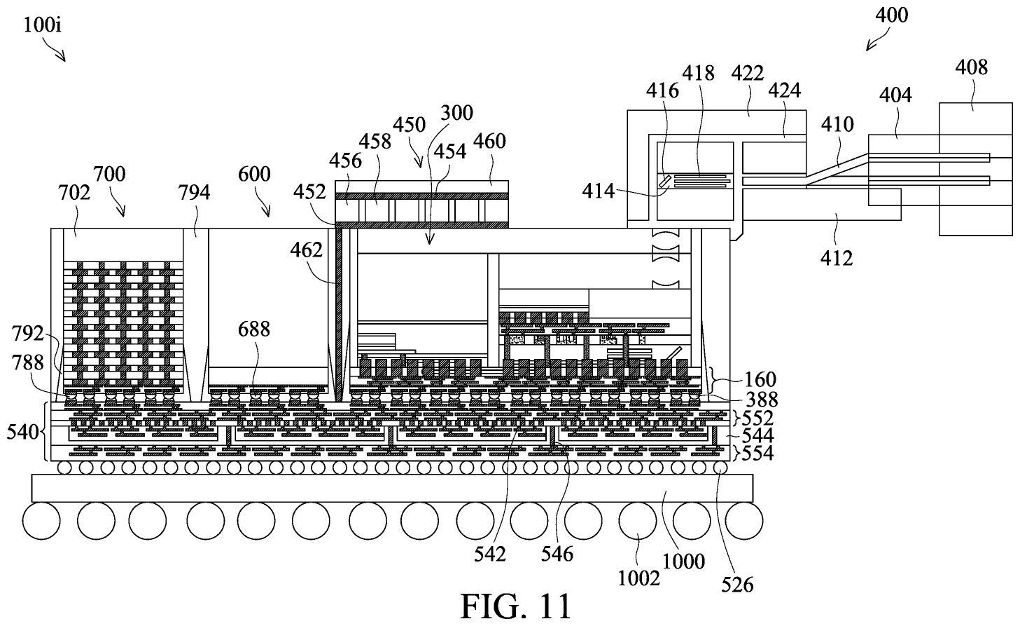

FIG. 11 shows a cross-sectional representation of a package structure 100i, in accordance with some embodiments of the disclosure. The package structure 100i is an alternate embodiment which may be similar to the package structure 100e of FIG. 7, where like reference numerals indicate like elements formed using like processes, unless specified otherwise. Processes and materials used to form the package structure 100i may be similar to, or the same as, those used to form the package structure 100e and are not repeated herein.

The difference between FIG. 11 and FIG. 7 is that the thermal electronic cooler (TEC) 450 is formed on the supporting substrate 360. The TEC 450 is directly formed on the optical die 300. The TEC 450 is configured to transfer heat generated by the optical die 300 or the composite die 260 to the external environment.

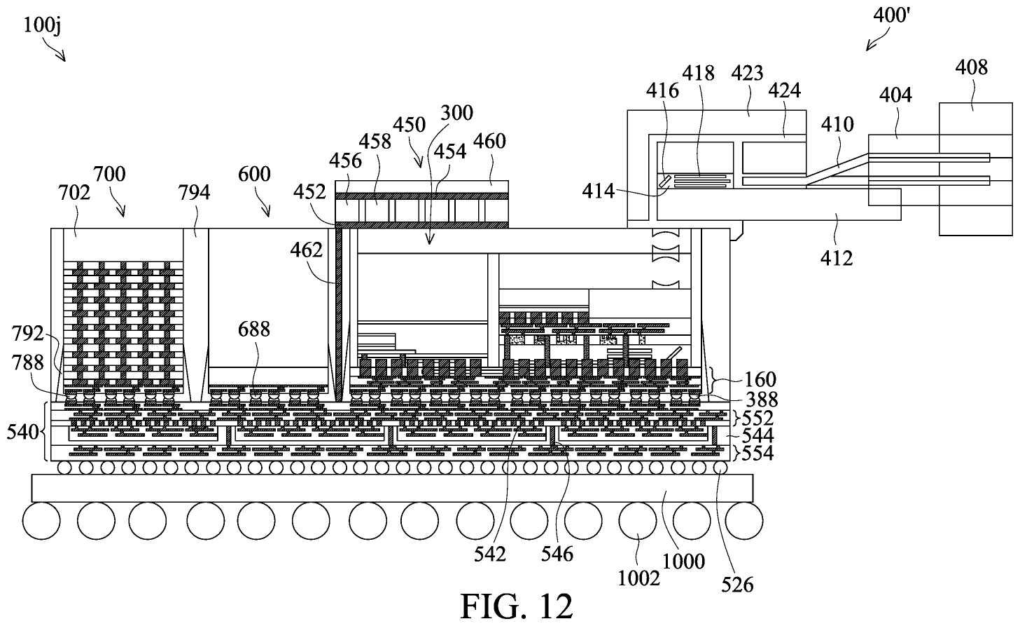

FIG. 12 shows a cross-sectional representation of a package structure 100j, in accordance with some embodiments of the disclosure. The package structure 100j is an alternate embodiment which may be similar to the package structure 100f of FIG. 8, where like reference numerals indicate like elements formed using like processes, unless specified otherwise. Processes and materials used to form the package structure 100j may be similar to, or the same as, those used to form the package structure 100f and are not repeated herein.

The difference between FIG. 12 and FIG. 8 is that the thermal electronic cooler (TEC) 450 is formed on the supporting substrate 360. The TEC 450 is directly formed on the optical die 300. The TEC 450 is configured to transfer heat generated by the optical die 300 or the composite die 260 to the external environment.

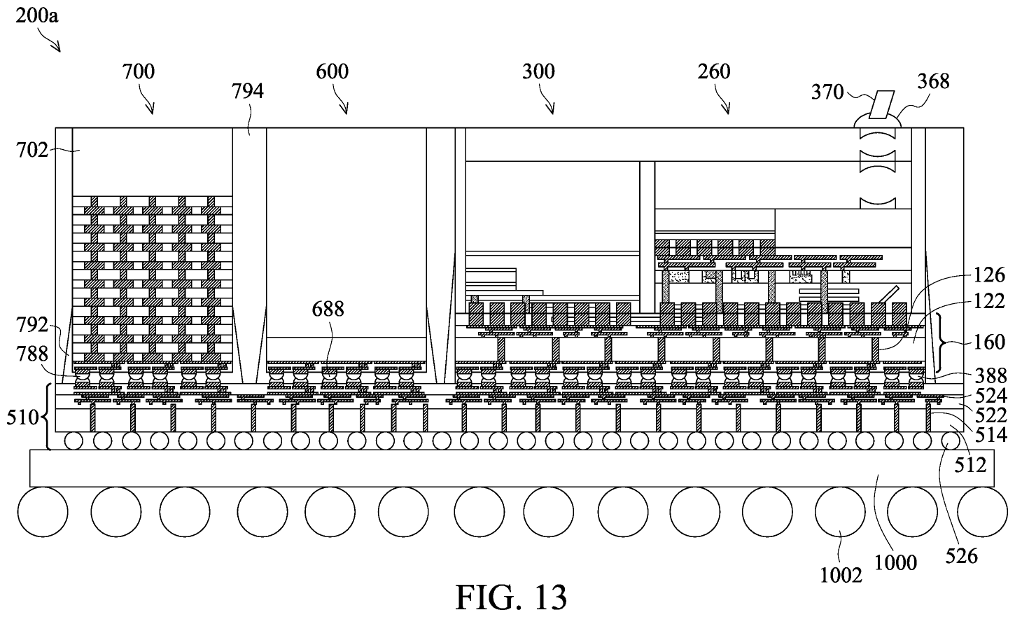

FIG. 13 shows a cross-sectional representation of a package structure 200a, in accordance with some embodiments of the disclosure. The package structure 200a is an alternate embodiment which may be similar to the package structure 100a of FIGS. 1A-1L, where like reference numerals indicate like elements formed using like processes, unless specified otherwise. Processes and materials used to form the package structure 200a may be similar to, or the same as, those used to form the package structure 100a and are not repeated herein.

The difference between FIG. 13 and FIG. 1L is that the top interposer 160 includes through-substrate via (TSV) structures 126 formed in the substrate 122. It should be noted that the substrate 122 is removed in the previous embodiments (e.g. FIGS. 1A-12), but the substrate 122 remains in FIG. 13.

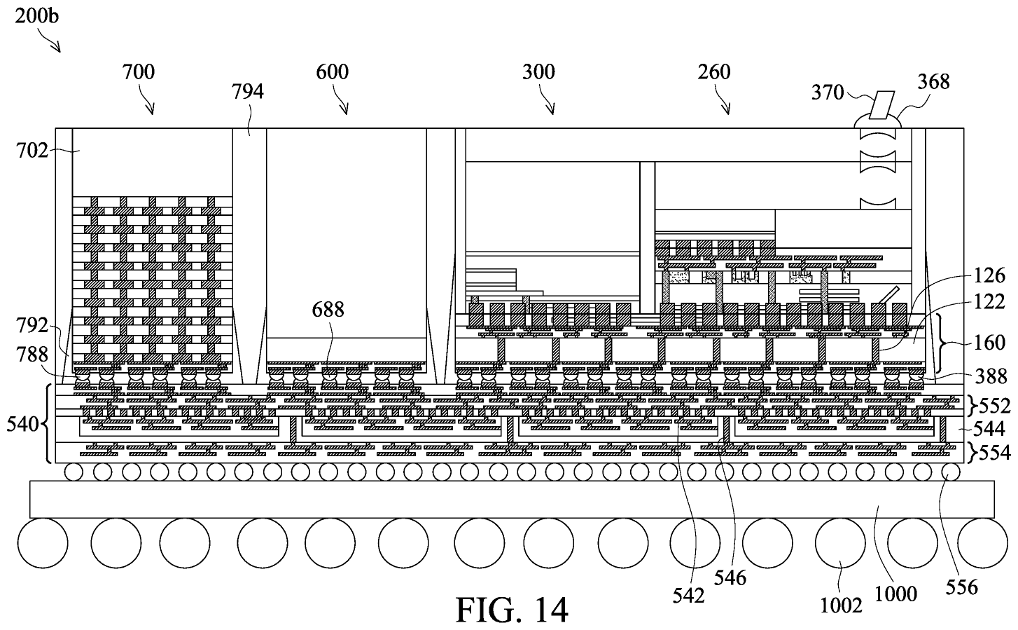

FIG. 14 shows a cross-sectional representation of a package structure 200b, in accordance with some embodiments of the disclosure. The package structure 200b is an alternate embodiment which may be similar to the package structure 100b of FIG. 4, where like reference numerals indicate like elements formed using like processes, unless specified otherwise. Processes and materials used to form the package structure 200b may be similar to, or the same as, those used to form the package structure 100b and are not repeated herein.

The difference between FIG. 14 and FIG. 4 is that the top interposer 160 includes through-substrate via (TSV) structures 126 formed in the substrate 122.

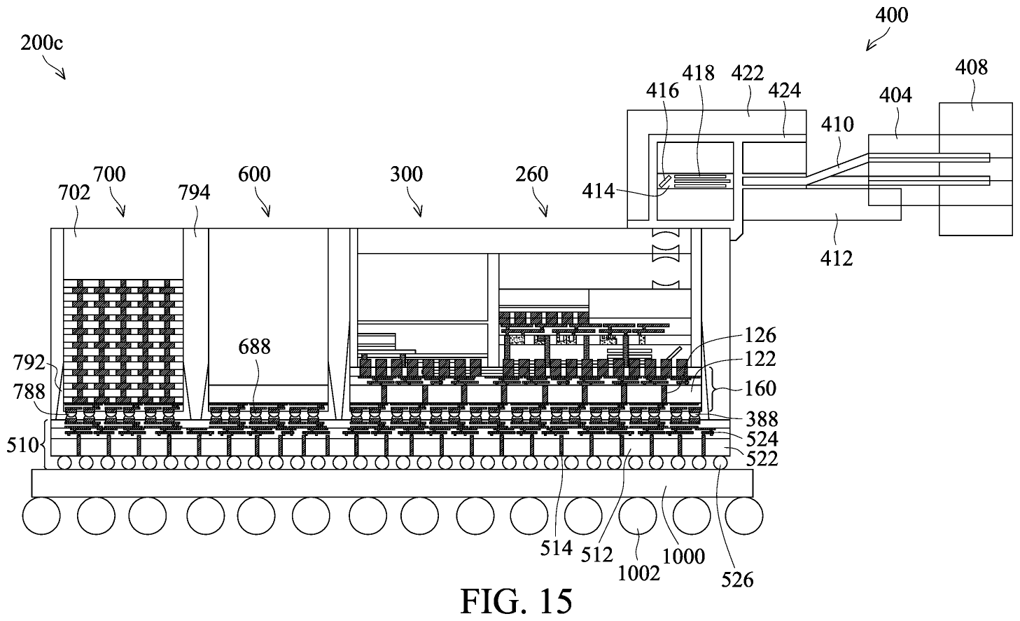

FIG. 15 shows a cross-sectional representation of a package structure 200c, in accordance with some embodiments of the disclosure. The package structure 200c is an alternate embodiment which may be similar to the package structure 200a of FIG. 13, where like reference numerals indicate like elements formed using like processes, unless specified otherwise. Processes and materials used to form the package structure 200c may be similar to, or the same as, those used to form the package structure 200a and are not repeated herein.

The difference between FIG. 15 and FIG. 13 is that the optical array 400 is formed on the supporting substrate 360. The optical array 400 is used as an optical input/output port to the optical package structure 200c.

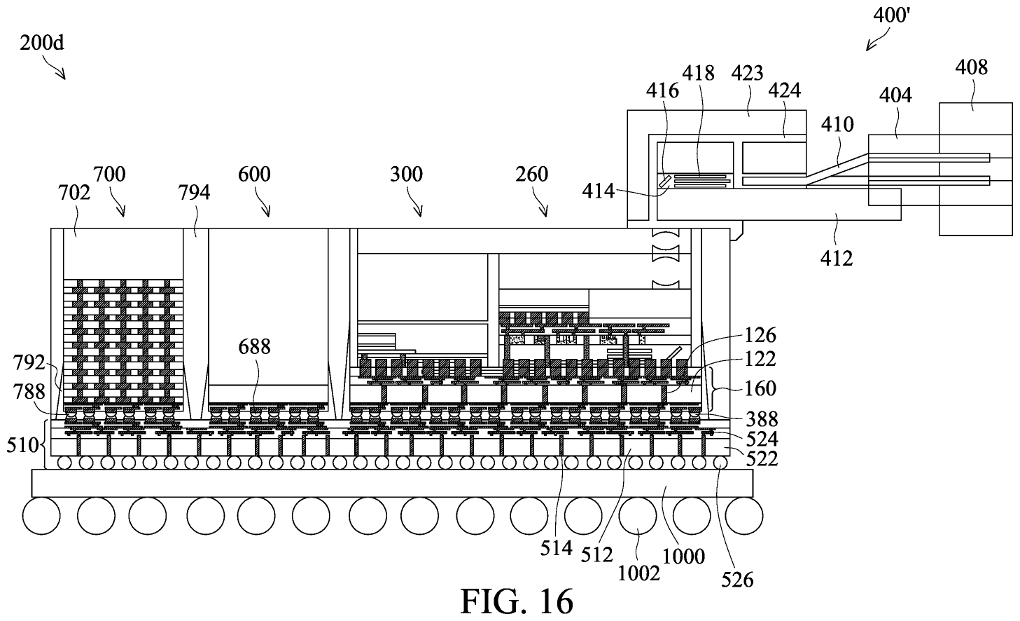

FIG. 16 shows a cross-sectional representation of a package structure 200d, in accordance with some embodiments of the disclosure. The package structure 200d is an alternate embodiment which may be similar to the package structure 200a of FIG. 13, where like reference numerals indicate like elements formed using like processes, unless specified otherwise. Processes and materials used to form the package structure 200d may be similar to, or the same as, those used to form the package structure 200a and are not repeated herein.

The difference between FIG. 16 and FIG. 13 is that an optical array 400′ is formed on the supporting substrate 360. The optical array 400′ is used as an optical input/output port to the optical package structure 100c. The substrate 412 and the substrate 423 are made of the same material. In some embodiments, the substrate 423 of the optical array 400′ is made of Si substrate.

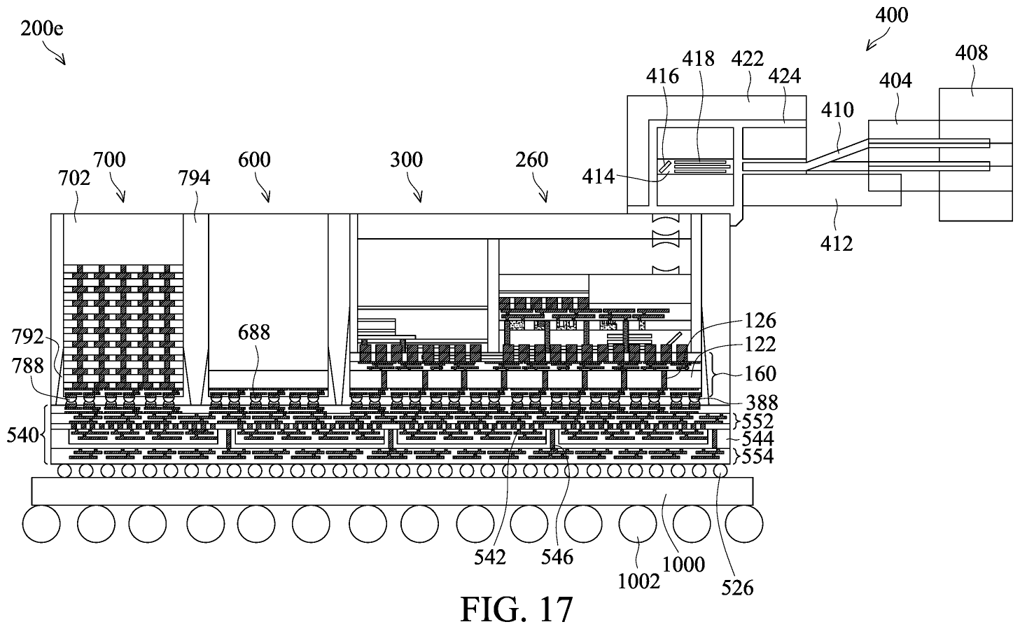

FIG. 17 shows a cross-sectional representation of a package structure 200e, in accordance with some embodiments of the disclosure. The package structure 200e is an alternate embodiment which may be similar to the package structure 200b of FIG. 14, where like reference numerals indicate like elements formed using like processes, unless specified otherwise. Processes and materials used to form the package structure 200e may be similar to, or the same as, those used to form the package structure 200b and are not repeated herein.

The difference between FIG. 17 and FIG. 14 is that the optical array 400 is formed on the supporting substrate 360. The optical array 400 is used as an optical input/output port to the optical package structure 200e.

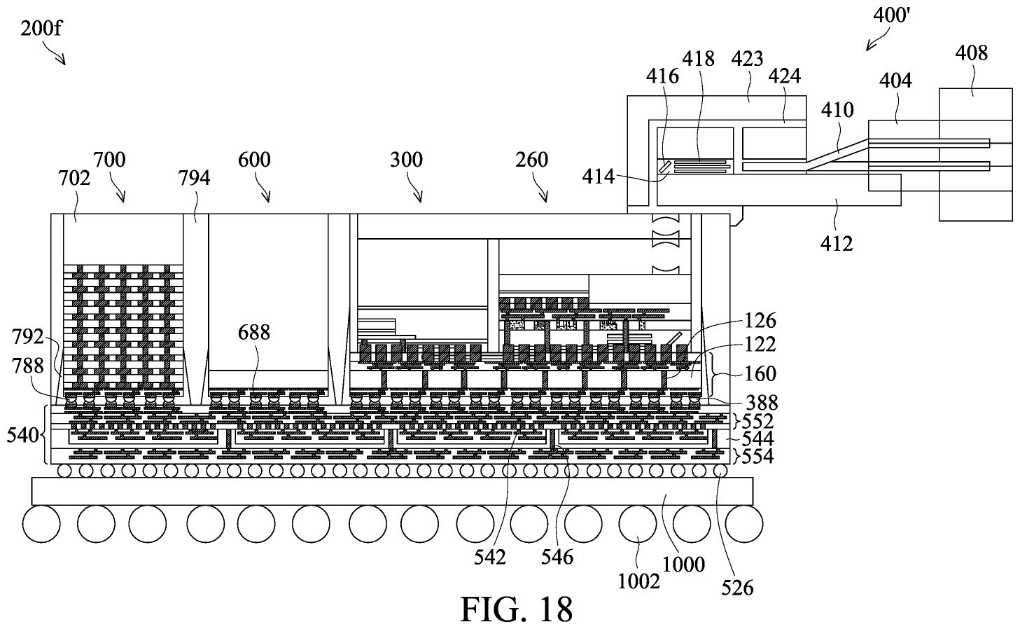

FIG. 18 shows a cross-sectional representation of a package structure 200f, in accordance with some embodiments of the disclosure. The package structure 200f is an alternate embodiment which may be similar to the package structure 200b of FIG. 14, where like reference numerals indicate like elements formed using like processes, unless specified otherwise. Processes and materials used to form the package structure 200f may be similar to, or the same as, those used to form the package structure 200a and are not repeated herein.

The difference between FIG. 18 and FIG. 14 is that an optical array 400′ is formed on the supporting substrate 360. The optical array 400′ is used as an optical input/output port to the optical package structure 100c. The substrate 412 and the substrate 423 are made of the same material. In some embodiments, the substrate 423 of the optical array 400′ is made of Si substrate.

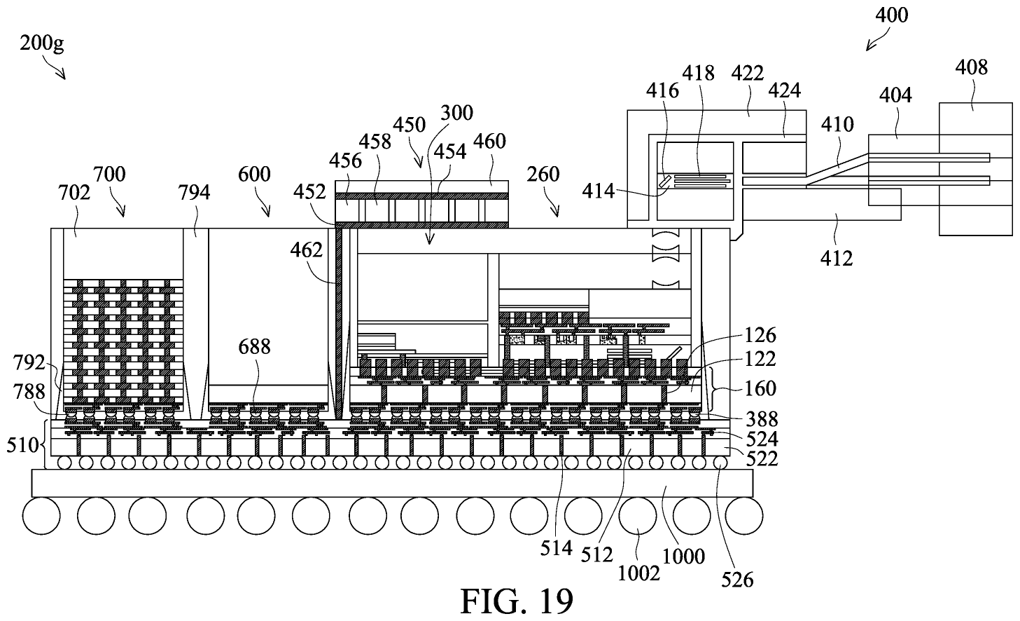

FIG. 19 shows a cross-sectional representation of a package structure 200g, in accordance with some embodiments of the disclosure. The package structure 200g is an alternate embodiment which may be similar to the package structure 200c of FIG. 15, where like reference numerals indicate like elements formed using like processes, unless specified otherwise. Processes and materials used to form the package structure 200g may be similar to, or the same as, those used to form the package structure 200c and are not repeated herein.

The difference between FIG. 19 and FIG. 15 is that the thermal electronic cooler (TEC) 450 is formed on the supporting substrate 360. The TEC 450 is directly formed on the optical die 300. The TEC 450 is configured to transfer heat generated by the optical die 300 or the composite die 260 to the external environment.

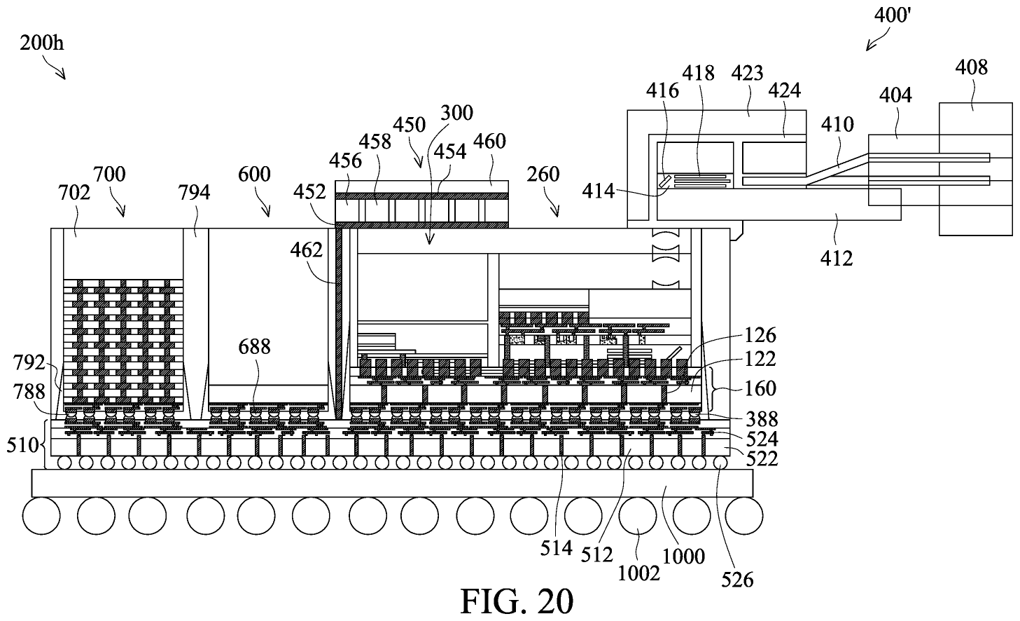

FIG. 20 shows a cross-sectional representation of a package structure 200h, in accordance with some embodiments of the disclosure. The package structure 200h is an alternate embodiment which may be similar to the package structure 200d of FIG. 16, where like reference numerals indicate like elements formed using like processes, unless specified otherwise. Processes and materials used to form the package structure 200h may be similar to, or the same as, those used to form the package structure 200d and are not repeated herein.

The difference between FIG. 20 and FIG. 16 is that the thermal electronic cooler (TEC) 450 is formed on the supporting substrate 360. The TEC 450 is directly formed on the optical die 300. The TEC 450 is configured to transfer heat generated by the optical die 300 or the composite die 260 to the external environment.

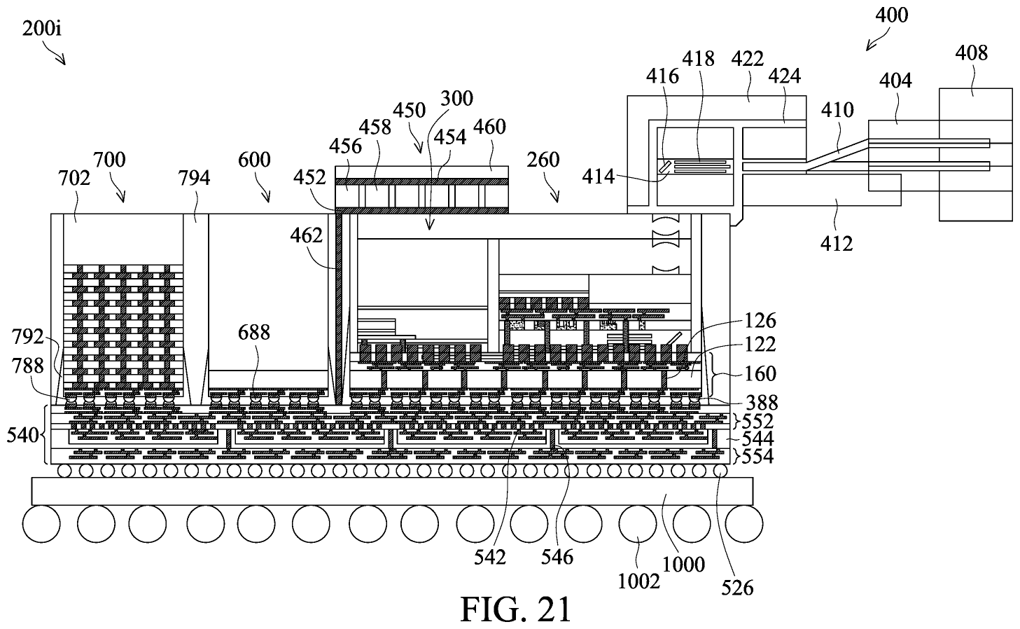

FIG. 21 shows a cross-sectional representation of a package structure 200i, in accordance with some embodiments of the disclosure. The package structure 200i is an alternate embodiment which may be similar to the package structure 200e of FIG. 17, where like reference numerals indicate like elements formed using like processes, unless specified otherwise. Processes and materials used to form the package structure 200i may be similar to, or the same as, those used to form the package structure 200e and are not repeated herein.

The difference between FIG. 21 and FIG. 17 is that the thermal electronic cooler (TEC) 450 is formed on the supporting substrate 360. The TEC 450 is directly formed on the optical die 300. The TEC 450 is configured to transfer heat generated by the optical die 300 or the composite die 260 to the external environment.

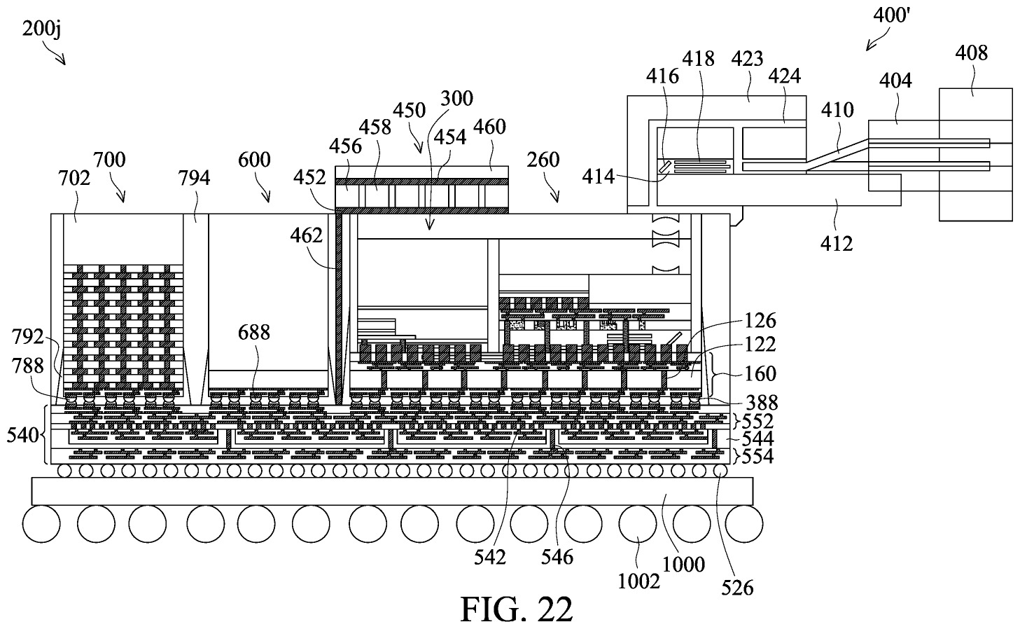

FIG. 22 shows a cross-sectional representation of a package structure 200j, in accordance with some embodiments of the disclosure. The package structure 200j is an alternate embodiment which may be similar to the package structure 200f of FIG. 18, where like reference numerals indicate like elements formed using like processes, unless specified otherwise. Processes and materials used to form the package structure 200j may be similar to, or the same as, those used to form the package structure 200f and are not repeated herein.

The difference between FIG. 22 and FIG. 18 is that the thermal electronic cooler (TEC) 450 is formed on the supporting substrate 360. The TEC 450 is directly formed on the optical die 300. The TEC 450 is configured to transfer heat generated by the optical die 300 or the composite die 260 to the external environment.

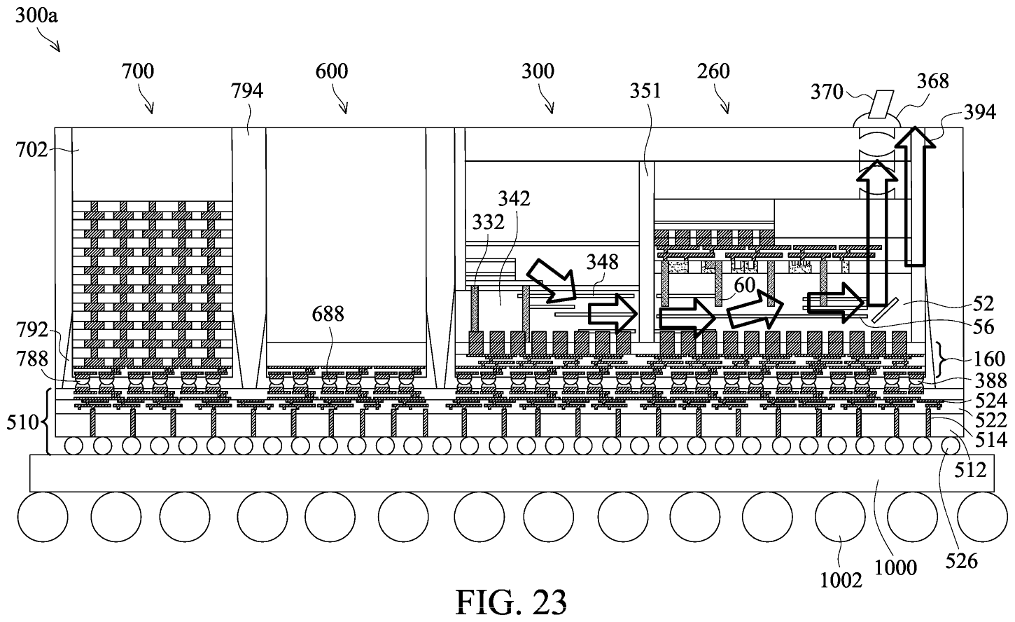

FIG. 23 shows a cross-sectional representation of a package structure 300a, in accordance with some embodiments of the disclosure. The package structure 300a is an alternate embodiment which may be similar to the package structure 100a of FIGS. 1A-1L, where like reference numerals indicate like elements formed using like processes, unless specified otherwise. Processes and materials used to form the package structure 300a may be similar to, or the same as, those used to form the package structure 100a and are not repeated herein.

The difference between FIG. 23 and FIG. 1L is that an optical gel 351 between the optical die 300 and the composite die 260. The vias 332 and the optical components 348 are formed in the dielectric layer 342. The vias 60 and the optical components 56 are formed in the dielectric layer 52. In some embodiments, the refractive index of the optical gel 351 is closer to the refractive index of the dielectric layer 342. In some embodiments, the refractive index of the optical components 348 is greater than the refractive index of the optical gel 351 and the dielectric layer 342, and the light can be confined in the optical components 348.

By forming the optical components 348 and the optical components 56, the optical signal can be transmitted in the horizontal direction through the optical coupling between adjacent the optical components 348 and 56. The optical signal leaving the optical components 348 is directed to the optical components 56.

The arrows 394 represent a general direction that the optical signals are routed within and between the optical fiber 370, the composite die 260 and the optical die 300, and do not necessarily represent the exact path that the optical signals travel through. The optical signals can be transmitted from the optical components 348, through the optical gel 351, to the optical components 56.

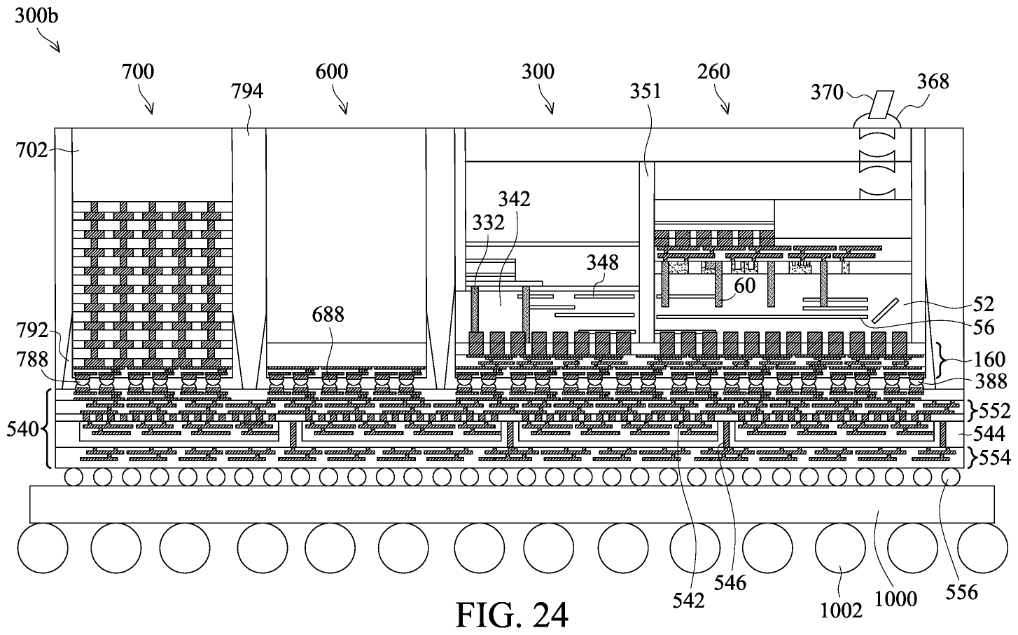

FIG. 24 shows a cross-sectional representation of a package structure 300b, in accordance with some embodiments of the disclosure. The package structure 300b is an alternate embodiment which may be similar to the package structure 100b of FIG. 4, where like reference numerals indicate like elements formed using like processes, unless specified otherwise. Processes and materials used to form the package structure 300b may be similar to, or the same as, those used to form the package structure 100b and are not repeated herein.

The difference between FIG. 24 and FIG. 4 is that the optical gel 351 between the optical die 300 and the composite die 260. The vias 332 and the optical components 348 are formed in the dielectric layer 342. The vias 60 and the optical components 56 are formed in the dielectric layer 52.

By forming the optical components 348 and the optical components 56, the optical signal can be transmitted in the horizontal direction through the optical coupling between adjacent the optical components 348 and 56. The optical signal leaving the optical components 348 is directed to the optical components 56.

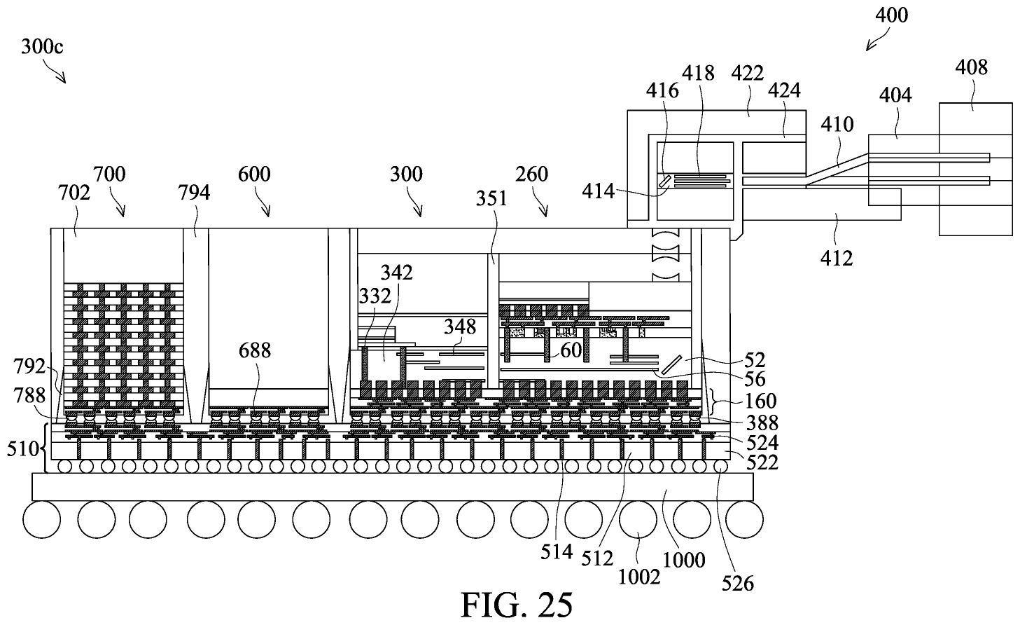

FIG. 25 shows a cross-sectional representation of a package structure 300c, in accordance with some embodiments of the disclosure. The package structure 300c is an alternate embodiment which may be similar to the package structure 300a of FIG. 23, where like reference numerals indicate like elements formed using like processes, unless specified otherwise. Processes and materials used to form the package structure 300c may be similar to, or the same as, those used to form the package structure 300a and are not repeated herein.

The difference between FIG. 25 and FIG. 23 is that the optical array 400 is formed on the supporting substrate 360. The optical array 400 is used as an optical input/output port to the optical package structure 300c.

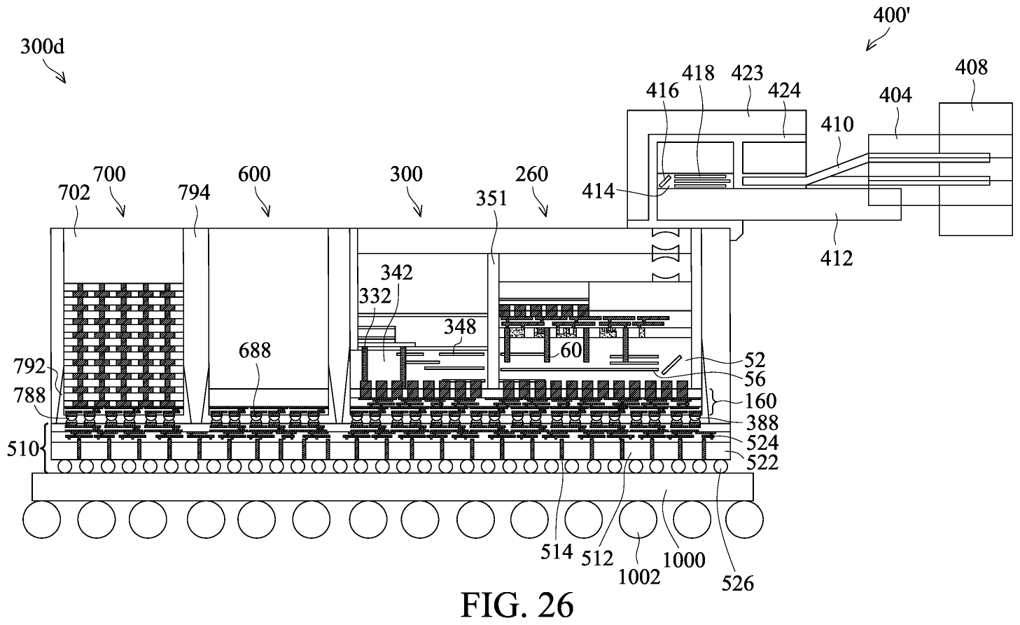

FIG. 26 shows a cross-sectional representation of a package structure 300d, in accordance with some embodiments of the disclosure. The package structure 300d is an alternate embodiment which may be similar to the package structure 300a of FIG. 23, where like reference numerals indicate like elements formed using like processes, unless specified otherwise. Processes and materials used to form the package structure 300d may be similar to, or the same as, those used to form the package structure 300a and are not repeated herein.

The difference between FIG. 26 and FIG. 23 is that an optical array 400′ is formed on the supporting substrate 360. The optical array 400′ is used as an optical input/output port to the optical package structure 100c. The substrate 412 and the substrate 423 are made of the same material. In some embodiments, the substrate 423 of the optical array 400′ is made of Si substrate.

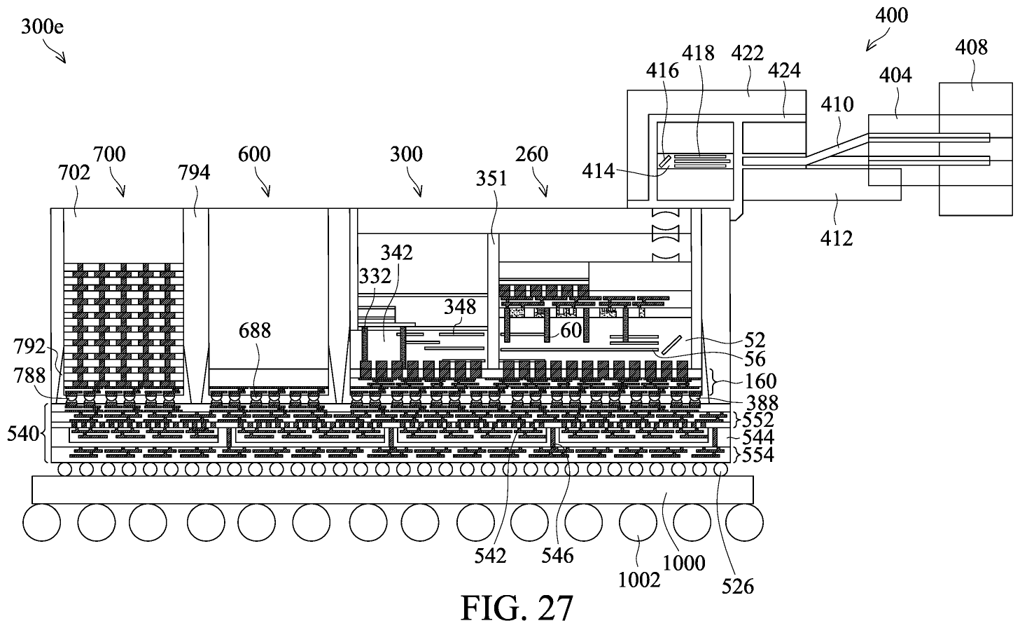

FIG. 27 shows a cross-sectional representation of a package structure 300e, in accordance with some embodiments of the disclosure. The package structure 300e is an alternate embodiment which may be similar to the package structure 300b of FIG. 24, where like reference numerals indicate like elements formed using like processes, unless specified otherwise. Processes and materials used to form the package structure 300e may be similar to, or the same as, those used to form the package structure 300b and are not repeated herein.

The difference between FIG. 27 and FIG. 23 is that the optical array 400 is formed on the supporting substrate 360. The optical array 400 is used as an optical input/output port to the optical package structure 300c.

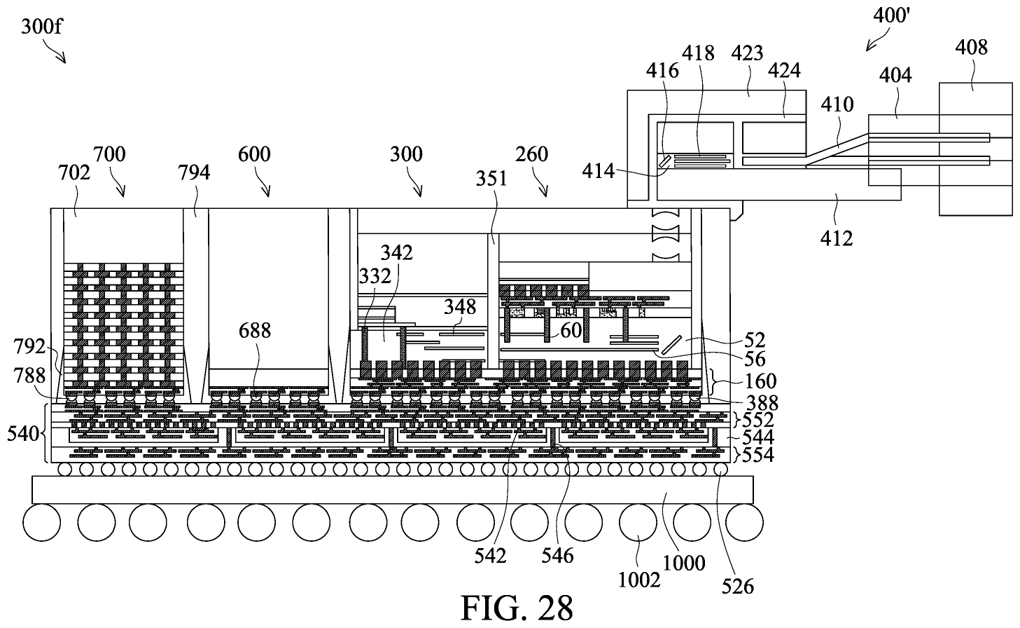

FIG. 28 shows a cross-sectional representation of a package structure 300f, in accordance with some embodiments of the disclosure. The package structure 300f is an alternate embodiment which may be similar to the package structure 300b of FIG. 24, where like reference numerals indicate like elements formed using like processes, unless specified otherwise. Processes and materials used to form the package structure 300f may be similar to, or the same as, those used to form the package structure 300b and are not repeated herein.

The difference between FIG. 28 and FIG. 23 is that an optical array 400′ is formed on the supporting substrate 360. The optical array 400′ is used as an optical input/output port to the optical package structure 100c. The substrate 412 and the substrate 423 are made of the same material. In some embodiments, the substrate 423 of the optical array 400′ is made of Si substrate.

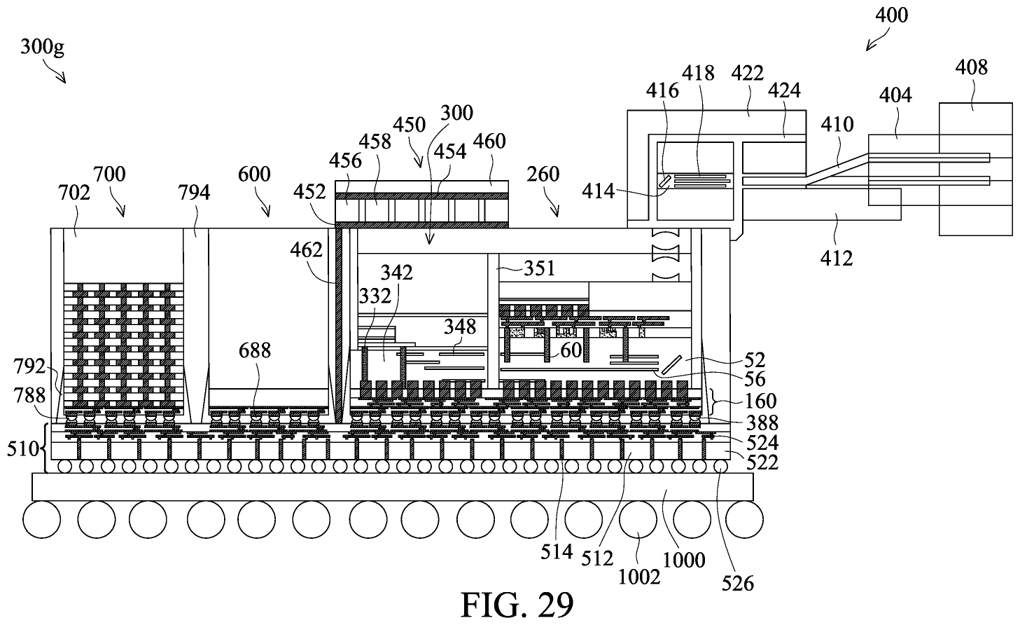

FIG. 29 shows a cross-sectional representation of a package structure 300g, in accordance with some embodiments of the disclosure. The package structure 300g is an alternate embodiment which may be similar to the package structure 300c of FIG. 25, where like reference numerals indicate like elements formed using like processes, unless specified otherwise. Processes and materials used to form the package structure 300g may be similar to, or the same as, those used to form the package structure 300c and are not repeated herein.

The difference between FIG. 29 and FIG. 25 is that the thermal electronic cooler (TEC) 450 is formed on the supporting substrate 360. The TEC 450 is directly formed on the optical die 300. The TEC 450 is configured to transfer heat generated by the optical die 300 or the composite die 260 to the external environment.

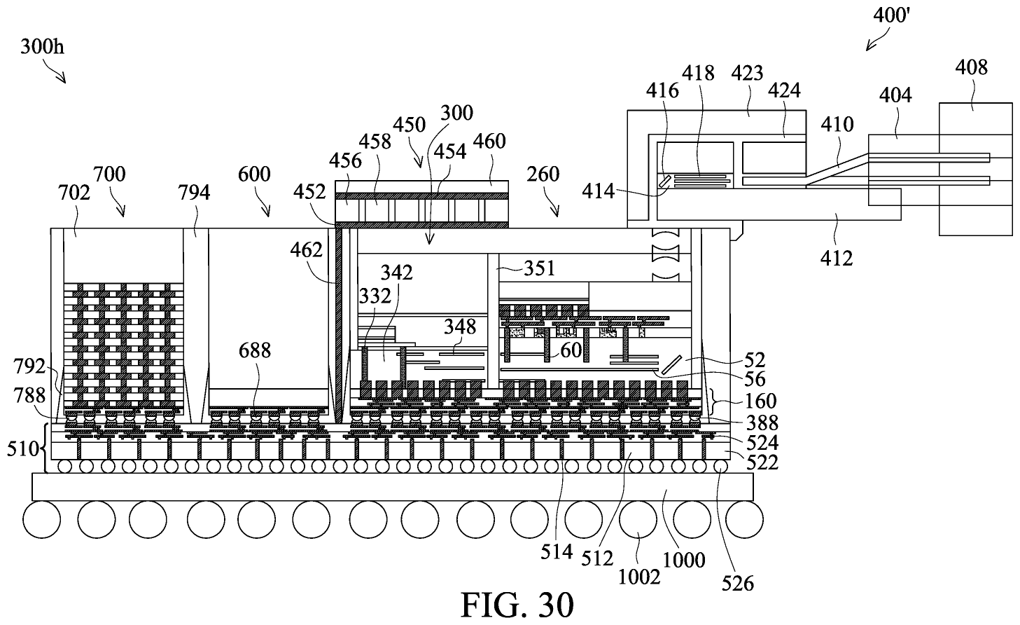

FIG. 30 shows a cross-sectional representation of a package structure 300h, in accordance with some embodiments of the disclosure. The package structure 300h is an alternate embodiment which may be similar to the package structure 300d of FIG. 26, where like reference numerals indicate like elements formed using like processes, unless specified otherwise. Processes and materials used to form the package structure 300h may be similar to, or the same as, those used to form the package structure 300d and are not repeated herein.

The difference between FIG. 30 and FIG. 26 is that the thermal electronic cooler (TEC) 450 is formed on the supporting substrate 360. The TEC 450 is directly formed on the optical die 300. The TEC 450 is configured to transfer heat generated by the optical die 300 or the composite die 260 to the external environment.

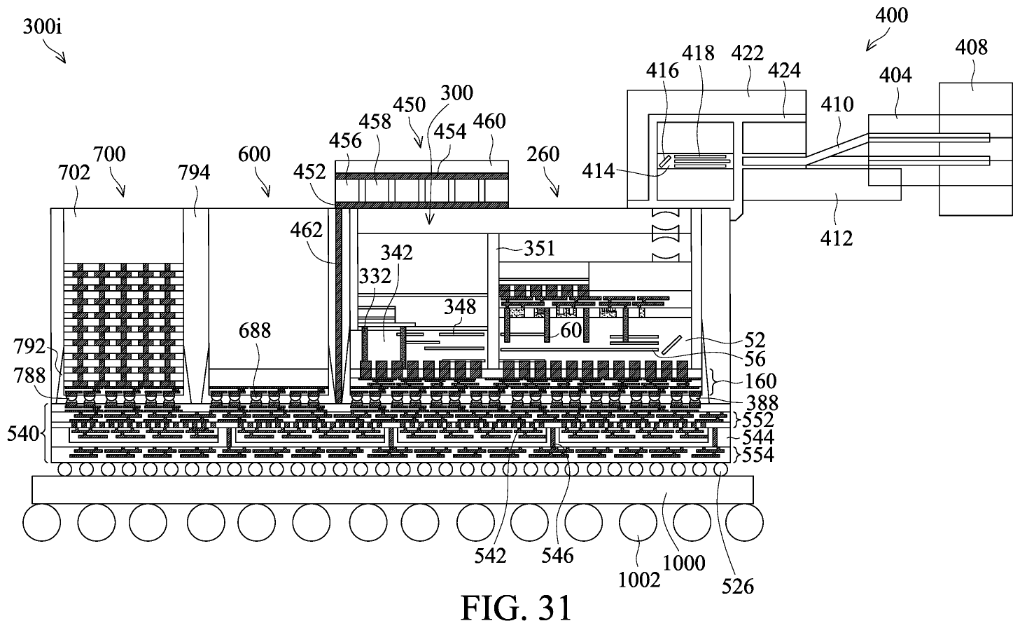

FIG. 31 shows a cross-sectional representation of a package structure 300i, in accordance with some embodiments of the disclosure. The package structure 300i is an alternate embodiment which may be similar to the package structure 300e of FIG. 27, where like reference numerals indicate like elements formed using like processes, unless specified otherwise. Processes and materials used to form the package structure 300i may be similar to, or the same as, those used to form the package structure 300e and are not repeated herein.

The difference between FIG. 31 and FIG. 27 is that the thermal electronic cooler (TEC) 450 is formed on the supporting substrate 360. The TEC 450 is directly formed on the optical die 300. The TEC 450 is configured to transfer heat generated by the optical die 300 or the composite die 260 to the external environment.

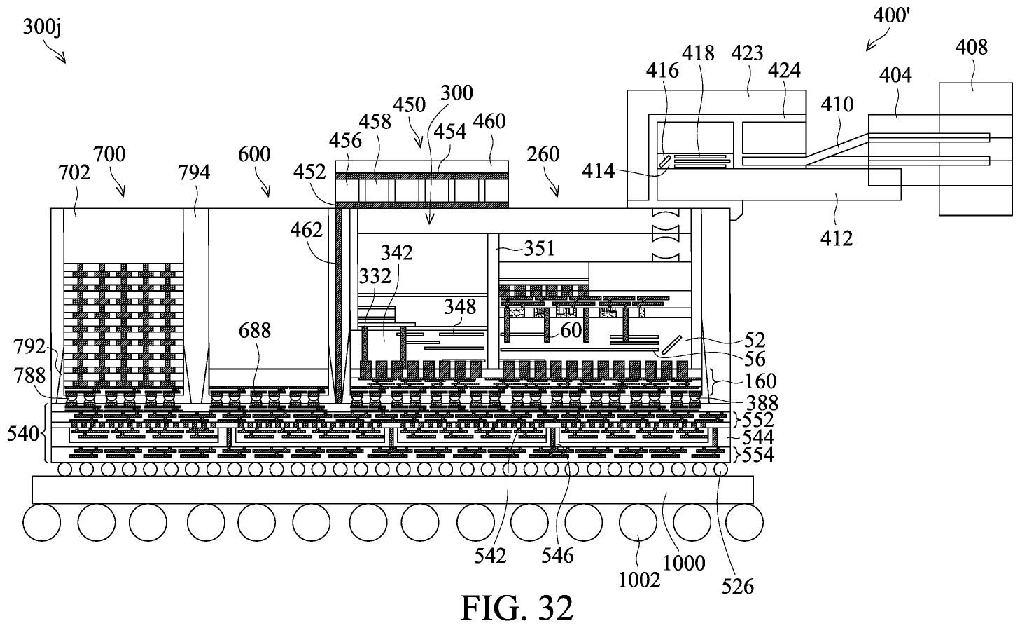

FIG. 32 shows a cross-sectional representation of a package structure 300j, in accordance with some embodiments of the disclosure. The package structure 300j is an alternate embodiment which may be similar to the package structure 300f of FIG. 28, where like reference numerals indicate like elements formed using like processes, unless specified otherwise. Processes and materials used to form the package structure 300j may be similar to, or the same as, those used to form the package structure 300f and are not repeated herein.

The difference between FIG. 32 and FIG. 27 is that the thermal electronic cooler (TEC) 450 is formed on the supporting substrate 360. The TEC 450 is directly formed on the optical die 300. The TEC 450 is configured to transfer heat generated by the optical die 300 or the composite die 260 to the external environment.

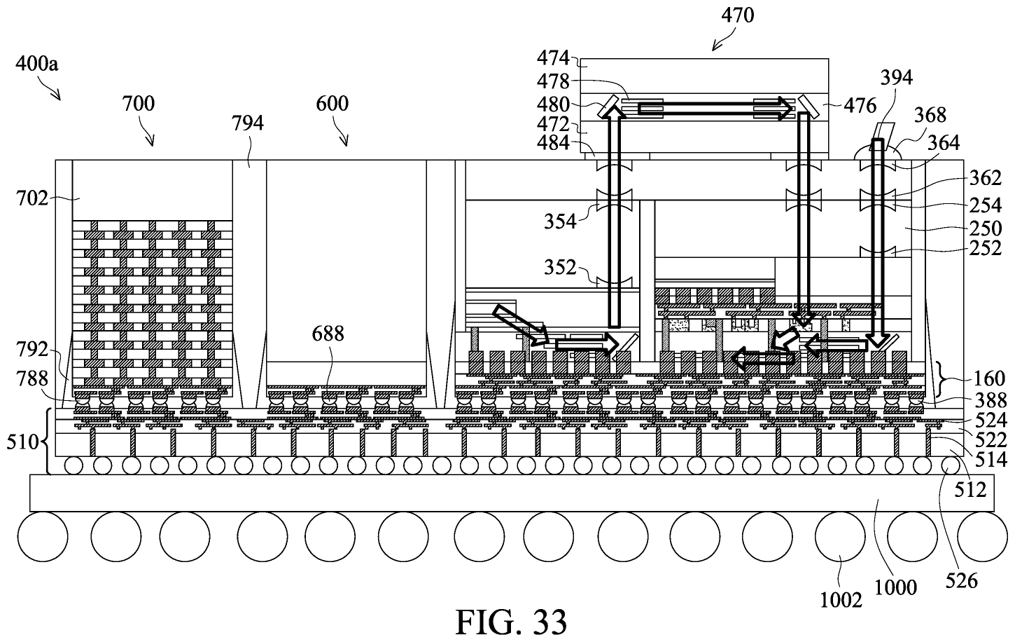

FIG. 33 illustrates a cross-sectional representation of a package structure 400a, in accordance with some embodiments. The package structure 400a is an alternate embodiment which may be similar to the package structure 100a of FIGS. 1A-1L, where like reference numerals indicate like elements formed using like processes, unless specified otherwise. Processes and materials used to form the package structure 400a may be similar to, or the same as, those used to form the package structure 100a and are not repeated herein.

The difference between FIG. 33 and FIG. 1L is that a bridge structure 470 is formed on the supporting substrate 360. The bridge structure 470 is configured to transfer the optical signal from the optical die 300 to the composite die 260. The light can transfer from the optical die 300 through the bridge structure 470 to the composite 260.

The bridge structure 470 includes a dielectric layer 476 between a substrate 472 and a substrate 474. The optical components 478 and mirrors 480 are formed in the dielectric layer 476. The optical gel 484 is between the substrate 472 and the supporting substrate 360. In some embodiments, the substrate 472 and the substrate 474 are made of glass. The light is transmitted in the optical components 478 with high-refractive index materials in the dielectric layer 476 with low-refractive index materials. In addition, the dielectric layer 476 is wrapped by the substrate 472 and the substrate 474, and the substrate 472 and 474 are configured to provide support.

The optical component 478 may include optical waveguides (e.g., ridge waveguides, rib waveguides, buried channel waveguides, diffused waveguides, slab waveguides etc.), couplers (e.g., grating couplers, edge couplers, etc.), optical switches (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. In some embodiments, the optical components 478 include optical waveguides, and the optical waveguides are made of SiN. In some embodiments, the bridge structure 470 includes the waveguides.

The arrows 394 represent a general direction that the optical signals are routed within and between the optical fiber 370, the composite die 260 and the optical die 300, and do not necessarily represent the exact path that the optical signals travel through.

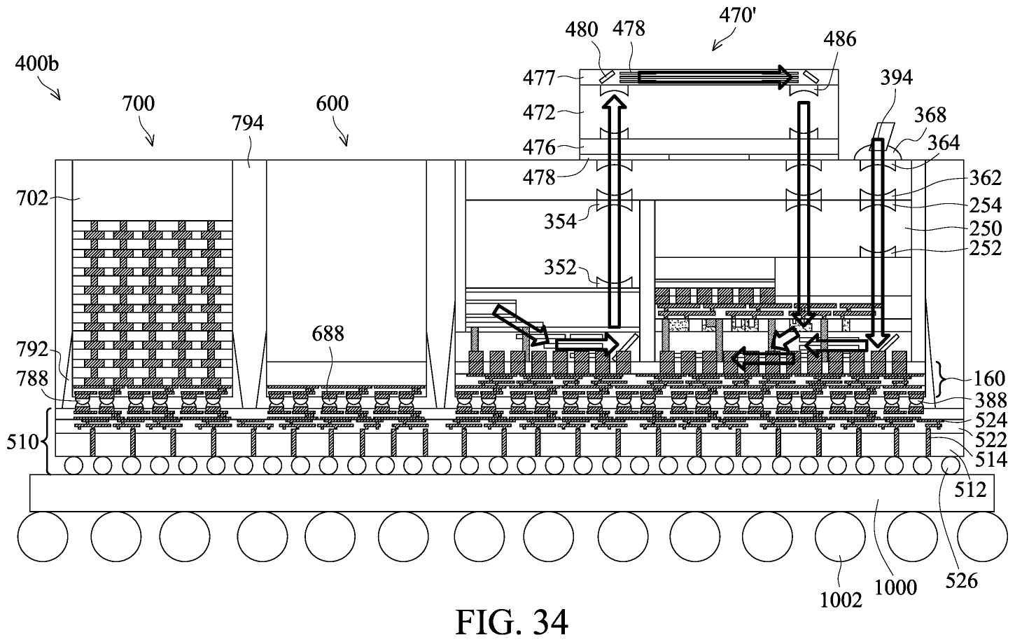

FIG. 34 illustrates a cross-sectional representation of a package structure 400b, in accordance with some embodiments. The package structure 400b is an alternate embodiment which may be similar to the package structure 400a of FIG. 33, where like reference numerals indicate like elements formed using like processes, unless specified otherwise. Processes and materials used to form the package structure 400a may be similar to, or the same as, those used to form the package structure 400b and are not repeated herein.

The difference between FIG. 34 and FIG. 33 is that a bridge structure 470′ is formed on the supporting substrate 360. The bridge structure 470′ includes a semiconductor substrate (e.g., Si substrate) 472 is between the dielectric layer 476 and the dielectric layer 477. The optical components 478 and mirrors 480 are formed in the dielectric layer 477. The optical gel 484 is between the dielectric layer 476 and the supporting substrate 360. The lens 486 is formed in the semiconductor substrate 472.

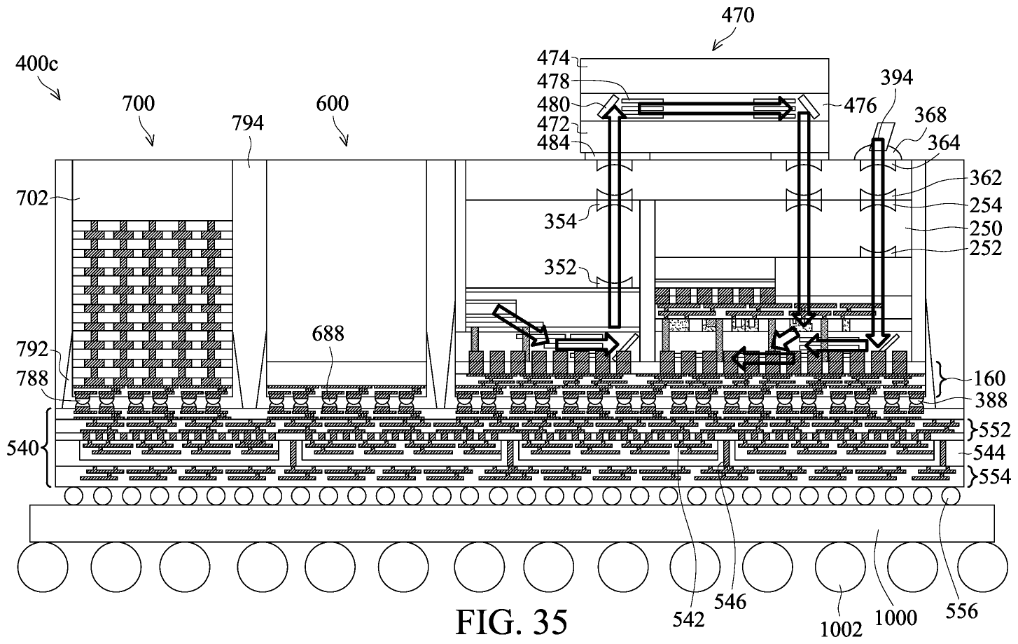

FIG. 35 illustrates a cross-sectional representation of a package structure 400c, in accordance with some embodiments. The package structure 400c is an alternate embodiment which may be similar to the package structure 100b of FIG. 4, where like reference numerals indicate like elements formed using like processes, unless specified otherwise. Processes and materials used to form the package structure 400c may be similar to, or the same as, those used to form the package structure 100b and are not repeated herein.

The difference between FIG. 35 and FIG. 4 is that the bridge structure 470 is formed on the supporting substrate 360.

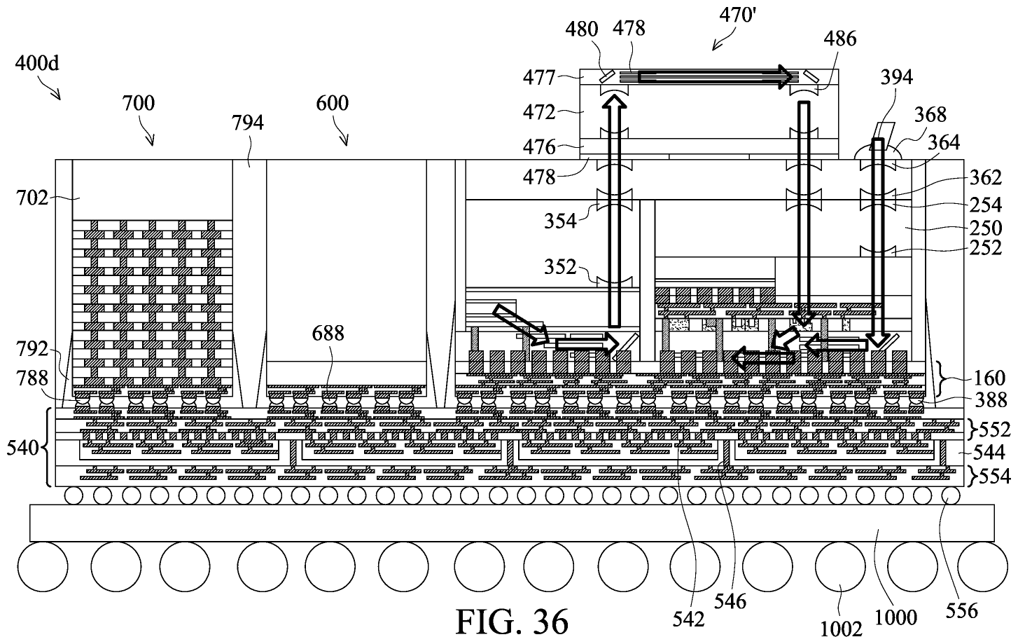

FIG. 36 illustrates a cross-sectional representation of a package structure 400d, in accordance with some embodiments. The package structure 400d is an alternate embodiment which may be similar to the package structure 400c of FIG. 35, where like reference numerals indicate like elements formed using like processes, unless specified otherwise. Processes and materials used to form the package structure 400d may be similar to, or the same as, those used to form the package structure 400c and are not repeated herein.

The difference between FIG. 36 and FIG. 35 is that the bridge structure 470 is replaced with the bridge structure 470′.

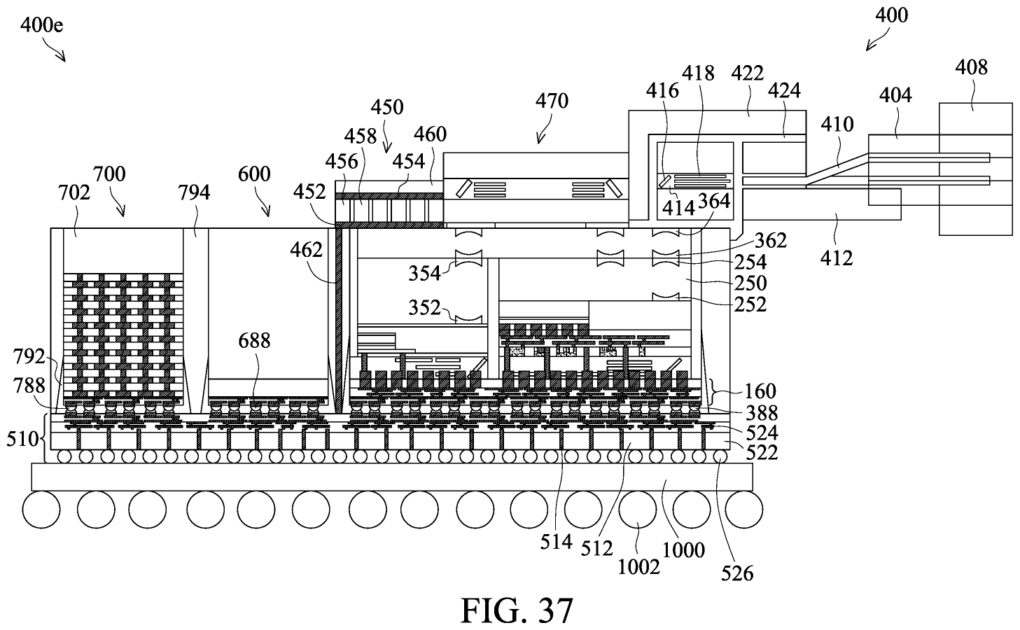

FIG. 37 illustrates a cross-sectional representation of a package structure 400e, in accordance with some embodiments. The package structure 400e is an alternate embodiment which may be similar to the package structure 400a of FIG. 33, where like reference numerals indicate like elements formed using like processes, unless specified otherwise. Processes and materials used to form the package structure 400e may be similar to, or the same as, those used to form the package structure 400a and are not repeated herein.

The difference between FIG. 37 and FIG. 33 is that the optical array 400 is formed on the supporting substrate 360, and the TEC 450 is formed on the supporting substrate 360 and the semiconductor die 600.

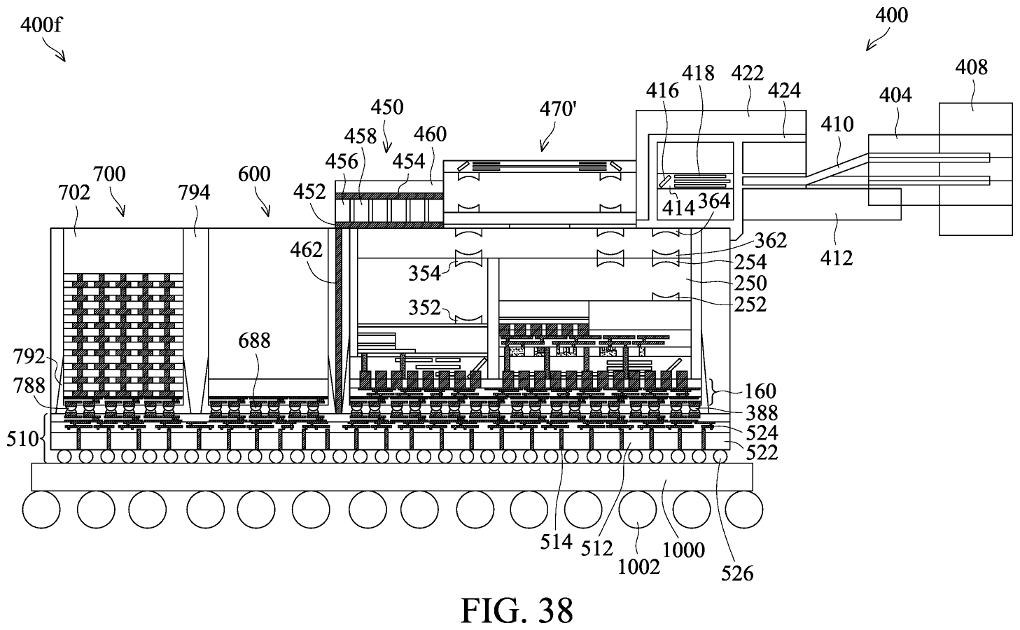

FIG. 38 illustrates a cross-sectional representation of a package structure 400f, in accordance with some embodiments. The package structure 400f is an alternate embodiment which may be similar to the package structure 400b of FIG. 34, where like reference numerals indicate like elements formed using like processes, unless specified otherwise. Processes and materials used to form the package structure 400f may be similar to, or the same as, those used to form the package structure 400b and are not repeated herein.

The difference between FIG. 38 and FIG. 33 is that the optical array 400 is formed on the supporting substrate 360, and the TEC 450 is formed on the supporting substrate 360 and the semiconductor die 600.

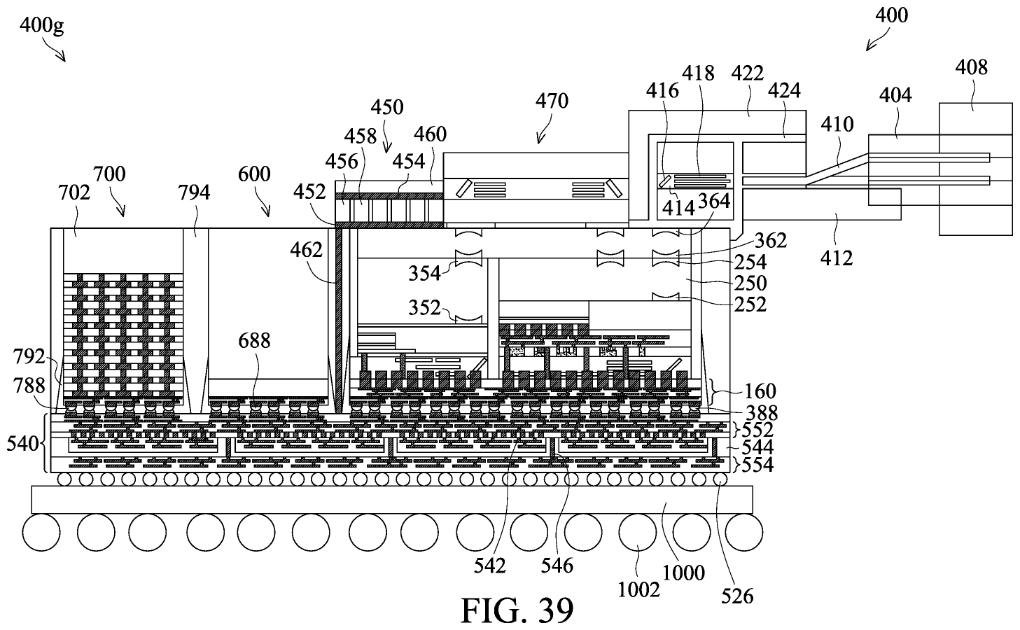

FIG. 39 illustrates a cross-sectional representation of a package structure 400g, in accordance with some embodiments. The package structure 400g is an alternate embodiment which may be similar to the package structure 400c of FIG. 35, where like reference numerals indicate like elements formed using like processes, unless specified otherwise. Processes and materials used to form the package structure 400g may be similar to, or the same as, those used to form the package structure 400c and are not repeated herein.

The difference between FIG. 39 and FIG. 35 is that the optical array 400 is formed on the supporting substrate 360, and the TEC 450 is formed on the supporting substrate 360 and the semiconductor die 600.

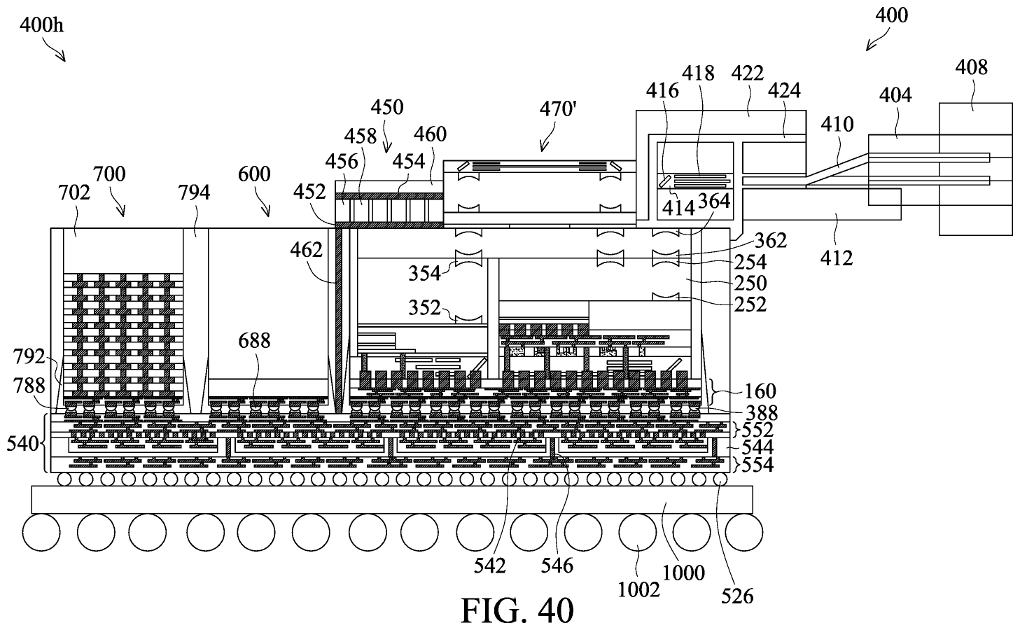

FIG. 40 illustrates a cross-sectional representation of a package structure 400h, in accordance with some embodiments. The package structure 400h is an alternate embodiment which may be similar to the package structure 400d of FIG. 36, where like reference numerals indicate like elements formed using like processes, unless specified otherwise. Processes and materials used to form the package structure 400h may be similar to, or the same as, those used to form the package structure 400d and are not repeated herein.

The difference between FIG. 40 and FIG. 36 is that the optical array 400 is formed on the supporting substrate 360, and the TEC 450 is formed on the supporting substrate 360 and the semiconductor die 600.

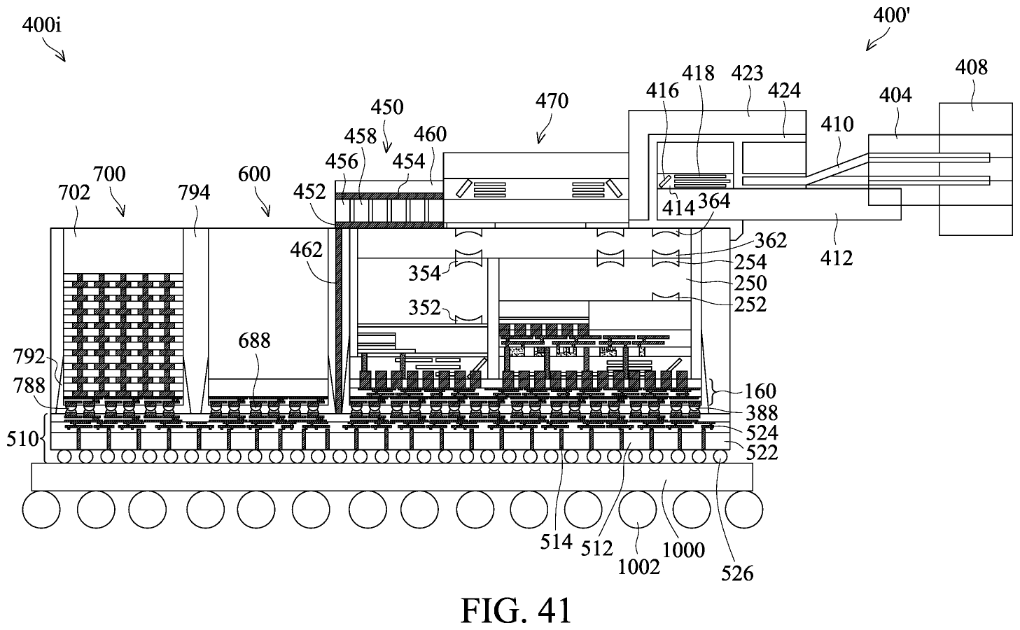

FIG. 41 illustrates a cross-sectional representation of a package structure 400i, in accordance with some embodiments. The package structure 400i is an alternate embodiment which may be similar to the package structure 400e of FIG. 37, where like reference numerals indicate like elements formed using like processes, unless specified otherwise. Processes and materials used to form the package structure 400i may be similar to, or the same as, those used to form the package structure 400e and are not repeated herein.

The difference between FIG. 41 and FIG. 37 is that the optical array 400′ is formed on the supporting substrate 360.

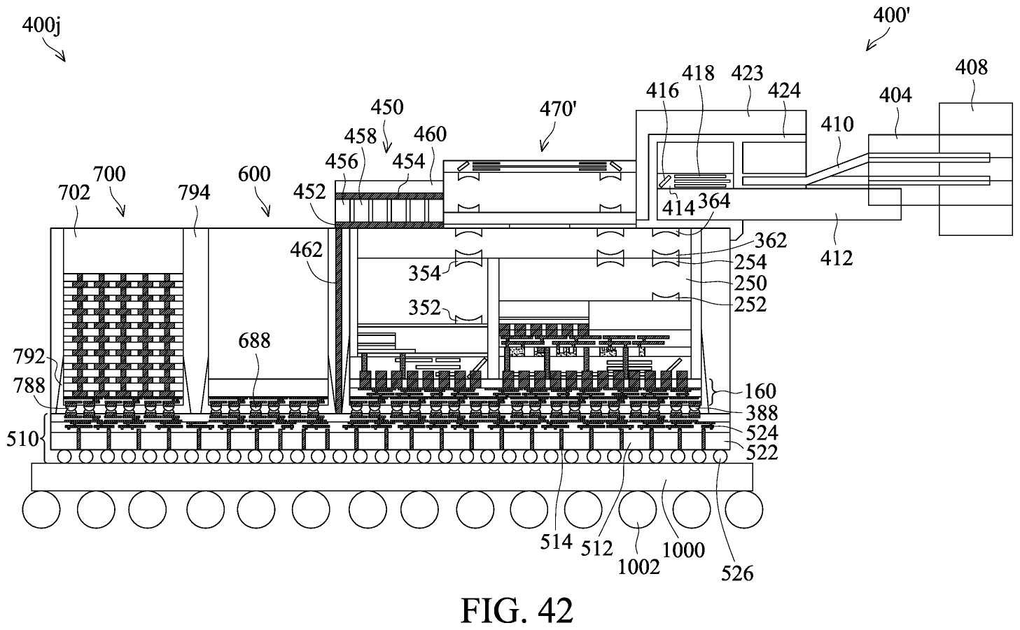

FIG. 42 illustrates a cross-sectional representation of a package structure 400j, in accordance with some embodiments. The package structure 400i is an alternate embodiment which may be similar to the package structure 400f of FIG. 38, where like reference numerals indicate like elements formed using like processes, unless specified otherwise. Processes and materials used to form the package structure 400j may be similar to, or the same as, those used to form the package structure 400f and are not repeated herein.

The difference between FIG. 42 and FIG. 38 is that the optical array 400′ is formed on the supporting substrate 360.

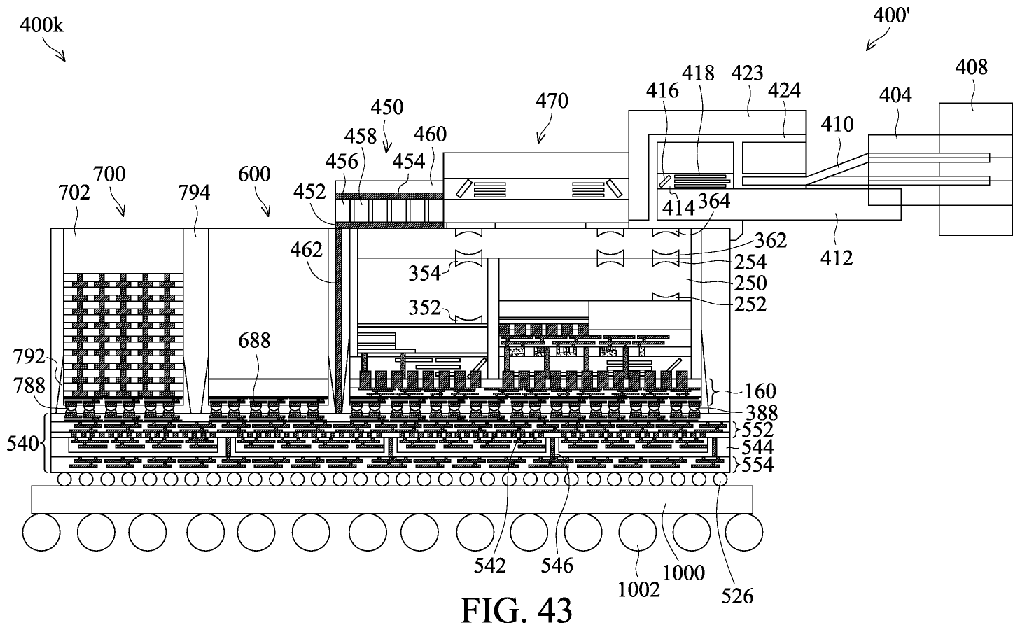

FIG. 43 illustrates a cross-sectional representation of a package structure 400k, in accordance with some embodiments. The package structure 400k is an alternate embodiment which may be similar to the package structure 400g of FIG. 39, where like reference numerals indicate like elements formed using like processes, unless specified otherwise. Processes and materials used to form the package structure 400k may be similar to, or the same as, those used to form the package structure 400g and are not repeated herein.

The difference between FIG. 43 and FIG. 39 is that the optical array 400′ is formed on the supporting substrate 360.

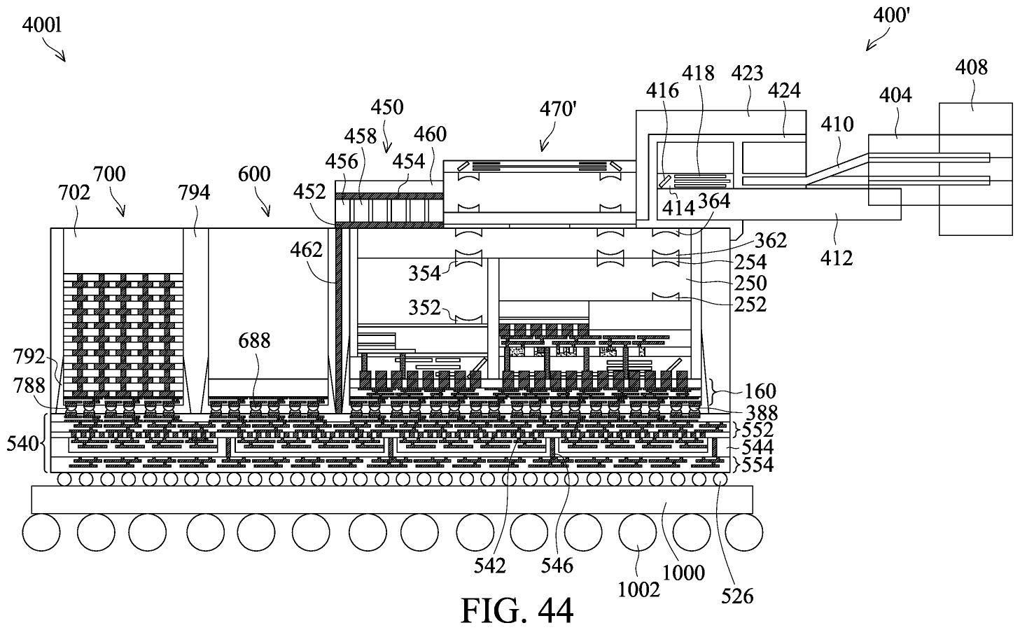

FIG. 44 illustrates a cross-sectional representation of a package structure 4001, in accordance with some embodiments. The package structure 4001 is an alternate embodiment which may be similar to the package structure 400h of FIG. 40, where like reference numerals indicate like elements formed using like processes, unless specified otherwise. Processes and materials used to form the package structure 4001 may be similar to, or the same as, those used to form the package structure 400h and are not repeated herein.

The difference between FIG. 44 and FIG. 40 is that the optical array 400′ is formed on the supporting substrate 360.

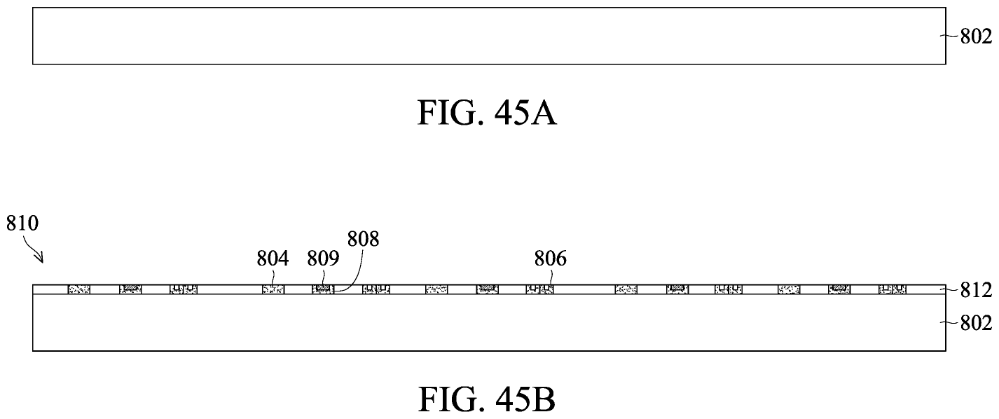

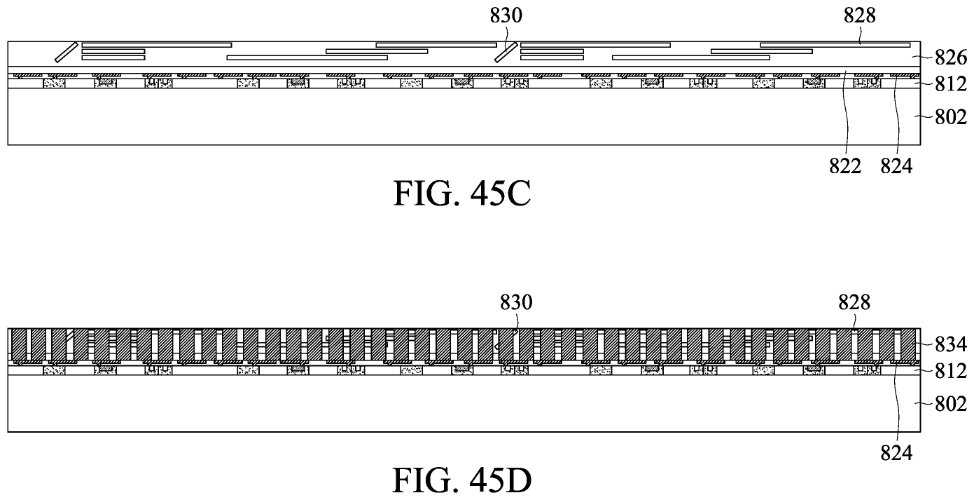

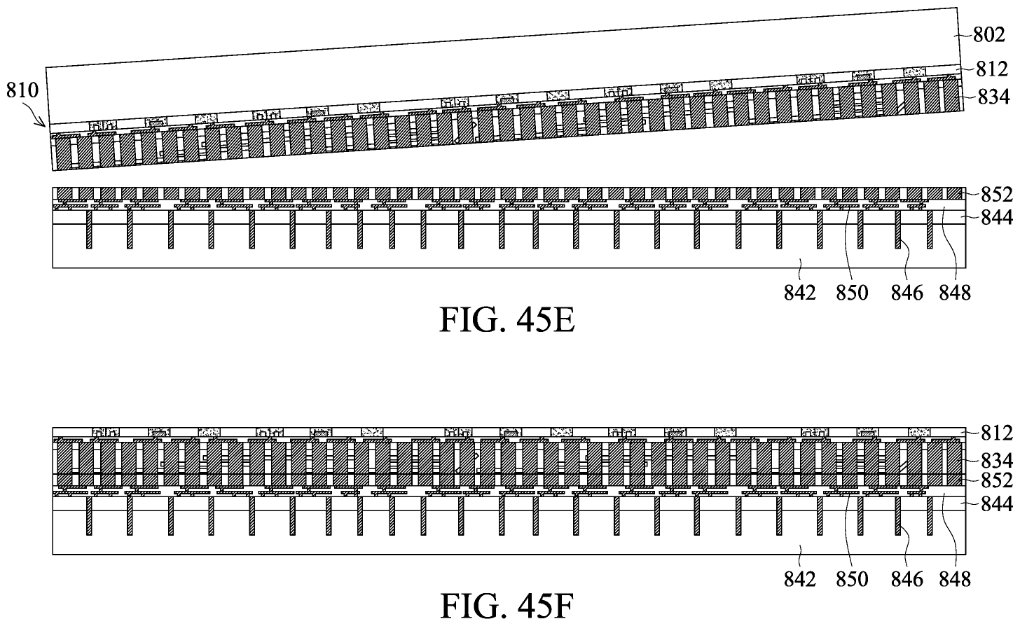

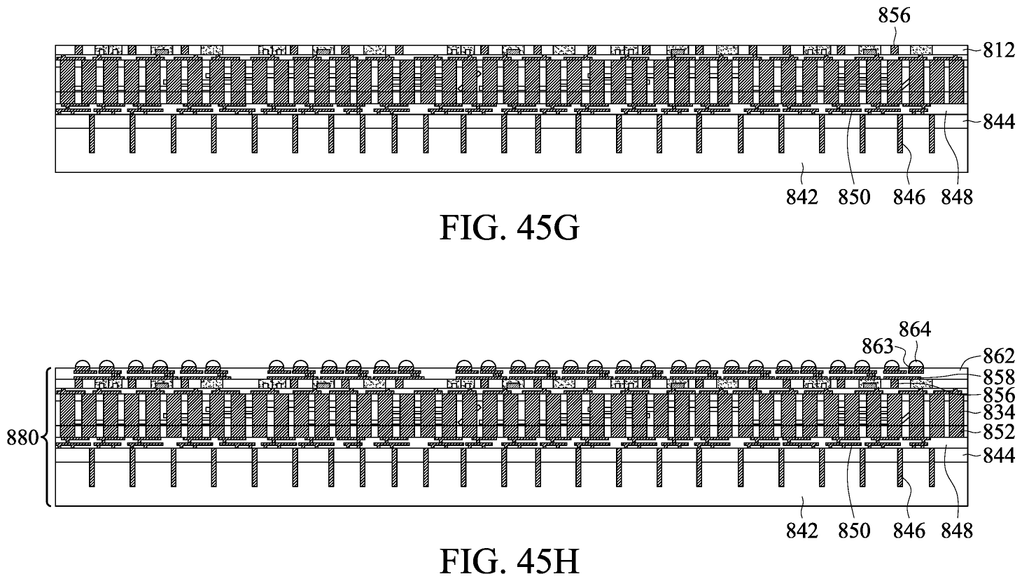

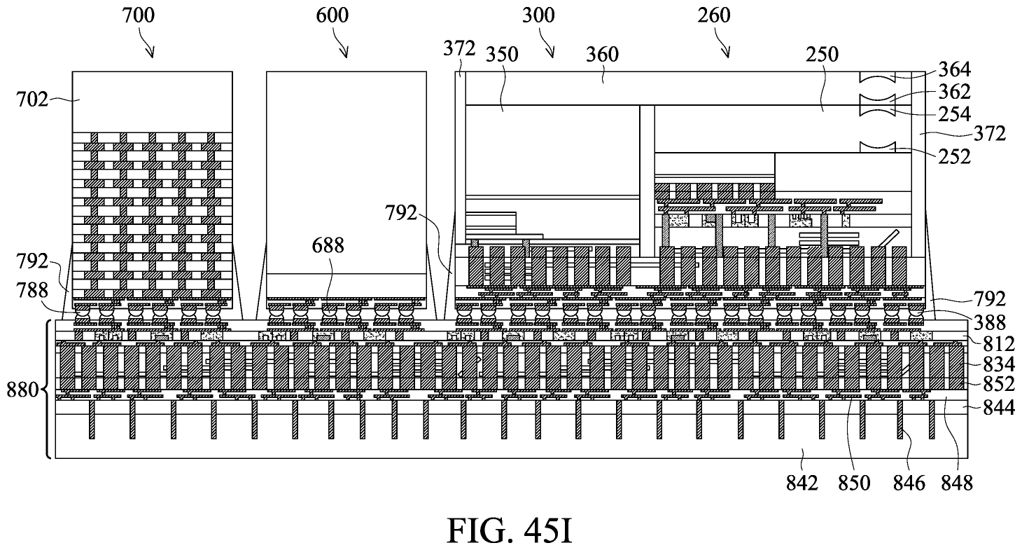

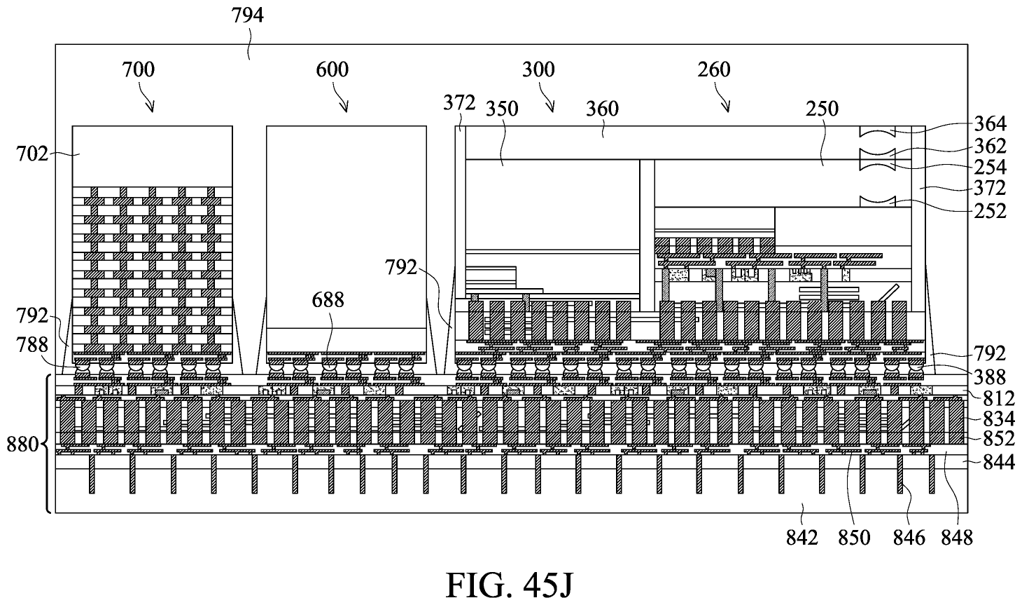

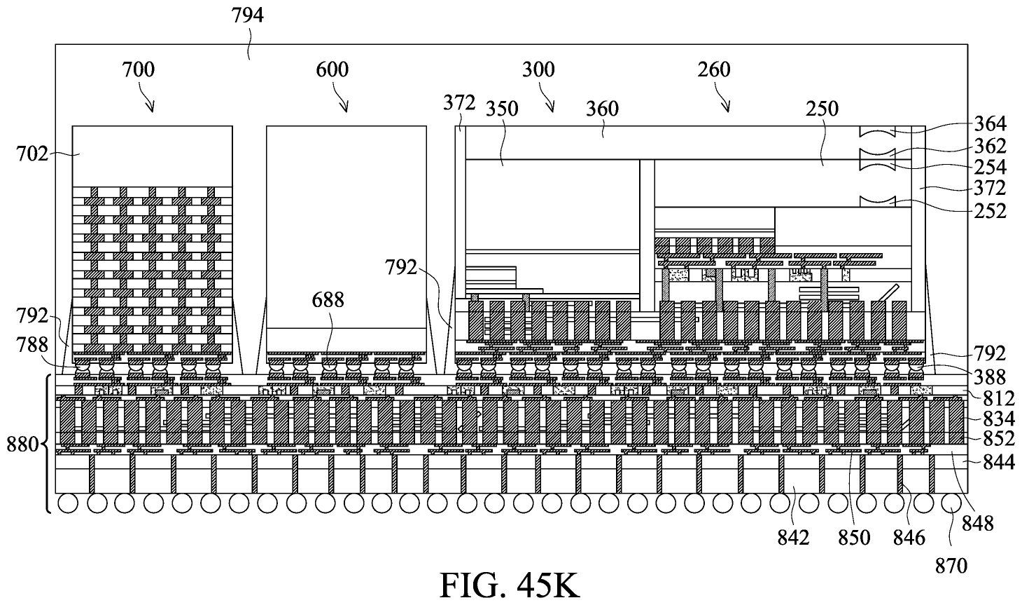

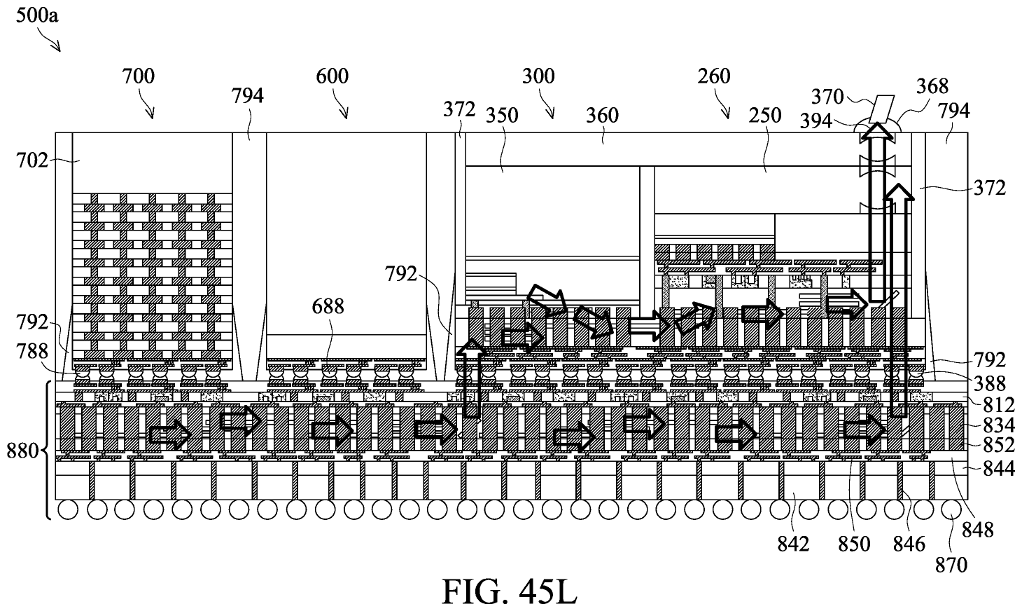

FIGS. 45A to 45L illustrate cross-sectional representations of various stages of manufacturing a package structure 500a, in accordance with some embodiments.

As shown in FIG. 45A, a substrate 802 is provided. The substrate 802 may be a semiconductor wafer such as a silicon wafer. Alternatively or additionally, the substrate 802 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GalnAs, GalnP, and/or GaInAsP.

Next, as shown in FIG. 45B, optical components 810 are formed by etching a portion of the substrate 802, in accordance with some embodiments. Next, a dielectric layer 812 is formed on the optical components 810. In some embodiments, the optical components 810 include waveguides 804, couplers 806, modulators 808 and germanium modulator 809.

Afterwards, as shown in FIG. 45C, a dielectric layer 822 is formed on the dielectric layer 812, and conductive layers 824 are formed in the dielectric layer 822, in accordance with some embodiments. Next, a dielectric layer 826 is formed on the dielectric layer 812, and optical components 828 and mirrors 830 are formed in the dielectric layer 826.

The optical component 828 may include optical waveguides (e.g., ridge waveguides, rib waveguides, buried channel waveguides, diffused waveguides, slab waveguides etc.), couplers (e.g., grating couplers, edge couplers, etc.), optical switches (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. In some embodiments, the optical components 828 include optical waveguides, and the optical waveguides are made of SiN.

The mirrors 830 formed in the dielectric layer 826 are configured to reflect the light from optical component 828 to the optical die 300 and the composite die 260. Therefore, the light can be transmitted from the horizontal direction to the vertical direction through the mirrors 830.

Next, as shown in FIG. 45D, conductive pads 834 are formed in the dielectric layer 822, in accordance with some embodiments.

Afterwards, as shown in FIG. 45E, another substrate 842 is provided, and a memory layer 844 is formed on the substrate 842, and a dielectric layer 848 is formed on the memory layer 844, in accordance with some embodiments. The through-substrate via (TSV) structures 846 are formed through the dielectric layer 842. The conductive layers 850 and the conductive pads 852 are formed in the dielectric layer 848.

Next, the structure as shown in FIG. 45D is flipped and facing the conductive pads 852, the conductive pads 834 are facing the conductive pads 852 for the hybrid bonding process.

Next, as shown in FIG. 45F, the conductive pads 834 are bonded to the conductive pads 852 by the hybrid bonding process, in accordance with some embodiments. Afterwards, the substrate 802 is removed to expose the optical components 810. The hybrid bonding structure includes the conductive pads 852 bonded to the conductive pads 834, and the dielectric layer 826 bonded to the dielectric layer 848.

Afterwards, as shown in FIG. 45G, through-substrate via (TSV) structures 856 are formed in the dielectric layer 812, in accordance with some embodiments.

Next, as shown in FIG. 45H, a dielectric layer 862 is formed on the dielectric layer 812, and conductive pads 858 are formed in the dielectric layer 862, in accordance with some embodiments. Next, the UBM layers 863 are formed on the conductive pads 858, and the conductive connectors 864 are formed on the dielectric layer 862 to form a bottom interposer 880. In some embodiments, the bottom interposer 880 is a high computational interposer. In some embodiments, the bottom interposer 880 is a wafer level interposer.

The UBM layers 863 may contain an adhesion layer and/or a wetting layer. In some embodiments, the UBM layers 66 are made of titanium (Ti), titanium nitride (TiN), tantalum nitride (TaN), tantalum (Ta), or the like. In some embodiments, the UBM layers 863 further includes a copper seed layer. In some embodiments, the UBM layers 863 are formed by electroplating, electroless plating, printing, a chemical vapor deposition (CVD) process, a physical vapor process, or another applicable process.

The conductive connectors 864 are made of solder materials, such as tin (Sn), tin-silver (SnAg), tin-lead (SnPb), tin-copper (SnCu), tin-silver-copper (SnAgCu), tin-silver-zinc (SnAgZn), tin-zinc (SnZn), tin-bismuth-indium (SnBiIn), tin-indium (SnIn), tin-gold (SnAu), tin-zinc-indium (SnZnIn), tin-silver-Antimony (SnAgSb) or another applicable material. In some embodiments, the conductive connectors 864 are formed by electroplating, electroless plating, printing, a chemical vapor deposition (CVD) process, a physical vapor process, or another applicable process.

Afterwards, as shown in FIG. 451, the composite die 260, optical die 300, the semiconductor die 600 and the semiconductor die 700 are bonded to the bottom interposer 880, in accordance with some embodiments. The composite die 260 is bonded to the bottom interposer 880 by the bonding conductive connector 388, the semiconductor die 600 is bonded to the bottom interposer 880 by the bonding conductive connector 688, and the semiconductor die 700 are bonded to the bottom interposer 880 by the bonding conductive connector 788.

The package layer 372 is formed to surround the composite die 260, and the underfill layer 792 is formed to surround the bonding conductive connector 388, the bonding conductive connector 688 and the bonding conductive connector 788.

Next, as shown in FIG. 45J, the package layer 794 is formed on the underfill layer 792, the composite die 260, the semiconductor die 600 and the semiconductor die 700, in accordance with some embodiments.

Afterwards, as shown in FIG. 45K, the backside of the substrate 842 is removed to expose the through-substrate via (TSV) structures 846, in accordance with some embodiments. Next, the conductive connectors 870 are formed below the TSV structures 846.

Next, as shown in FIG. 45L, a portion of the package layer 794 is removed to expose the supporting substrate 360, in accordance with some embodiments. As a result, the package structure 500a is obtained.

As shown in FIG. 45L, the optical die 300 and the composite die 260 are formed on the top interposer 160, and the top interposer 160, the semiconductor die 600 and the semiconductor die 700 are bonded to the bottom interposer 880. The bottom interposer 880 includes optical components 810 formed in the dielectric layer 812, and memory layer 844 formed over the substrate 842.

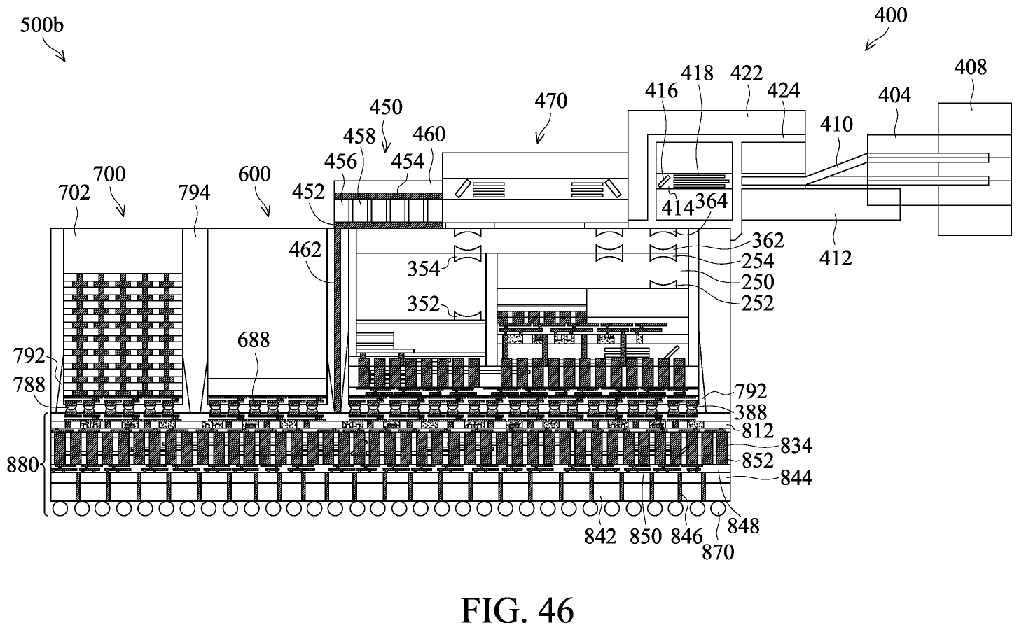

FIG. 46 illustrates a cross-sectional representation of a package structure 500b, in accordance with some embodiments. The package structure 500b is an alternate embodiment which may be similar to the package structure 500a of FIG. 45L, where like reference numerals indicate like elements formed using like processes, unless specified otherwise. Processes and materials used to form the package structure 500b may be similar to, or the same as, those used to form the package structure 500a and are not repeated herein.

The difference between FIG. 46 and FIG. 45L is that the optical array 400 and the bridge structure 470 are formed on the supporting substrate 360, and the TEC 450 is formed on the optical die 300, in accordance with some embodiments.

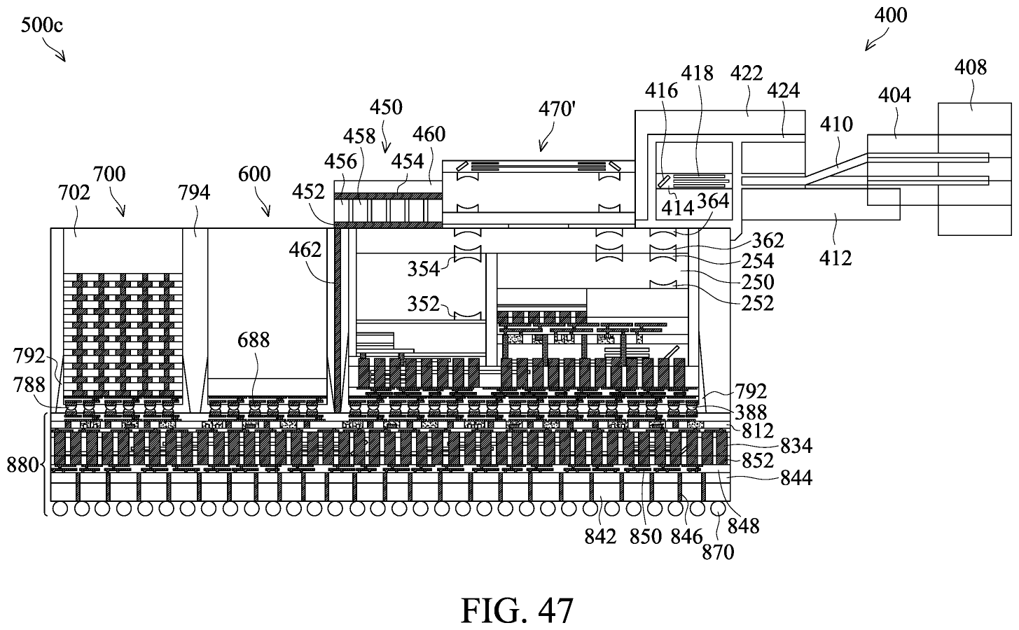

FIG. 47 illustrates a cross-sectional representation of a package structure 500c, in accordance with some embodiments. The package structure 500c is an alternate embodiment which may be similar to the package structure 500b of FIG. 46, where like reference numerals indicate like elements formed using like processes, unless specified otherwise. Processes and materials used to form the package structure 500c may be similar to, or the same as, those used to form the package structure 500b and are not repeated herein.

The difference between FIG. 47 and FIG. 46 is that the bridge structure 470′ is formed on the optical die 300, in accordance with some embodiments.

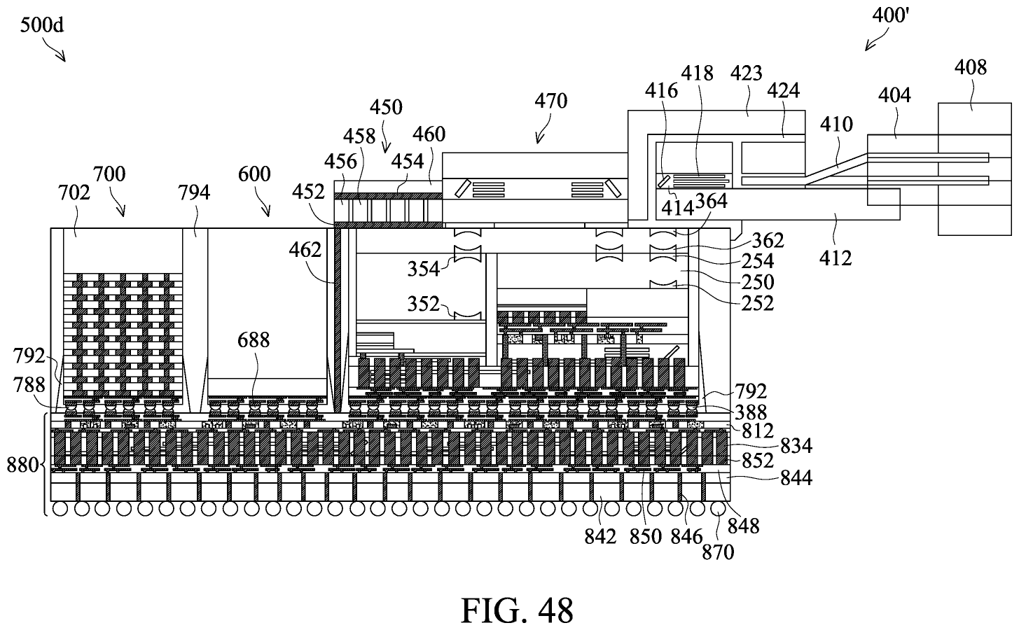

FIG. 48 illustrates a cross-sectional representation of a package structure 500d, in accordance with some embodiments. The package structure 500d is an alternate embodiment which may be similar to the package structure 500b of FIG. 46, where like reference numerals indicate like elements formed using like processes, unless specified otherwise. Processes and materials used to form the package structure 500d may be similar to, or the same as, those used to form the package structure 500b and are not repeated herein.

The difference between FIG. 48 and FIG. 46 is that the optical array 400′ is formed on the supporting substrate 360, in accordance with some embodiments.

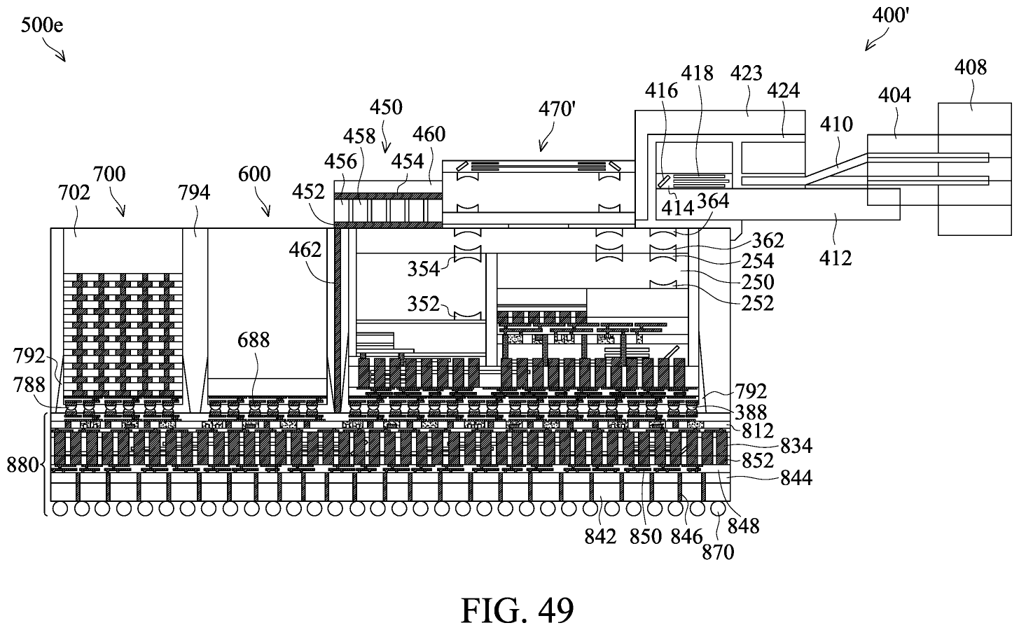

FIG. 49 illustrates a cross-sectional representation of a package structure 500e, in accordance with some embodiments. The package structure 500e is an alternate embodiment which may be similar to the package structure 500d of FIG. 48, where like reference numerals indicate like elements formed using like processes, unless specified otherwise. Processes and materials used to form the package structure 500e may be similar to, or the same as, those used to form the package structure 500d and are not repeated herein.

The difference between FIG. 49 and FIG. 48 is that the bridge structure 470′ is formed on the optical die 300, in accordance with some embodiments.

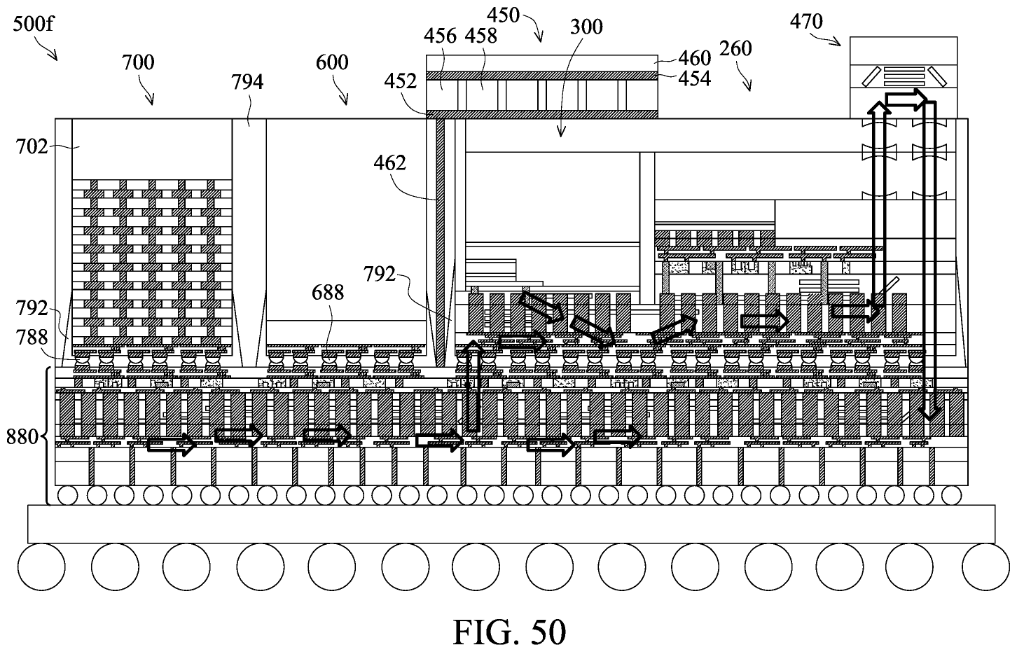

FIG. 50 illustrates a cross-sectional representation of a package structure 500f, in accordance with some embodiments. The package structure 500f is an alternate embodiment which may be similar to the package structure 500a of FIG. 45L, where like reference numerals indicate like elements formed using like processes, unless specified otherwise. Processes and materials used to form the package structure 500f may be similar to, or the same as, those used to form the package structure 500a and are not repeated herein.

The difference between FIG. 50 and FIG. 45L is that the bridge structure 470 is formed on the supporting substrate 360, and the TEC 450 is formed on the optical die 300, in accordance with some embodiments.

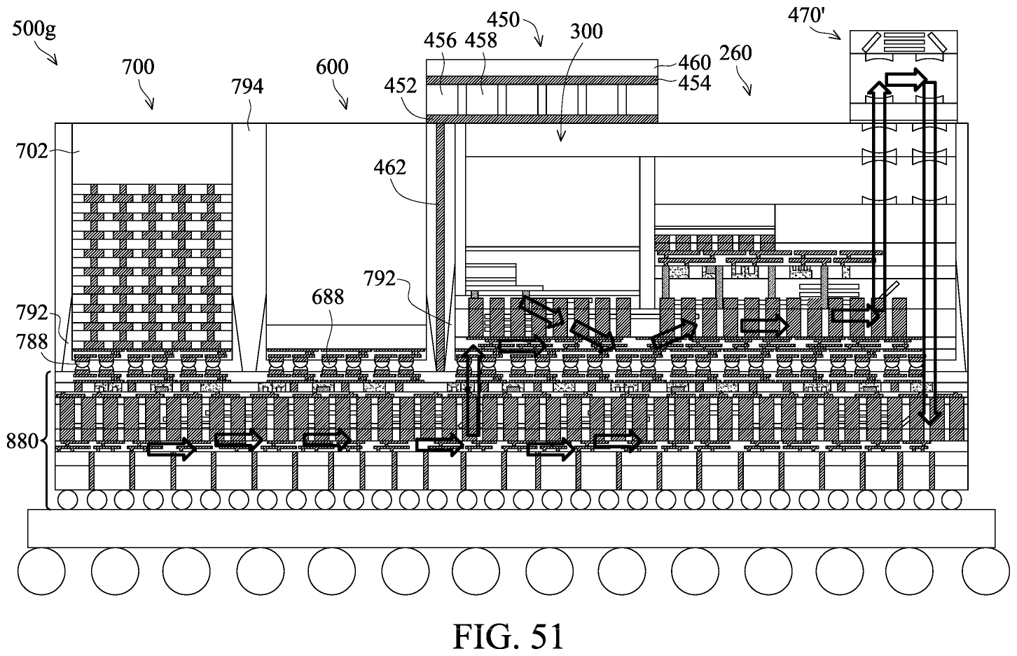

FIG. 51 illustrates a cross-sectional representation of a package structure 500g, in accordance with some embodiments. The package structure 500g is an alternate embodiment which may be similar to the package structure 500f of FIG. 50, where like reference numerals indicate like elements formed using like processes, unless specified otherwise. Processes and materials used to form the package structure 500g may be similar to, or the same as, those used to form the package structure 500f and are not repeated herein.

The difference between FIG. 51 and FIG. 50 is that that the bridge structure 470′ is formed on the supporting substrate 360, in accordance with some embodiments.

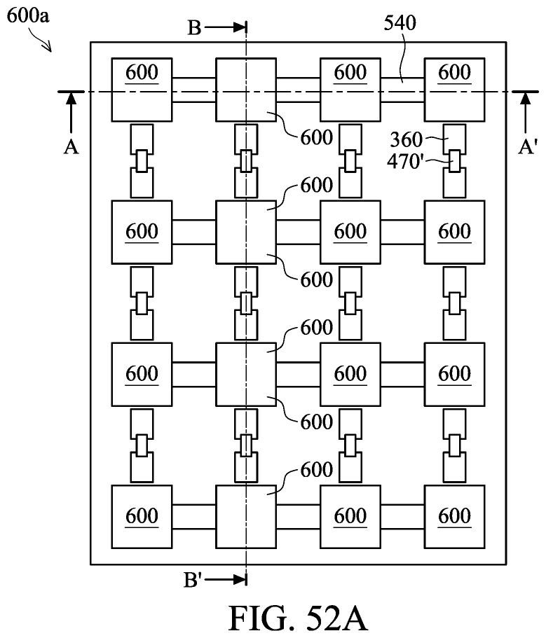

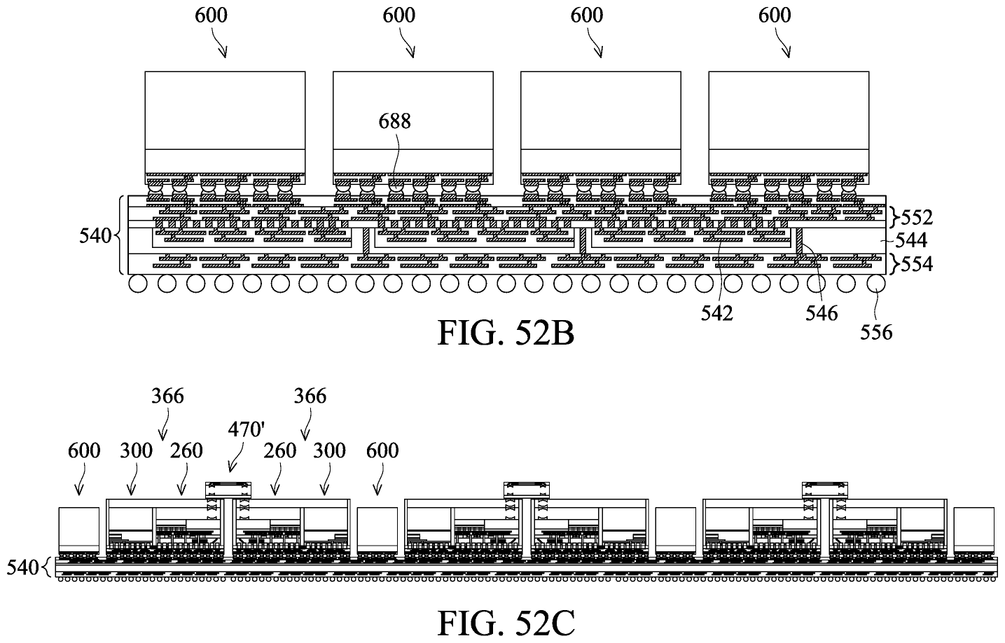

FIG. 52A illustrates a top-view representation of a package structure 600a, in accordance with some embodiments. FIG. 52B illustrate a cross-sectional representation of the package structure shown along line A-A′ in FIG. 52A, in accordance with some embodiments. FIG. 52C illustrate a cross-sectional representation of the package structure shown along line B-B′ in FIG. 52A, in accordance with some embodiments.

As shown in FIGS. 52A and 52B, a number of the semiconductor dies 600 are formed on the bottom interposer 540 along a first direction (such as line A-A′), in accordance with some embodiments.

As shown in FIGS. 52A and 52C, the optical die 300 and the composite die 260 are bonded to the top interposer 160 to form the connection die 366, in accordance with some embodiments. A number of the connection dies 366 are arranged along a second direction (line B-B′), and the bridge structure 470′ is formed to connect two adjacent connection dies 366. The semiconductor die 600 is adjacent to the connection die 366. The semiconductor die 600 and another connection die 366 are formed on opposite side of one of the connection die 366.

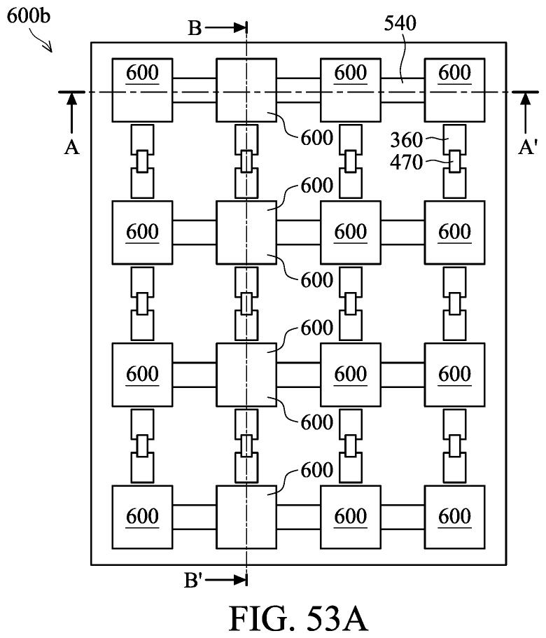

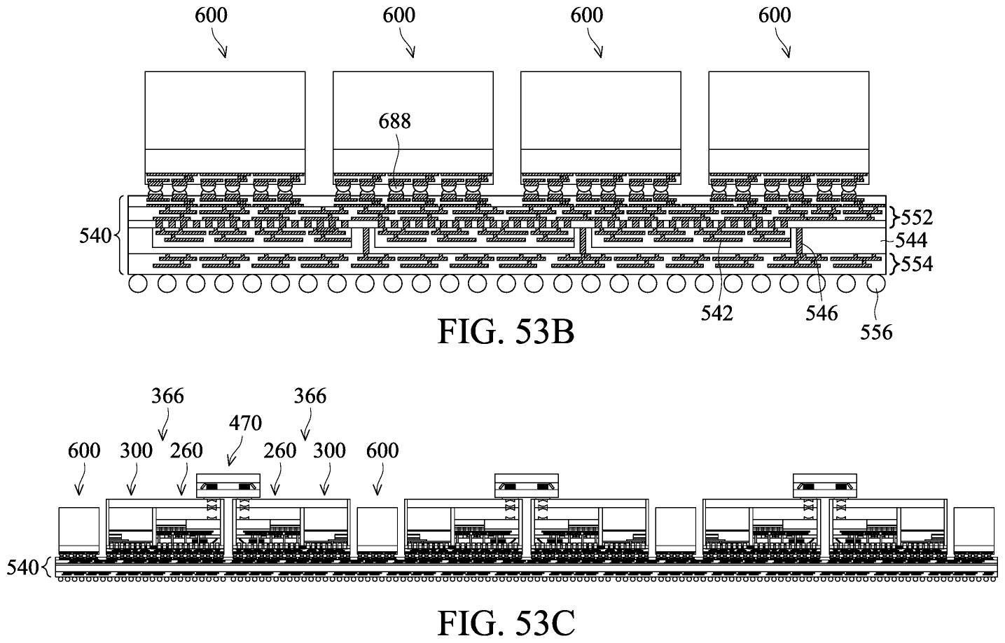

FIG. 53A illustrates a top-view representation of a package structure 600b, in accordance with some embodiments. FIG. 53B illustrate a cross-sectional representation of the package structure shown along line A-A′ in FIG. 53A, in accordance with some embodiments. FIG. 53C illustrate a cross-sectional representation of the package structure shown along line B-B′ in FIG. 53A, in accordance with some embodiments.

The package structure 600b is an alternate embodiment which may be similar to the package structure 600a of FIGS. 52A, 52B and 52C, where like reference numerals indicate like elements formed using like processes, unless specified otherwise. Processes and materials used to form the package structure 600b may be similar to, or the same as, those used to form the package structure 600a and are not repeated herein.

The difference between FIGS. 53A, 53B and 53C and FIGS. 52A, 52B and 52C is that that the bridge structure 470 is replaced with the bridge structure 470.

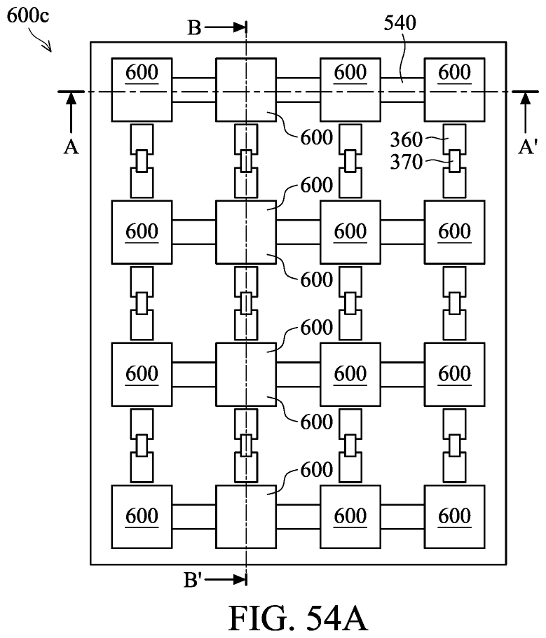

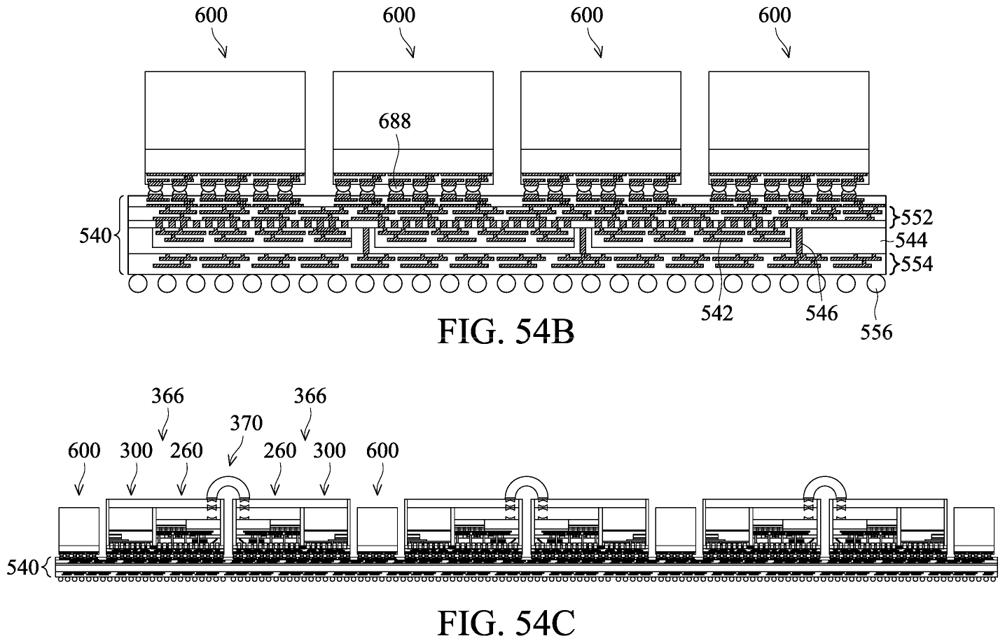

FIG. 54A illustrates a top-view representation of a package structure 600c, in accordance with some embodiments. FIG. 54B illustrate a cross-sectional representation of the package structure shown along line A-A′ in FIG. 54A, in accordance with some embodiments. FIG. 54C illustrate a cross-sectional representation of the package structure shown along line B-B′ in FIG. 54A, in accordance with some embodiments.

The package structure 600c is an alternate embodiment which may be similar to the package structure 600a of FIGS. 52A, 52B and 52C, where like reference numerals indicate like elements formed using like processes, unless specified otherwise. Processes and materials used to form the package structure 600c may be similar to, or the same as, those used to form the package structure 600a and are not repeated herein.

The difference between FIGS. 53A, 53B and 53C and FIGS. 52A, 52B and 52C is that the bridge structure 470 is replaced with the optical fiber 370.

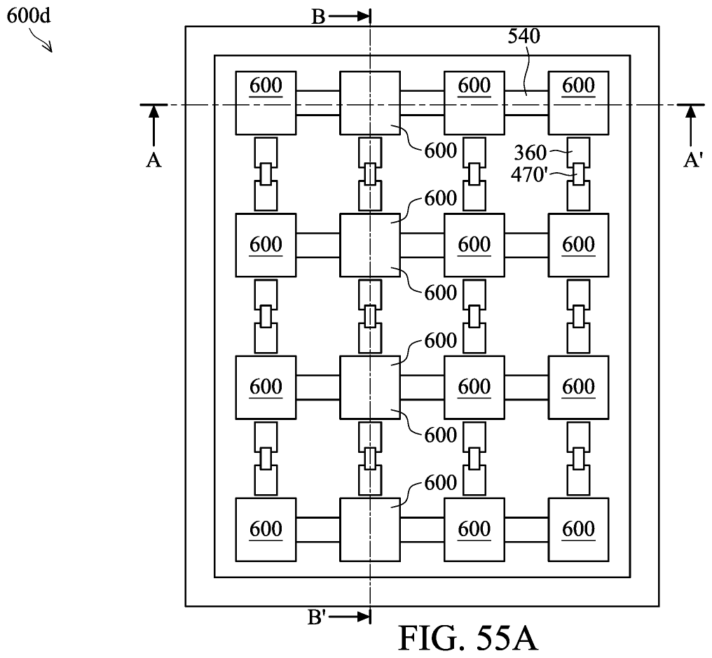

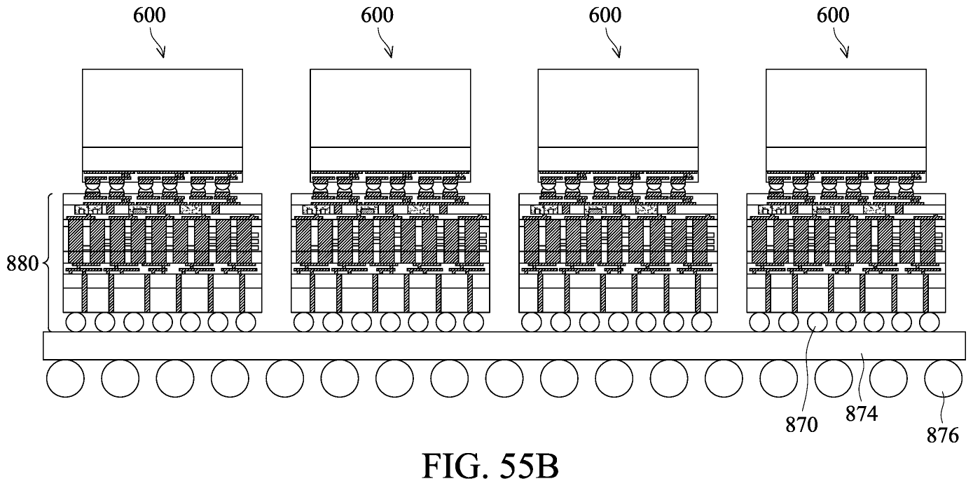

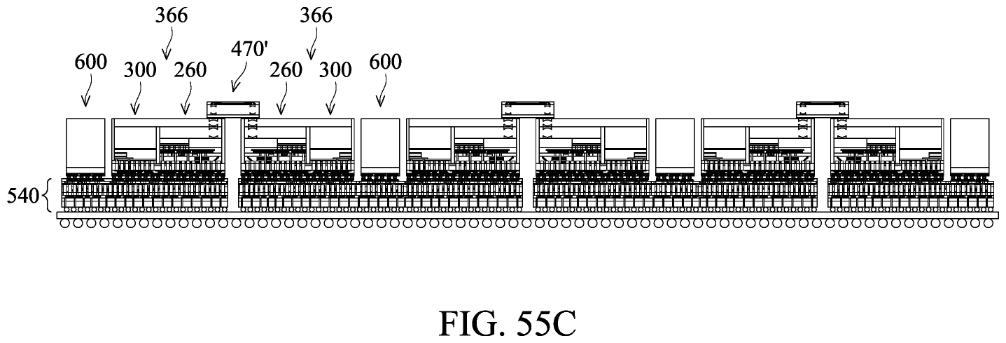

FIG. 55A illustrates a top-view representation of a package structure 600d, in accordance with some embodiments. FIG. 55B illustrate a cross-sectional representation of the package structure shown along line A-A′ in FIG. 55A, in accordance with some embodiments. FIG. 55C illustrate a cross-sectional representation of the package structure shown along line B-B′ in FIG. 55A, in accordance with some embodiments.

The package structure 600d is an alternate embodiment which may be similar to the package structure 600a of FIGS. 52A, 52B and 52C, where like reference numerals indicate like elements formed using like processes, unless specified otherwise. Processes and materials used to form the package structure 600d may be similar to, or the same as, those used to form the package structure 600a and are not repeated herein.

The difference between FIGS. 55A, 55B and 55C and FIGS. 52A, 52B and 52C is that the bottom interposer 540 is replaced with the bottom interposer 880. The bottom interposer 880 is formed on a substrate 874, and conductive connectors 876 are formed below the substrate 874.

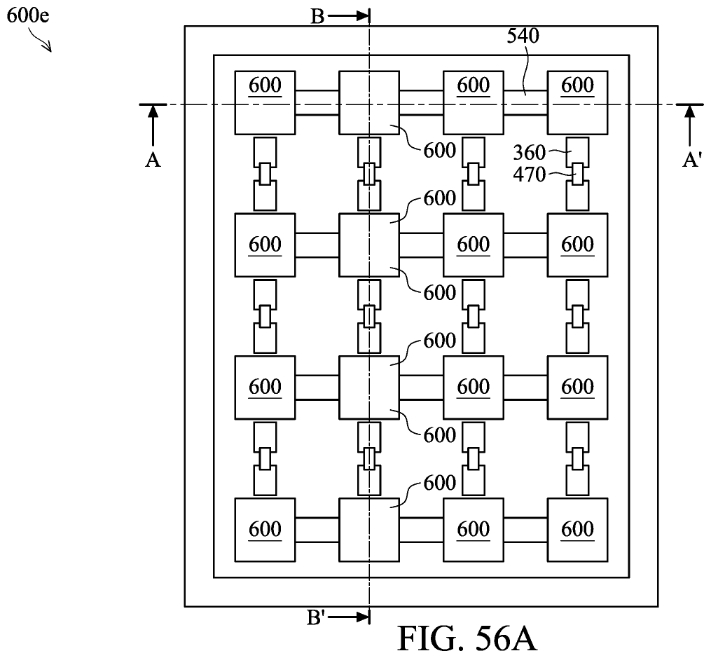

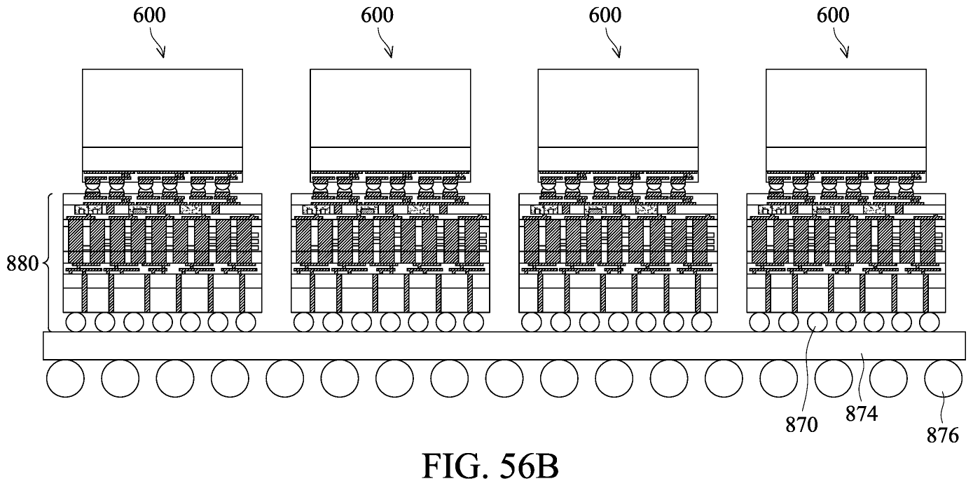

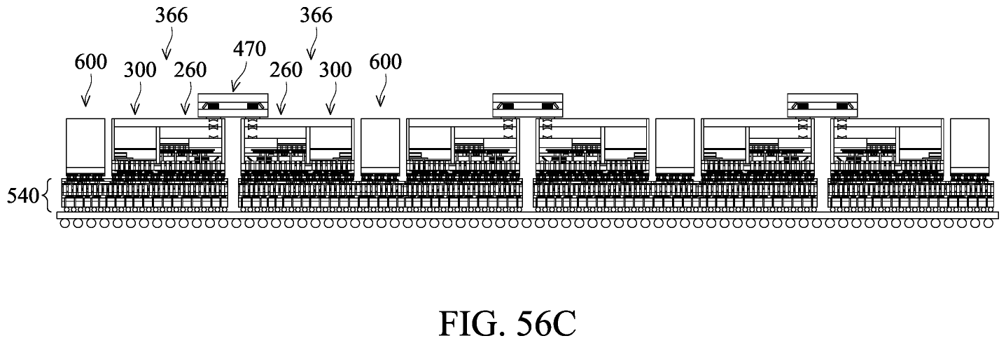

FIG. 56A illustrates a top-view representation of a package structure 600e, in accordance with some embodiments. FIG. 56B illustrate a cross-sectional representation of the package structure shown along line A-A′ in FIG. 56A, in accordance with some embodiments. FIG. 56C illustrate a cross-sectional representation of the package structure shown along line B-B′ in FIG. 56A, in accordance with some embodiments.

The package structure 600e is an alternate embodiment which may be similar to the package structure 600d of FIGS. 55A, 55B and 55C, where like reference numerals indicate like elements formed using like processes, unless specified otherwise. Processes and materials used to form the package structure 600e may be similar to, or the same as, those used to form the package structure 600d and are not repeated herein.

The difference between FIGS. 56A, 56B and 56C and FIGS. 55A, 55B and 55C is that that the bridge structure 470′ is replaced with the bridge structure 470.

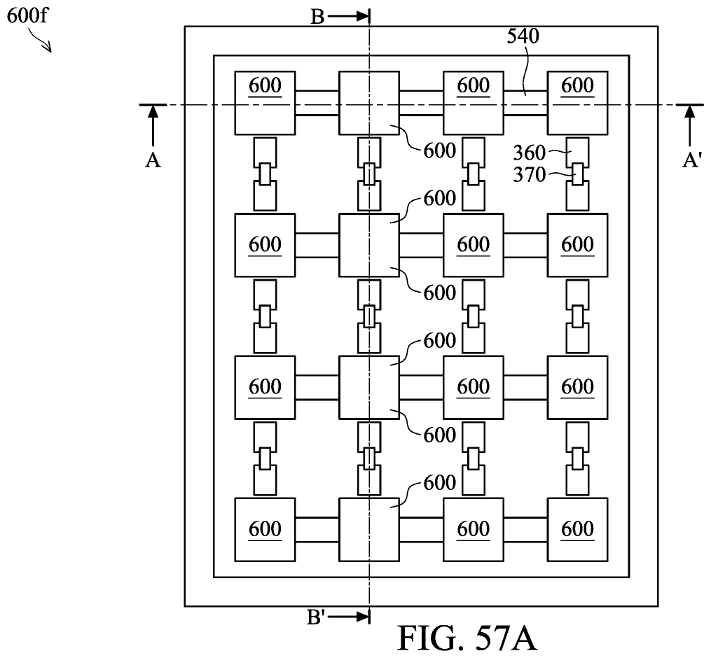

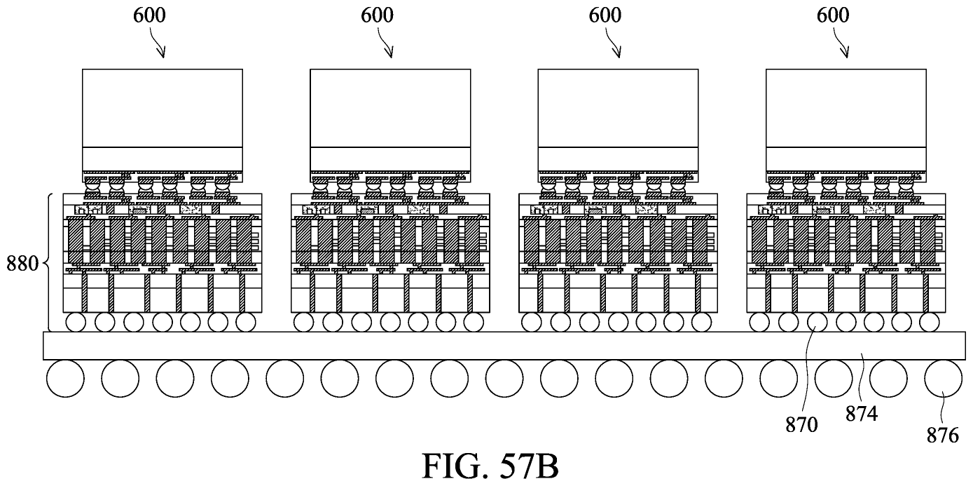

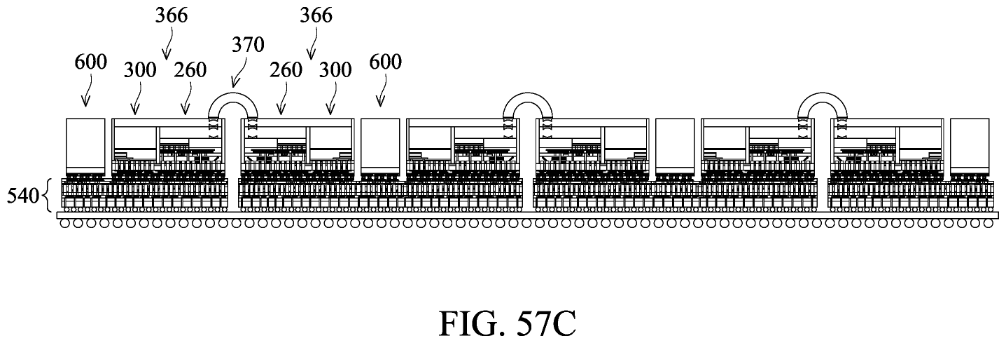

FIG. 57A illustrates a top-view representation of a package structure 600f, in accordance with some embodiments. FIG. 57B illustrate a cross-sectional representation of the package structure shown along line A-A′ in FIG. 57A, in accordance with some embodiments. FIG. 57C illustrate a cross-sectional representation of the package structure shown along line B-B′ in FIG. 57A, in accordance with some embodiments.

The package structure 600f is an alternate embodiment which may be similar to the package structure 600d of FIGS. 55A, 55B and 55C, where like reference numerals indicate like elements formed using like processes, unless specified otherwise.

Processes and materials used to form the package structure 600f may be similar to, or the same as, those used to form the package structure 600d and are not repeated herein.

The difference between FIGS. 57A, 57B and 57C and FIGS. 55A, 55B and 55C is that that the bridge structure 470′ is replaced with the optical fiber 370.

The package structure 100a includes the optical die 300 adjacent to the composite die 260, and the optical die 300 and the composite die 260 are bonded to the top interposer 160. The optical die 300 provides a build-in light source to improve the optical coupling efficiency. In addition, the optical die is configured to provide the light to the composite die, rather than from the external environment, the alignment accuracy between the optical die and the composite die become easier.

The package structures 100b, 100c, 100d, 100e and 100f include the optical array 400 or 400′ formed on the supporting substrate 360 to provide the light source.

The package structures 100g, 100h, 100i, and 100j also include the TEC 450 formed on the optical die 300 to transfer heat generated by the optical die 300 or the composite die 260 to the external environment.

The package structures 200a and 200b includes the top interposer 160 having the TSV structures 126 formed in the substrate 122. The package structures 200c, 200d, 200e and 200f are modified embodiments of the package structures 200a and 200b, and they include the optical array 400 or 400′ formed on the supporting substrate 360 to provide the light source. The package structures 200g, 200h, 200i and 200j are modified embodiments of the package structures 200a and 200b, and they include the TEC 450 formed on the optical die 300 to transfer heat.

The package structures 300a and 300b include the optical gel 351 between the optical die 300 and the composite die 260, and the optical components 348 and 56. By forming the optical components 348 and 56, the optical signal can be transmitted in the horizontal direction through the optical coupling between adjacent optical components 348, and 56. The package structures 300c, 300d, 300e and 300f are modified embodiments of the package structures 300a and 300b, and they include the optical array 400 or 400′ formed on the supporting substrate 360 to provide the light source. The package structures 300g, 300h, 300i and 300j are modified embodiments of the package structures 200a and 200b, and they also include the TEC 450 formed on the optical die 300 to transfer heat.

The package structures 400a, 400b, 400c, 400d includes the bridge structure 470 or 470′ on the supporting substrate 360 to transfer the optical signal from the optical die 300 to the composite die 260. The package structures 400e, 400f, 400g and 400h are modified embodiments of the package structures 400a, 400b, 400c, 400d, and they include the optical array 400 or 400′ formed on the supporting substrate 360, and the TEC 450 formed on the optical die 300.

The package structure 500a includes the bottom interposer 880 having the memory layer 844. The package structures 500b, 500c, 500d, 500e include the optical array 400 or 400′, the TEC 450 and the bridge structure 470 or 470′. The package structures 500f, and 500g include the TEC 450 and the bridge structure 470 or 470′.

The package structure 600a includes a number of the semiconductor dies 600 and a number of the connection dies 366 alternatively stacked. The bottom interposer 540 is formed below the semiconductor dies 600 and the connection dies 366. The package structures 600b and 600c are modified embodiments of the package structures 600a, and they includes the bridge structure 470 and the optical fiber 370. The package structures 600d, 600e and 600f are modified embodiments of the package structures 600a, 600b and 600c, and they includes the bottom interposer 880 having the memory layer 844.

Embodiments for forming a package structure and method for formation the same are provided. The package structure includes a composite die including an optical package structure (e.g. photonic integrated circuit (PIC)) and an electronic die (e.g. electronic integrated circuit (EIC)) and an optical die adjacent to the composite die. The composite die and the optical die are formed on the top interposer, and the top interposer is shared by the composite die and the optical die. Furthermore, the optical die provides a build-in light source to improve the optical coupling efficiency. In addition, the optical die is configured to provide the light to the composite die, rather than from the external environment, the alignment accuracy between the optical die and the composite die become easier. The light loss is reduced, and the light efficiency is greatly improved. Therefore, the performance and the reliability of the package structure are further improved.

In some embodiments, a package structure is provided. The package structure includes a top interposer formed over a substrate, and a first die formed over the top interposer. The first die includes an optical package structure, and the optical package structure includes first optical components. The first die also includes an electronic die bonded to the optical package structure to form a hybrid bonding structure. The hybrid bonding structure includes a metal-to-metal bonding and non-metal-to-non-metal bonding. The package structure includes an optical die adjacent to the first die, and the top interposer is shared by the optical die and the first die.

In some embodiments, a package structure is provided. The package structure includes a top interposer formed over a bottom interposer, and a composite die formed on the top interposer. The composite die includes an optical package structure, and the optical package structure includes first optical components, and an electronic die bonded to the optical package structure. The package structure also includes a laser die formed on the top interposer, and the laser die and the composite die are bonded to the top interposer by a hybrid bonding structure. The hybrid bonding structure includes a metal-to-metal bonding and non-metal-to-non-metal bonding. The package structure includes a semiconductor die formed adjacent to the laser die, and the semiconductor die and the top interposer are bonded to the bottom interposer.

In some embodiments, a method for forming a package structure is provided. The method include bonding an electronic die to an optical package structure to form a composite die, and bonding the composite die and an optical die to a top interposer by a hybrid bonding structure. The top interposer is shared by the optical die and the composite die. The method also includes bonding the top interposer to a bottom interposer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a top interposer formed over a substrate;
a first die formed over the top interposer, wherein the first die comprises:
an optical package structure, wherein the optical package structure comprises first optical components; and
an electronic die bonded to the optical package structure; and
an optical die adjacent to the first die, wherein the top interposer is shared by the optical die and the first die.

2. The package structure as claimed in claim 1, further comprising:
a bottom interposer formed below the top interposer; and
a first semiconductor die formed adjacent to the top interposer, wherein the first semiconductor die and the top interposer are bonded to the bottom interposer.

3. The package structure as claimed in claim 2, wherein the bottom interposer comprises a plurality of dies, wherein each of the dies comprises an interconnect structure.

4. The package structure as claimed in claim 1, further comprising:
an optical array formed adjacent to the first die; and
a supporting substrate formed on the first die, wherein the supporting substrate comprises a lens.

5. The package structure as claimed in claim 1, further comprising:
a cooler formed on the first die and the optical die.

6. The package structure as claimed in claim 1, further comprising:
an optical gel between the first die and the optical die.

7. The package structure as claimed in claim 1, further comprising:
a bridge structure formed on the first die and the optical die, wherein the bridge structure comprises a waveguide.

8. The package structure as claimed in claim 1, further comprising:
a bottom interposer formed below the top interposer, wherein the bottom interposer comprises a memory layer.

9. The package structure as claimed in claim 1, further comprising:
a second die formed over the top interposer, wherein the second die comprises:
an optical package structure, wherein the optical package structure comprises second optical components; and
an electronic die bonded to the optical package structure to form a hybrid bonding structure, wherein the hybrid bonding structure comprises a metal-to-metal bonding and non-metal-to-non-metal bonding; and
a bridge structure between the first die and the second die.

10. A package structure, comprising:
a top interposer formed over a bottom interposer;
a composite die formed on the top interposer, wherein the composite die comprises:
an optical package structure, wherein the optical package structure comprises first optical components; and
an electronic die bonded to the optical package structure;
a laser die formed on the top interposer, wherein the laser die and the composite die are bonded to the top interposer; and
a semiconductor die formed adjacent to the laser die, wherein the semiconductor die and the top interposer are bonded to the bottom interposer.

11. The package structure as claimed in claim 10, further comprising:
a first supporting substrate formed on the composite die;
a second supporting substrate formed on the laser die; and
a third supporting substrate formed on the first supporting substrate and the second supporting substrate.

12. The package structure as claimed in claim 10, further comprising:
an optical array formed adjacent to the composite die, wherein the optical array comprises optical components and a mirror.

13. The package structure as claimed in claim 10, further comprising:
a cooler formed on the composite die and the laser die.

14. The package structure as claimed in claim 10, wherein the composite die comprises optical components and a mirror.

15. The package structure as claimed in claim 10, wherein the bottom interposer comprises a plurality of dies, wherein each of the dies comprises an interconnect structure.

16. The package structure as claimed in claim 10, wherein the bottom interposer comprises a memory layer and optical components.

17. A method for forming a package structure, comprising:
bonding an electronic die to an optical package structure to form a composite die;
bonding the composite die and an optical die to a top interposer by a hybrid bonding structure, wherein the top interposer is shared by the optical die and the composite die; and
bonding the top interposer to a bottom interposer.

18. The method for forming the package structure as claimed in claim 17, further comprising:
forming a first supporting substrate on the composite die; and
forming an optical array on the first supporting substrate, wherein the optical array comprises optical components and a mirror.

19. The method for forming the package structure as claimed in claim 17, further comprising:
forming a bridge structure on the composite die and the optical die.

20. The method for forming the package structure as claimed in claim 17, wherein the bottom interposer comprises a memory layer and optical components.
